(19) United States
(12) Patent Application Publication
(10) Pub. No.: US 2026/0227770 A1
(43) Pub. Date: Aug. 6, 2026

(54) Inspection Management System and Method

(71) Applicant: Hitachi High-Tech Corporation, Minato-ku, Tokyo (JP)

(72) Inventors: Ayana MURAKI, Tokyo (JP); Yutaka IKKU, Tokyo (JP); Makoto SATO, Tokyo (JP)

(21) Appl. No.: 19/148,458

(22) PCT Filed: Jan. 25, 2023
(86) PCT No.: PCT/JP2023/002232

§ 371 Date: Jul. 16, 2025

(51) Int. Cl. G05B 19/418

(52) U.S. Cl. CPC G05B 19/4187; G05B 19/41855; G05B 2219/31455; G05B 2219/31472; G05B 2219/45031

(57) ABSTRACT

Provided is a technique capable of realizing more efficient inspection processing when an inspection system has a plurality of devices. An inspection in the inspection system is implemented as an inspection processing sequence performed by, for example, a first type device, a second type device, and a third type device. The first type device, the second type device, and the third type device each include one or more devices. As the inspection processing sequence, the inspection system produces a thin piece from a sample at each portion of the inspection, transfers the thin piece to a carrier, and performs processing related to the inspection for each of the thin pieces on the carrier. The inspection management system grasps a device status of each device based on communication with each device, and based on an inspection instruction and the device status, selects, from a plurality of devices, each type of devices to be used in the inspection processing sequence and a time to be used for the devices, and creates a plan of the inspection processing sequence including the selected devices and time.

### TECHNICAL FIELD

The present disclosure relates to a semiconductor manufacturing process and semiconductor device inspection processing technique.

### BACKGROUND ART

As miniaturization of a structure of a semiconductor device, an increase in a density of a circuit pattern, an increase in the number of layers of wiring, and the like progress, the importance of section analysis of a wafer by using, for example, a transmission electron microscope (TEM) or a scanning transmission electron microscope (STEM) is increasing in order to improve reliability.

In imaging, observation, measurement, analysis, evaluation, inspection, and the like (which may be collectively referred to as inspection for the sake of description) of a sample in a semiconductor manufacturing process, for example, a focused Ion beam (FIB) device performs thinning machining on a designated portion of a wafer to produce a thin piece (also referred to as a lamella, a thin film sample, or the like) where a cross-sectional structure of a device is exposed. The thin piece is transferred to a carrier, and a cross-sectional structure of the thin piece is observed using, for example, a TEM device.

Examples of the related art include JP2014-022296A (PTL 1). PTL 1 describes a charged particle beam device capable of performing machining by FIB and observation by a scanning electron microscope (SEM). In the charged particle beam device, a cross section of a machined lamella (thin piece) is acquired as an SEM image, the SEM image is compared with a reference image prepared in advance, and when the images do not match, the cross section is specified as a defective portion. The machined lamella is extracted by a mechanical probe and a deposition function provided in the charged particle beam device.

### CITATION LIST

### Patent Literature

PTL 1: JP2014-022296A

### SUMMARY OF INVENTION

### Technical Problem

Efficient operation and management are required for a series of sequences (which may be referred to as an inspection processing sequence or the like) related to inspection processing of a semiconductor device in the related art. The inspection processing sequence is shared and implemented by various devices such as an FIB-SEM device, a lift out device, and a TEM device.

For example, an inspection in an IC manufacturing process is performed by observing a TEM image using a TEM device. In this case, a manufacturing management system of a manufacturing line of a semiconductor manufacturing plant sets an inspection target portion on a wafer which is a sample, and provides inspection target portion information, an inspection instruction, the wafer, and the like to an inspection system. The inspection system forms and produces a thin piece by performing thinning machining on an inspection target portion of the wafer using, for example, an FIB-SEM device. On the wafer for which the thin piece is to be formed, the thin piece is taken out by, for example, a lift out device, and the thin piece is transferred to a carrier. Thereafter, a cross section of the thin piece on the carrier is observed using a TEM image obtained by, for example, a TEM device.

In an environment having an inspection system, each of devices such as a FIB-SEM device may be provided in plurality. For example, in order to enhance the overall processing capacity related to the inspection processing, each device is provided in plurality. For example, a set of FIB-SEM device, lift out device, and TEM device is provided in plurality. In this case, in order to reduce costs and the like, efficient operation and management of a plurality of devices of the entire inspection system are required. However, in the related art, when each device is provided in plurality in the inspection system, how to operate and manage a plurality of devices to realize efficient inspection processing is not sufficiently examined.

An object of the present disclosure is to provide a technique related to the semiconductor manufacturing process and semiconductor device inspection processing technique and capable of realizing more efficient inspection processing by operating and managing a plurality of devices when the plurality of devices are provided in an inspection system.

### Solution to Problem

A representative embodiment of the present disclosure has the following configuration. An inspection management system according to the embodiment is an inspection management system for managing inspection of a sample by an inspection system that inspects the sample, in which
the inspection in the inspection system is implemented as an inspection processing sequence in which first processing, second processing, and third processing are sequentially performed by a first type device, a second type device, and a third type device, respectively, which are devices that perform different kinds of processing,
the first type device, the second type device, and the third type device each include one or more devices,
as the inspection processing Sequence, the inspection system produces a thin piece from the sample at each target portion of the inspection, transfers the thin piece to a carrier, and performs processing related to the inspection for each of the thin pieces on the carrier, and
the inspection management system
   is connected to each of a plurality of devices including the first type device, the second type device, and the third type device through communication,
   grasps a device status including an idle time and a usage time of each of the devices based on communication with each of the devices, and
   based on an inspection instruction related to the inspection and the device status, selects, from the plurality of devices, devices respectively serving as the first type device, the second type device, and the third type device to be used in the inspection processing sequence and a time to be used for the devices, and creates a plan of the inspection processing sequence including the selected devices and time.

### Advantageous Effects of Invention

According to the representative embodiment of the present disclosure, regarding the semiconductor manufacturing process and semiconductor device inspection processing technique, when each device is provided in plurality in the inspection system, it is possible to realize more efficient inspection processing by operating and managing a plurality of devices. Problems, configurations, effects, and the like other than those described above will be made clear in embodiments for carrying out the invention.

### BRIEF DESCRIPTION OF DRAWINGS

FIG. 1 illustrates a system configuration including an inspection management system and an inspection system according to Embodiment 1.

FIG. 2 illustrates a configuration example in which a plurality 41 of the inspection system are communicably connected to the inspection management system according to Embodiment 1.

FIG. 3 illustrates a configuration example of the inspection management system according to Embodiment 1 as a computer system.

FIG. 4 illustrates a flow of an outline of inspection processing in the inspection system according to Embodiment 1.

FIG. 5 illustrates an outline of processing of each device in the inspection system according to Embodiment 1.

FIG. 6 illustrates an inspection processing sequence in a first type inspection system according to Embodiment 1.

FIG. 7 illustrates an inspection processing sequence in a second type inspection system according to Embodiment 1.

FIG. 8 illustrates a configuration example related to a carrier and the like in the first type inspection system according to Embodiment 1.

FIG. 9 illustrates a configuration example related to a carrier and the like in the second type inspection system according to Embodiment 1.

FIG. 10 illustrates a configuration example of an FIB-SEM device as a thin piece production device according to Embodiment 1.

FIG. 11 illustrates a configuration example of a lift out device as a thin piece transfer device according to Embodiment 1.

FIG. 12 illustrates a configuration example of a TEM device as a thin piece observation device according to Embodiment 1.

FIG. 13 illustrates a structure example of a thin piece according to Embodiment 1.

FIG. 14 illustrates a state in which a thin piece is taken out by the lift out device according to Embodiment 1.

FIG. 15 illustrates a state in which a thin piece is imaged by the lift out device according to Embodiment 1.

FIG. 16 illustrates a structure example of a carrier according to Embodiment 1.

FIG. 17 illustrates a state in which a thin piece is transferred to a carrier by the lift out device according to Embodiment 1.

FIG. 18 illustrates a configuration example when a thin piece is transferred to a carrier by a microsampling method according to Embodiment 1.

FIG. 19 illustrates another configuration example when a thin piece is transferred to a carrier according to Embodiment 1.

FIG. 20 illustrates a configuration example when a carrier is held inside a TEM device according to Embodiment 1.

FIG. 21 illustrates functional block configuration example of the inspection management system according to Embodiment 1.

FIG. 22 illustrates a processing flow of the inspection management system according to Embodiment 1.

FIG. 23 illustrates an example of a schedule table of device status information in Embodiment 1.

FIG. 24 illustrates an example of communication between the inspection management system and each device and plan creation in Embodiment 1.

FIG. 25 illustrates an example of creating a plan using a success rate and an index value in Embodiment 1.

FIG. 26 illustrates a screen example of plan creation with priority given to a success rate in Embodiment 1.

FIG. 27 illustrates a screen example of plan creation with priority given to a processing capacity in Embodiment 1.

FIG. 28 illustrates a screen example when execution of the inspection processing sequence is started according to Embodiment 1.

FIG. 29 illustrates a start instruction method in Embodiment 1.

FIG. 30 illustrates a plan determination method in Embodiment 1.

FIG. 31 illustrates a manual execution method in Embodiment 1.

FIG. 32 illustrates a screen example of an inspection processing status in Embodiment 1.

FIG. 33 illustrates a screen example of an inspection processing result in Embodiment 1.

FIG. 34 illustrates an example of warning notification in Embodiment 1.

FIG. 35 illustrates an example of error notification in Embodiment 1.

FIG. 36 illustrates a screen example of performance of the success rate in Embodiment 1.

FIG. 37 illustrates a screen example of an index value in Embodiment 1.

FIG. 38 illustrates a screen example of a maintenance status in Embodiment 1.

FIG. 39 illustrates a screen example of a maintenance plan in Embodiment 1.

FIG. 40 illustrates another example of plan creation in Embodiment 1.

FIG. 41 illustrates an example of plan creation according to an inspection priority in Embodiment 1.

FIG. 42 illustrates an example of a plan for simultaneous parallel inspection processing in Embodiment 1.

### DESCRIPTION OF EMBODIMENTS

Hereinafter, embodiments of the present disclosure will be described in detail with reference to the drawings. In the drawings, the same components are denoted by the same reference numerals in principle, and repeated description thereof is omitted. In order to facilitate understanding of the invention, expressions of components in the drawings may not represent an actual position, size, shape, range, and the like.

For the sake of description, in the case of describing processing executed by a program, a program, a function, a processing unit, and the like may be described as a main body, but a main body of hardware thereof is a processor, or a controller, a device, a computer, a system or the like implemented by a processor. The computer executes processing according to a program read onto a memory by a processor while appropriately using resources such as a memory and communication interface. Accordingly, a predetermined function, processing unit, and the like are implemented. The processor is implemented with, for example a semiconductor device such as a CPU/MPU or a GPU. Processing can be executed not only by software program processing but also by a dedicated circuit. The dedicated circuit may be an FPGA, an ASIC, a CPLD, or the like.

The program may be installed as data in a target computer in advance, or may be distributed as data from a program source to a target computer. The program source may be a program distribution server on a communication network, or may be a non-transitory computer-readable storage medium, for example, a memory card or a disk. The program may include a plurality of modules. A computer system may include a plurality of devices. The computer system may be configured with a client Server system, a cloud computing system, an IoT system, or the like. The various kinds of data and information are configured with a structure such as a table or a list, but are not limited thereto. The expressions such as identification information, identifier, ID, name, and number can be mutually replaced.

### Problems and the Like

The problems and the like will be additionally described. For example, a thin piece having a size of less than 150 nm is prepared as a TEM sample for observation and analysis of the sample performed by a TEM device. An inspection system forms and produces one or more thin pieces on a wafer by using an FIB-SEM device, a lift out device, or the like, takes out the thin pieces from the wafer, and transfers the thin pieces to a carrier. The thin pieces on the carrier is subjected to TEM image observation by the TEM device. Although a transfer method varies depending on a configuration of the inspection system, for example, in a first type inspection system to be described later, a thin piece is taken out from a wafer by a lift out device which is a thin piece transfer device, and the thin piece is transferred to a carrier. For example, in a second type inspection system to be described later, a thin piece is cut out from a wafer and the thin piece is transferred to a carrier by a first type FIB-SEM device.

An inspection processing sequence including production and transfer of the thin piece as described above takes a relatively long time. In order to efficiently implement a processing operation and work of such an inspection processing sequence, automated techniques are required.

In the related art, a lift out method and a microsampling method are known as methods for producing the thin piece. In the case of the lift out method, for example, a thin piece portion formed on a wafer in the FIB-SEM device is taken out by the lift out device and transferred to a carrier. In the case of the microsampling method, the production of a thin piece and the transfer of the thin piece to a carrier can be performed in the same device, for example, in the first type FIB-SEM device. In either one of the methods, for example, the lift out device or the first type FIB-SEM device can perform a processing operation while monitoring a sample or the like using an image captured by an optical microscope or an SEM mechanism.

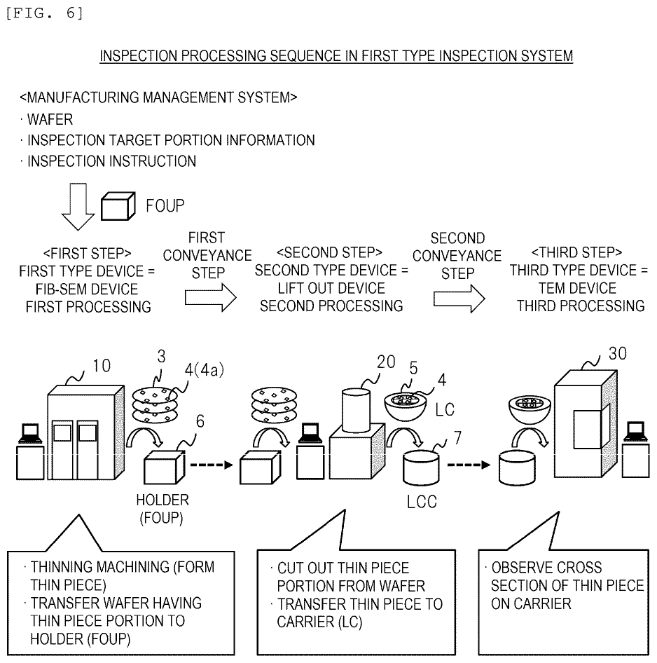

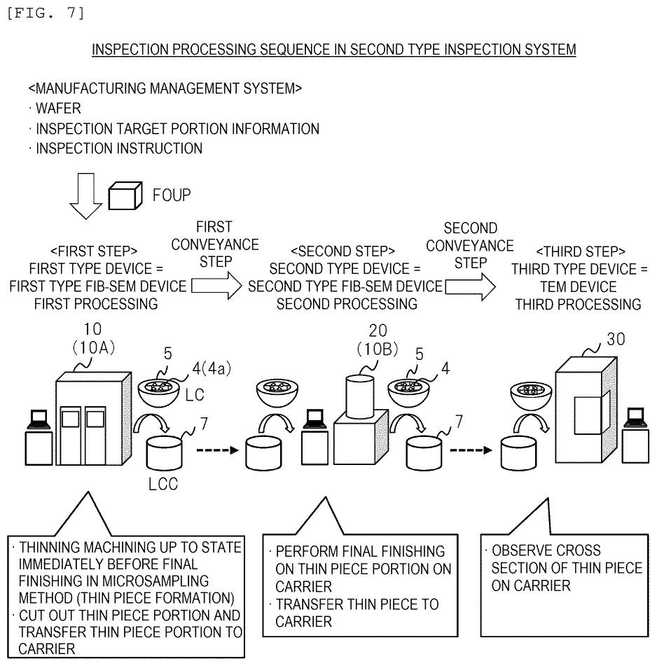

Here, in particular, the following problems exist. One type of device constituting the inspection system is the FIB-SEM device and the lift out device, for example. The FIB-SEM device has both a function of performing machining by FIB irradiation and a function of capturing an image by SEM. The lift out device has a function of lifting out the sample by an attaching and detaching device and a function of capturing an image by the optical microscope or the SEM mechanism. These devices can perform a processing operation such as formation or transfer of a thin piece by the lift out method or the microsampling method while using the captured image (see, for example, FIGS. 6 and 7 to be described later in detail).

As an example of the transfer, in the first type inspection system (FIG. 6), the FIB-SEM device in a first step transfers a wafer to a holder, and the lift out device in a second step takes out a thin piece from the wafer and transfers the thin piece to a carrier. In the second type inspection system (FIG. 7), the first type FIB-SEM device in the first step takes out a thin piece from a wafer and transfers the thin piece to a carrier.

In a process including production and transfer of a thin piece as in the above example, when the device performs a processing operation such as transfer, the processing operation may fail. For example, the lift out device may fail in an operation of gripping a thin piece portion with the attaching and detaching device. For example, the FIB-SEM device may fail in an operation of producing a thin piece portion or an operation of cutting a thin piece portion from a wafer by deposition or etching machining.

Both the FIB-SEM device and the lift out device having a function of performing a processing operation such as transfer perform a predetermined processing operation on the sample on the stage. In particular, these devices perform processing operations such as transfer while using image recognition and monitoring using an SEM image, an optical microscope image, or the like. Each of these devices has a machine difference in terms of stability of the charged particle beam, stage reproducibility, and the like for each individual device. The machine difference of the device affects the success/failure related to the processing operation such as transfer, and the success rate varies.

The success/failure of the transfer is also important from the viewpoint of a processing time and a processing capacity (in other words, throughput) of the entire inspection processing. When the transfer of the thin piece fails, recovery processing or the like for the production or transfer of the thin piece is required. Therefore, the processing time of the entire inspection processing becomes longer, the throughput decreases, and the overall efficiency decreases.

### Solutions

In the embodiment, an inspection management system (hereinafter, also simply referred to as a management system) is provided for efficient operation and management of an inspection processing sequence of a semiconductor device by an inspection system. The inspection management system according to the embodiment has a function of operating and managing each device constituting each step of the inspection processing sequence in the inspection system, for example, each device such as a FIB-SEM device, a lift out device, and a TEM device. In other words, the inspection management system is a computer system for managing an inspection processing sequence of the inspection system, or an inspection processing sequence management system.

The inspection management system is connected to each device of the inspection system through communication, and manages a processing operation of each device and grasps a status of the inspection processing sequence. The inspection management system has a function of creating a plan, a schedule, and the like (which may be collectively referred to as a plan) of the inspection processing sequence. The inspection management system has a function of managing the execution of the inspection processing sequence by the inspection system according to the plan, a function of outputting a status and a result of inspection processing, and the like.

Even when each device in each step of the inspection system is provided in plurality, the inspection management system efficiently operates and manages a plurality of devices. The inspection management system has a function of creating a suitable plan with the plurality of devices as candidates. The number of respective devices in each step in the inspection system may be the same or different. The number of devices in some steps may be only one. Typically, for example, in a case where one FIB-SEM device, one lift out device, and one TEM device are set as one set, addition may be performed for each set.

The inspection management system has a function of managing inspection processing sequences of at least two types (FIGS. 6 and 7 to be described later) of inspection systems. The two types of management coexist. Two types of inspection systems may be provided in an inspection environment. In this case, the management system creates a plan corresponding to each type of inspection system.

The inspection management system is connected to each device of the inspection system through communication, and appropriately performs communication related to an instruction, a response, and the like with each device to grasp a device status and the like. The inspection management system transmits a start instruction or the like to each device based on the created plan, and causes each device to execute a processing operation while receiving a response or the like from each device. The processing operation is a processing operation including, for example, thinning machining by the FIB-SEM device, lift out by the lift out device, and cross-sectional observation by the TEM device. The inspection management system monitors a status and a result of the processing operation of each device in each step of the inspection system, and records the status and result as performance. The inspection management system creates a new plan based on performance information.

The inspection management system grasps an idle time, a usage time, and the like of each device of the inspection system as a device status. The usage time includes a time during which the inspection processing is already in progress, a time during which future inspection processing is scheduled by the created plan, and the like. The usage time includes an adjustment time during which an adjustment work for a device is scheduled, a maintenance time during which maintenance for a device is scheduled, and the like. In addition, the usage time includes a time during which an individual device is scheduled to be used for a specific purpose.

The inspection management system creates a new inspection processing plan based on a sample, an inspection instruction, inspection portion information, and the like from a manufacturing management system. The inspection management system refers to and checks a device status, past performance information, and the like at the time of plan creation. The inspection management system selects a device to be used in each step to configure a new plan and calculates a time allocated for processing in the device (sometimes referred to as device usage time or the like) based on a device status or the like. The management system selects a device from a plurality of devices in each step. The management system determines a scheduled start time and a scheduled end time as the time allocated to the processing operation of each device. Therefore, the management system calculates the device usage time required for the processing of each device based on the performance information. When the device usage time falls within the idle time of the device, the time of the device can be assigned as a candidate for the processing.

Based on the set policy, the inspection management system creates one or more plan proposals optimize efficiency throughout the inspection processing sequence by combining the candidate devices and times in each step of the inspection processing sequence. The inspection management system may create a plurality of plan proposals in a ranked order.

When the inspection processing on a plurality of thin pieces of a plurality of wafers is requested, the inspection management system creates a plurality of plans related to a plurality of inspection processing sequences using an inspection system including a plurality of devices. The plurality of inspection processing sequences may be executed simultaneously in parallel when there is a margin in the device and time, or may be executed sequentially on a time axis if there is no margin in the device and time.

At the time of plan creation, the inspection management system may select the device and the time in each step in consideration of a success rate, a processing capacity, and the like of the processing operation of each device based on the past performance information in addition to the device status. For example, in the case of a policy giving priority to the success rate, a plan is created by preferentially using a device with a high success rate. For example, in a case of a policy giving priority to a processing time or a processing capacity (in other words, throughput or the like), a plan is created by preferentially using a device with a short processing time or a high processing capacity.

In response to the above-described problem, in order to achieve automation and efficiency in the inspection processing of the inspection system, it is desirable to improve the efficiency and the success rate of the processing operation such as production or transfer of the thin piece. For this reason, in the embodiment, the inspection management system has a function of operating and managing a plurality of devices of the inspection system in consideration of the machine difference, the success rate of transfer, and the like of each device. As a specific example, the inspection management system grasps, for each device of the inspection system, a success rate and a processing capacity of a processing operation including transfer, and creates a plan of an inspection processing sequence based on the success rate and the processing capacity.

In any type of inspection system, the inspection management system according to the embodiment grasps a processing time, success/failure, and the like of a processing operation including production and transfer of a thin piece by each device, and stores the processing time, success/failure, and the like as the device e status and the performance information. The device detects and grasps a state including success/failure of the processing operation such as production or transfer of a thin piece by performing monitoring using an SEM image, for example. The device transmits a response of a processing status and a processing result including information indicating success/failure of the processing operation to the inspection management system. The inspection management system grasps the status and the result of the processing of each device based on the response and information, and calculates a success rate and the like.

The inspection management system displays a progress status of the inspection processing sequence to a user during execution of the inspection processing sequence according to the plan. The inspection management system grasps a degree of progress of the processing operation of each device, success or failure of the operation, and the like. The inspection management system displays an execution result of the inspection processing sequence according to the plan to the user. The user can check the progress status and the execution result on a screen, for example, and can also take measures such as temporary stop of the inspection processing by a manual operation as necessary. Further, the inspection management system has a function of receiving data on an observation result from a sample observation device in a third step and displaying the observation result to the user on a screen based on the data.

The inspection management system has a function of calculating, for each device of the inspection system, a processing capacity, a processing time, and a success rate specific to a device, which reflect a machine difference, based on performance information of the inspection processing up to the present. In particular, the inspection management system calculates a success rate, a processing time, and a processing capacity of the processing operation including transfer for a device (for example, an FIB-SEM device or a lift out device) having a function of transferring a wafer or a thin piece as a device of the inspection system. The inspection management system calculates, for example, an index value of the processing capacity such as throughput and an index value of the processing time. When a new plan is created, the inspection management system selects a device to be used and a time by using information on at least one of a success rate or an index value in addition to the device status such as an idle time. The inspection management system can predict the success rate of the processing operation of the device based on the success rate. Even among a plurality of devices of the same type, the success rate may differ depending on the machine difference or the like. The inspection management system selects a device to be used in consideration of the predicted success rate. The inspection management system can create a suitable plan based on the success rate and the index value. The inspection management system may display information on the calculated success rate and index value for each device to the user on a screen.

The inspection management system according to the embodiment has both a function of performing plan creation and execution management corresponding to a fully automatic execution method of the inspection system and a function of performing plan creation and execution management corresponding to a manual execution method of the inspection system. The inspection management system has a function of switching between fully automatic execution management by the inspection management system and manual execution management by a manual operation by a user. For example, the user can select and set a mode corresponding to the automatic execution management and a mode corresponding to the manual execution management on the screen.

The inspection management system according to the embodiment has a function of transmitting an instruction or the like according to a plan to each device of the inspection system. In addition, the inspection management system has a function of transmitting a work instruction or the like for causing a worker associated with each device to recognize work when the work of the worker is interposed in a part of the inspection processing sequence.

The inspection management system according to the embodiment has the above functions to optimize the inspection time and the throughput while ensuring the accuracy required for the inspection. According to the embodiment, it is possible to create a suitable plan in consideration of a success rate of the transfer or the like, and it is possible to implement efficient inspection processing in which the processing time of the entire inspection processing is shortened and the throughput is increased as compared with the related art by managing the execution of the inspection processing sequence according to the plan.

### Embodiment 1

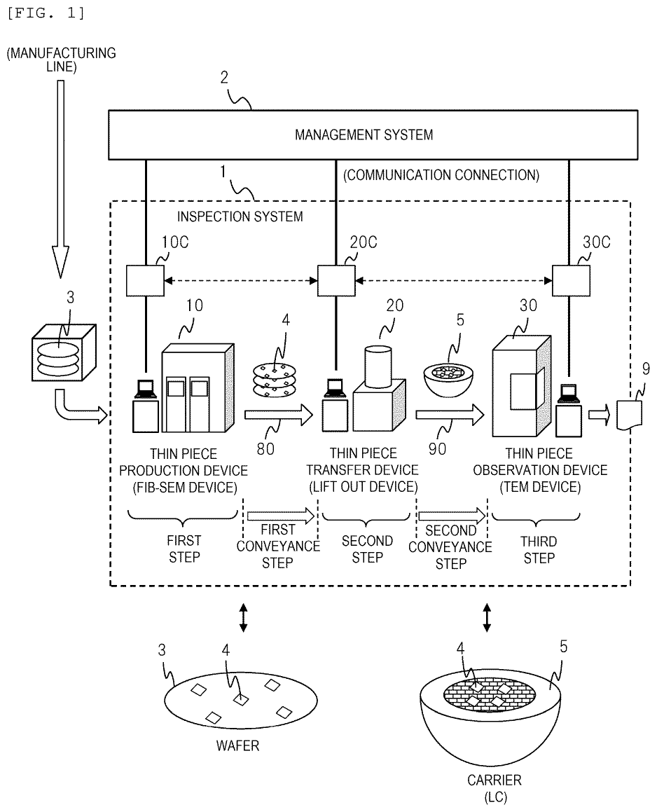

An inspection management system and a method according to Embodiment 1 will be described with reference to FIGS. 1 to 42. The inspection management system according to Embodiment 1 is a system that is connected to an inspection system and manages inspection processing executed by the inspection system. An inspection management method according to Embodiment 1 is a method executed by the inspection management system according to Embodiment 1.

### Overall System

FIG. 1 illustrates a configuration of the entire system including the inspection management system according to Embodiment 1 and an inspection system. A management system 2 which is the inspection management system according to Embodiment 1 is communicably connected to an inspection system 1. The inspection system 1 is a system that performs production, transfer, observation, analysis, and the like of a thin piece 4 from a wafer 3 as inspection processing. The management system 2 operates and manages an inspection processing sequence executed by the inspection system 1. In FIG. 1, a case of a first type inspection system 1 (FIG. 6) to be described later is illustrated as an example, but the invention is not limited thereto.

The inspection system 1 includes a thin piece production mechanism, a thin piece transfer mechanism, a thin piece observation mechanism, a control mechanism, and the like. In FIG. 1, the thin piece production mechanism includes a thin piece production device 10, and for example, a FIB-SEM device is applied as the thin piece production device 10. The thin piece transfer mechanism includes a thin piece transfer device 20, and for example, a lift out device is applied as the thin piece transfer device 20. The thin piece observation mechanism includes a thin piece observation device 30, and for example, a TEM device is used as the thin piece observation device 30. The control mechanism includes, for example, controllers 10C, 20C, and 30C provided for each device. The controller for each device manages information of the device and controls a processing operation of the device.

In FIG. 1, for ease of description, the controllers of the devices of the inspection system 1 are illustrated as blocks of the controllers 10C, 20C, and 30C. These controllers may be built in the devices or may be externally connected. The controllers of the devices may communicate with one another as appropriate. In a case where a controller which is a host control unit is provided for each device such as an FIB-SEM device 10 or a lift out device 20, one controller may control a plurality of devices. The controllers of the devices may be each configured to control the corresponding devices while cooperating with one another through communication.

The inspection system 1 conveys and receives the wafer 3 to be inspected from a semiconductor manufacturing line in a semiconductor manufacturing plant. The wafer 3 is set in the thin piece production device 10. The wafer 3 is conveyed between the semiconductor manufacturing line and the thin piece production device 10 of the inspection system 1 by a predetermined conveyance mechanism. For example, a FOUP, which is a container storing the wafer 3, is conveyed by an automatic conveyance system or a worker.

The FIB-SEM device 10 which is the thin piece production device 10 forms and produces the thin piece 4 by performing thinning machining on a designated portion of the wafer 3. The lift out device 20 which is the thin piece transfer device 20 takes out the thin pieces 4 from the wafer 3 from which the thin piece 4 is formed, the thin piece 4 being produced by the thin piece production device 10, and transfers the thin piece 4 to a carrier 5. Then, a TEM device 30 which is the thin piece observation device 30 observes and analyzes a cross section of the thin piece 4 on the carrier 5, and creates and outputs data 9 and the like as a result.

Various types of data and information may be appropriately exchanged among the devices of the inspection system 1 through communication in order to control the inspection processing. The various types of data and information include, for example, data indicating an inspection target position on a surface of the wafer 3, data indicating a position where the thin piece 4 is successfully created, and data indicating a position of the thin piece 4 mounted on the carrier 5. The data 9 as an inspection result includes a detection signal related to secondary electrons generated from the thin piece 4 irradiated with a beam, an image obtained based on the detection signal, data obtained as a result of processing the image, data related to X-rays generated from the thin piece 4, and the like.

The inspection system 1 performs a processing operation of producing the thin piece 4 at a designated position of the designated wafer 3 and transferring the thin piece 4 to a designated position on the designated carrier 5 using the devices in a shared manner, and grasps information on the processing operation, a state, and a position in terms of control. The inspection system 1 outputs an inspection result of the thin piece 4 as the data 9. The management system 2 communicates with each device of the inspection system 1 to grasp the above-described processing operation, state, position, inspection result, and the like in inspection processing of the inspection system 1.

The wafer 3 from which the thin piece 4 is formed is conveyed between the thin piece production device 10 and the thin piece conveyance device 20 by a conveyance mechanism 80. For example, a holder (details will be described later) for storing the wafer 3 is conveyed by an automatic conveyance system or a worker.

The thin piece 4 is conveyed between the thin piece conveyance device 20 and the thin piece observation device 30 by a conveyance mechanism 90. For example, the carrier 5 (details will be described later) to which the thin piece 4 is transferred is conveyed by an automatic conveyance system or a worker.

It is also possible to convey and return the wafer 3 from the thin piece transfer device 20 to the semiconductor manufacturing line by a conveyance mechanism (not illustrated). A FOUP, the carrier 5, or the like is used during various types of conveyance. The FOUP is a container filled with an inert gas such as nitrogen, and can store a wafer or the like by loading and unloading the wafer into and from the container.

The wafer 3 used in the embodiment includes a semiconductor substrate in which a p-type or n-type impurity region is formed, a semiconductor element such as a transistor formed on the semiconductor substrate, a wiring layer formed on the semiconductor element, and the like. The thin piece 4 is a portion formed from a part of the wafer 3 and taken out. Therefore, the thin piece 4 similarly includes structures of the semiconductor substrate, the semiconductor element, the wiring layer, and the like of the wafer 3. In Embodiment 1, the thin piece 4 of the wafer 3 mainly used in the semiconductor manufacturing line is an inspection target, but the invention is not limited thereto, and a sample may be a structure used in fields other than the semiconductor technology.

### Multiple Devices and Communication Connection

The inspection processing in the inspection system 1 of a semiconductor manufacturing process and a semiconductor device is shared and performed by various devices that perform different kinds of processing, and these kinds of processing are sequentially performed as sequence processing among the devices. Such inspection processing may be referred to as an inspection processing sequence. The management system 2 has a function of operating and managing such an inspection processing Sequence of the inspection system 1.

In Embodiment 1, the inspection processing sequence of the inspection system 1 is divided into a plurality of pieces of processing such as first processing executed by the thin piece production device 10 which is a first type device in a first step, second processing executed by the thin piece transfer device 20 which is a second type device in a second step, and third processing executed by the thin piece observation device 30 which is a third type device in a third step. The inspection processing sequence may include two or more types of devices of two or more steps.

A plurality of devices constituting the inspection system 1 include, for example, one or more FIB-SEM devices 10 as the first type devices, one or more lift out devices 20 as the second type devices, and one or more TEM devices 30 as the third type devices in the first type inspection system 1, but are not limited thereto. At least one of the steps includes a plurality of devices.

The management system 2 is communicably connected to each device of the inspection system 1. Examples of the communication include, but are not limited to, communication via a LAN. The devices of the inspection system 1, for example, the devices of the FIB-SEM device 10, the lift out device 20, and the TEM device 30 may be communicably connected to one another, which is not essential. In Embodiment 1, since the management system 2 is provided, the communication among the devices may be replaced with communication via the management system 2. Each device of the inspection system 1 includes a controller (for example, the controller 10C in FIG. 1) for controlling the device, which is not essential. The management system 2 may also serve as a controller of the devices. In other words, control functions for some devices may be implemented by the management system 2.

Each of the devices of the inspection system 1 may be devices of the same type or may have different functions or the like. For example, specifications or the like may be different among the plurality of FIB-SEM devices 10 in the first step. The management system 2 also manages such a difference as information and considers the difference in plan creation to be described later. The difference in a function of each device, as well as a machine difference, affects a success rate of the processing operation of the device.

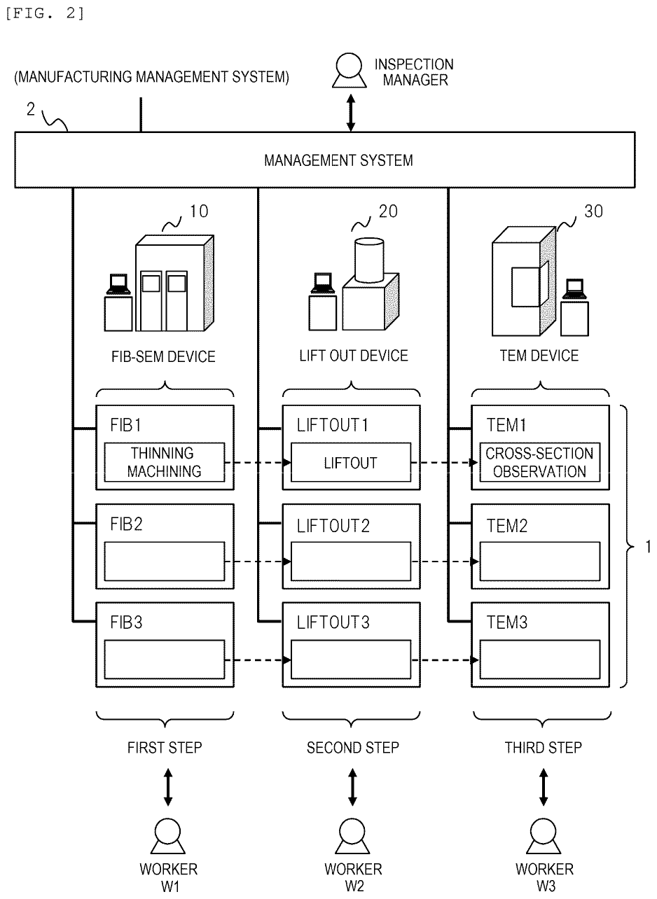

FIG. 2 illustrates a configuration example in which a plurality of devices constituting the inspection system 1 are connected to the management system 2 through communication (wired or wireless) based on FIG. 1. In Embodiment 1, a plurality of FIB-SEM devices 10 are provided as the thin piece production device 10 in the first step, a plurality of lift out devices 20 are provided as the thin piece transfer device 20 in the second step, and a plurality of TEM devices 30 are provided as the thin piece observation device 30 in the third step. In the example of FIG. 2, when one FIB-SEM device 10, one lift out device 20, and one TEM device 30 are set as one set, three such sets are installed in parallel.

The thin piece observation device 30 is not limited to the TEM device, and an STEM device may be applied.

The management system 2 is operated and used by, for example, an inspection manager such as a user. The management system 2 provides a management screen to the user. The screen is a screen accompanied by a graphical user interface (GUI) for operation, management, aid, support, visualization, and the like of the inspection processing sequence. In the related art, the inspection system 1 provides a control screen for each device. A device of the inspection system 1 provides a control screen to a user who uses the device. A screen example will be described later.

A part of the inspection processing of the inspection system 1 may be performed by a worker. FIG. 2 illustrates an example in which a worker in charge is associated with each step of the inspection processing sequence. For example, a first worker W1 is associated with the FIB-SEM device 10 in the first step, a second worker W2 is associated with the lift out device 20 in the second step, and a third worker W3 is associated with the TEM device 30 in the third step. The association is not limited thereto, and for example, the same worker may be in charge of a plurality of steps or a plurality of devices.

Each user such as an inspection manager or a worker may have a mobile terminal or the like for work, and the management system 2 may transmit information to the mobile terminal of each user and display the information on a screen of the mobile terminal. Information transmission and information output from the management system 2 are not limited to the form of screen display, and sound output, lamp lighting control, or the like may be used.

### Management System

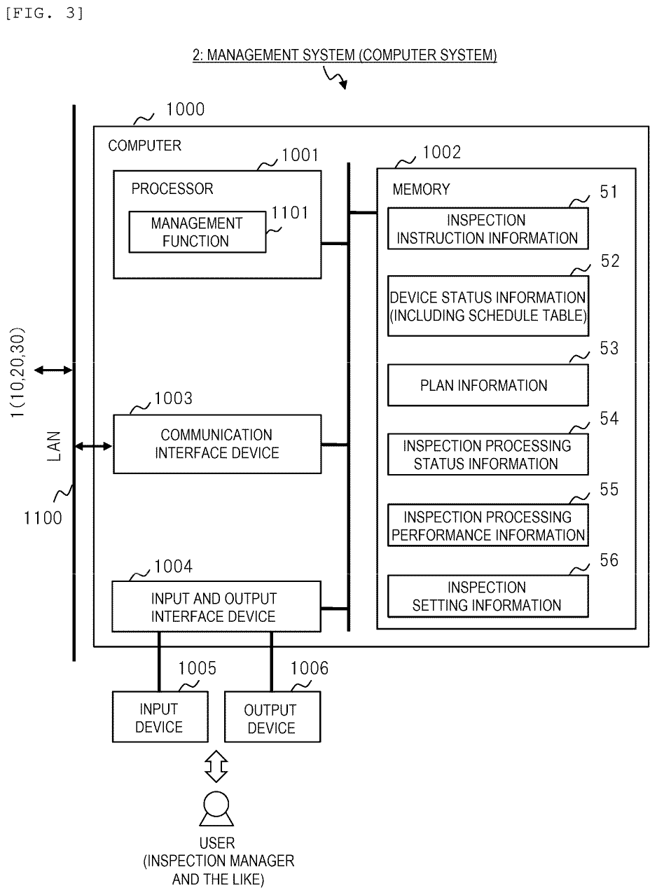

FIG. 3 illustrates a configuration example of the management system 2 as a computer system 2 and a configuration example of data and information. The computer system 2, which is the management system 2 in FIG. 3, mainly includes a computer 1000. In this example, the computer 1000 is connected to a LAN 1100 which is a communication network. The computer 1000 may be a PC, a server device, or the like in an implementation example. Each device of the inspection system 1 in FIG. 1 is connected to the LAN 1100. The computer 1000 can communicate with each device of the inspection system 1 through a communication interface device 1003 and the LAN 1100.

The computer 1000 includes a processor 1001, a memory 1002, the communication interface device 1003, an input and output interface device 1004, and the like, which are connected to a bus. The computer 1000 implements a management function 1101 and the like as an execution module by the processor 1001 executing processing according to a control program. The management function 1101 is a part that implements various functions to be described later. The processor 1001 includes, for example, a CPU. The memory 1002 includes, for example, a nonvolatile storage device. The memory 1002 stores preset information, various types of information input by a user, various types of information generated by the computer 1000, and the like. The communication interface device 1003 is mounted with, for example, a communication interface for communicating with an external device via the LAN 1100. An input device 1005 and an output device 1006 are externally connected to the input and output interface device 1004. The input device 1005 and the output device 1006 may be built in the computer 1000.

In this example, the memory 1002 stores inspection instruction information 51, device status information 52 (including a schedule table), plan information 53, inspection processing status information 54, inspection processing performance information 55, inspection setting information 56, and the like, which will be described later. These kinds of data and information are created as necessary. The memory 1002 may be implemented as a storage area of an external storage device.

The inspection setting information 56 includes setting information related to a mode of a function at the time of execution of inspection processing related to the inspection processing of the inspection system 1, configuration information (for example, a type, the number, and the like) of the inspection system 1, operation manual information, information of a semiconductor manufacturing plant, design information of a sample, and other kinds of data and information necessary for operation and management in the management system 2.

Other devices may be further connected to the LAN 1100 in FIG. 3. Examples of the other devices include a client terminal device of a user, an external defect inspection device, and a manufacturing execution system (MES). The computer 1000 may communicate with these external devices to input and output necessary data and information. The computer 1000 may be a server, and a client-server system may be provided between the computer 1000 and a client terminal device of a user. In this case, the computer 1000 serving as a server performs main processing, and the client terminal device of the user serves as a GUI. The computer 1000 generates GUI information and data information in the form of a Web page or the like, and transmits the information to the client terminal device of the user. The user can check the GUI information and the data information displayed on a screen of the client terminal device, and inputs an instruction and a setting as necessary. The client terminal device transmits the instruction or the like to the computer 1000. The computer 1000 performs processing according to the instruction or the like, and transmits GUI information or the like including a processing result to the client terminal device. The client terminal device displays the information on a screen, and the user can check the information on the screen.

### Inspection Processing Flow of Inspection System

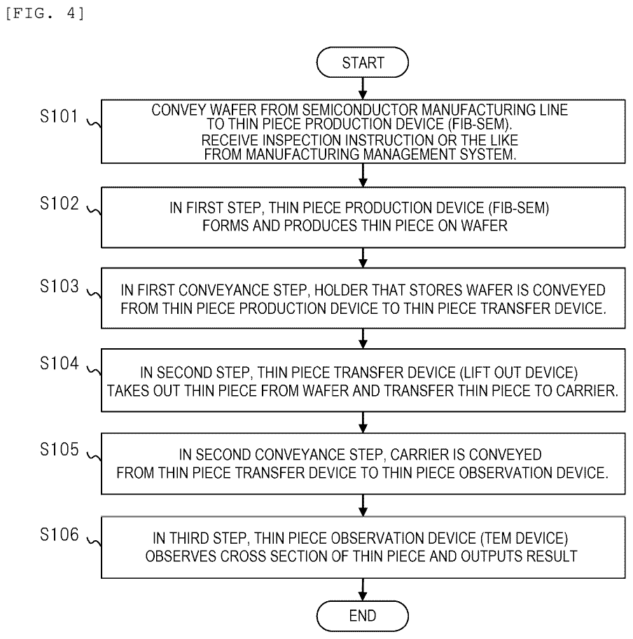

FIG. 4 illustrates a flow of an outline of inspection processing of the inspection system 1, and includes steps S101 to S106. FIG. 4 illustrates a case of the inspection processing sequence of a first type inspection system (FIG. 6). This flow is automatically executed and controlled by each device (particularly, the controller 10C or the like in FIG. 1) of the inspection system 1 based on an instruction from the management system 2, but a part thereof may be manually operated by a user. For example, not only automatic conveyance by an automatic conveyance system but also conveyance work by a worker may be applied in a first conveyance step and a second conveyance step, and in each step such as the first step, the worker may press a start button at the start of processing of a device.

In step S101, a FOUP that stores the wafer 3 to be inspected is conveyed from a semiconductor manufacturing line by a conveyance mechanism and reaches a place of the thin piece production device 10 of the inspection system 1. The thin piece production device 10 receives the FOUP and places the wafer 3 on a stage. At this time, a controller of the inspection system 1 or the management system 2 acquires data and information on inspection target portion information and an inspection instruction of the wafer 3 from the manufacturing management system in a plant. In Embodiment 1, the management system 2 receives data and information on an inspection instruction from the manufacturing management system, and the management system 2 instructs system 1 to execute inspection processing.

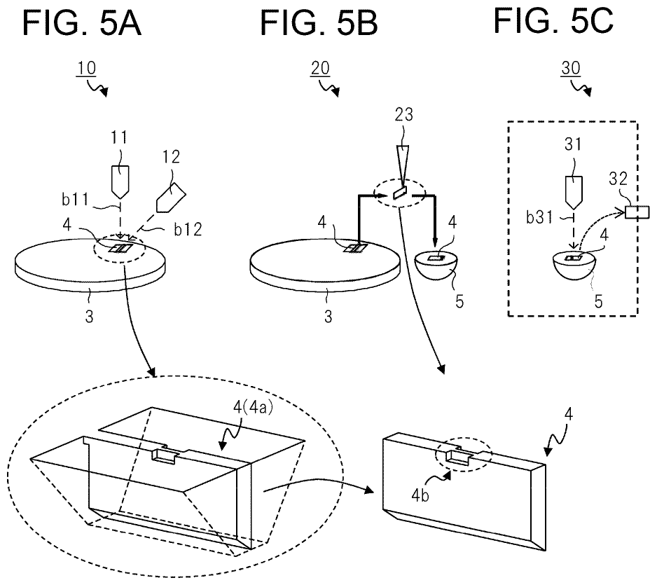

In step S102, the FIB-SEM device 10 which is the thin piece production device 10 in the first step performs a processing operation of thinning machining for forming and producing one or more thin pieces 4 from the wafer 3, which is first processing. Based on the information on an inspection position received from the management system 2, the thin piece production device 10 positions a field of view at an inspection target position on a surface of the wafer 3 by moving the stage. Then, the thin piece production device 10 forms a thin piece portion 4a corresponding to the thin piece 4 by irradiating the inspection target position with a beam which is an FIB (see FIG. 5 to be described later).

In step S103, the first conveyance step is performed. In the first conveyance step, the wafer 3 from which the thin piece portion 4a is formed is conveyed from the thin piece production device 10 to the thin piece transfer device 20 by an automatic conveyance system serving as the conveyance mechanism 80 or by a worker. The wafer 3 is conveyed while being stored in, for example, a holder (for example, the FOUP) to be described later.

In step S104, the lift out device 20 which is the thin piece transfer device 20 in the second step performs a lift out processing operation of taking out the thin piece 4 from the wafer 3 and transferring the thin piece 4 onto the carrier 5, which is second processing.

In step S105, the second conveyance step is performed. in the second conveyance step, the carrier 5 on which the thin piece 4 is mounted is conveyed from the thin piece transfer device 20 to the thin piece observation device 30 by an automatic conveyance system serving as the conveyance mechanism 90 or by a worker. The carrier 5 is conveyed while being stored in an LCC to be described later, for example.

In step S106, the TEM device 30 which is the thin piece observation device 30 in the third step observes a cross section of the thin piece 4 on the carrier 5 using a TEM image, performs analysis and inspection, and stores and outputs a result as the data 9, which is third processing.

### Devices of Inspection Processing and Outline of Steps

FIG. 5 illustrates an outline configuration of the thin piece production device 10, the thin piece transfer device 20, and the thin piece observation device 30 in the first type inspection system 1 and first, second, and third steps corresponding thereto. (A) of FIG. 5 illustrates a processing operation of thinning machining performed by, for example, the FIB-SEM device 10 which is the thin piece production device 10 in the first step. (B) of FIG. 5 illustrates a lift out processing operation performed by the lift out device 20 which is the thin piece transfer device 20 in the second step. (C) of FIG. 5 illustrates a processing operation of observing a cross section performed by the TEM device 30 which is the thin piece observation device 30 in the third step. An example of the thin piece portion 4a is illustrated in an enlarged manner on a lower side of (A), and an example of the thin piece 4 is illustrated in an enlarged manner on a lower side of (B) (details will be described later).

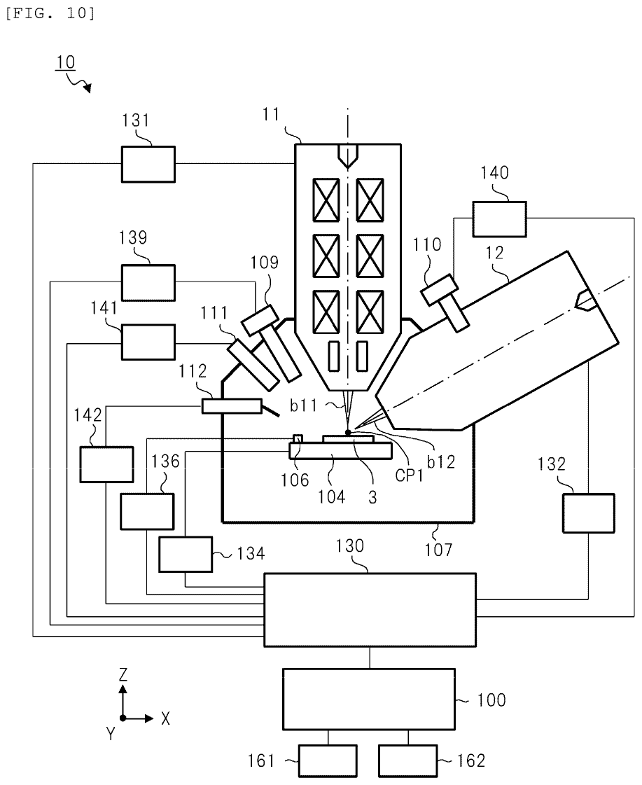

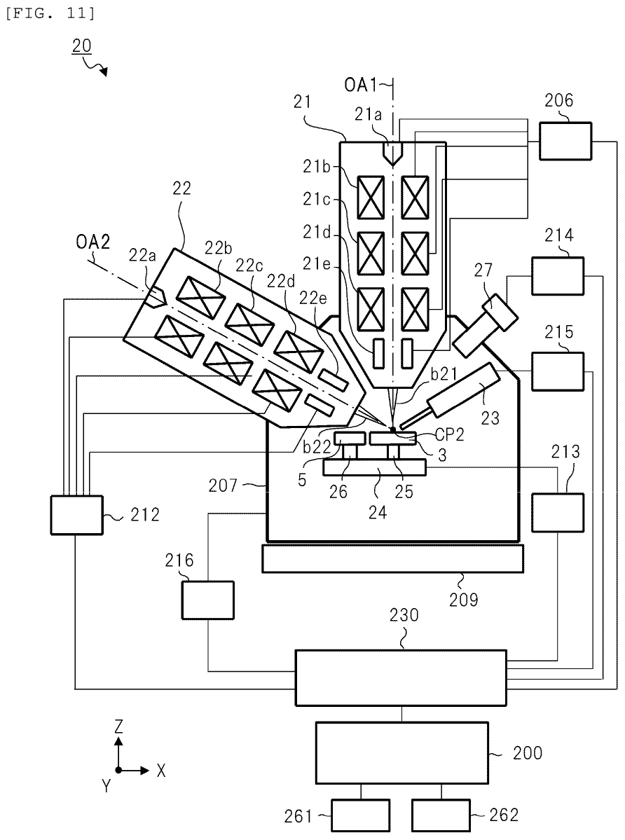

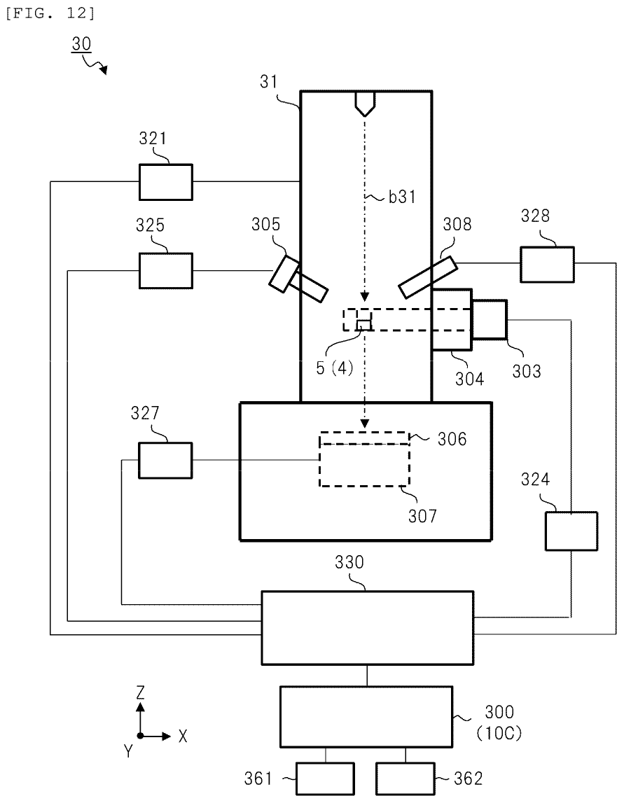

The thin piece production device 10 is implemented by, for example, a FIB-SEM device as illustrated in FIG. 10 to be described later. The thin piece transfer device 20 is implemented by, for example, a lift out device as illustrated in FIG. 11 to be described later. The thin piece observation device 30 is implemented by, for example, a TEM device as illustrated in FIG. 12 to be described later. In other words, these devices are a charged particle beam device, a microscope device, and the like.

In (A) of FIG. 5, the thin piece production device 10 includes at least an FIB column 11 which is an ion beam column 11 and an SEM column 12 which is an electron beam column 12. The ion beam column 11 includes all components necessary for a FIB device, such as an ion source for generating a charged particle beam b11 which is an ion beam b11, a lens for focusing the ion beam b11, and a deflection system for performing scanning using the ion beam b11 and shifting the ion beam b11. The electron beam column 12 includes all components necessary for an SEM device, such as an electron source for generating a charged particle beam b12 which is an electron beam b12, a lens for focusing the electron beam b12, and a deflection system for performing scanning using the electron beam b12 and shifting the electron beam b12.

In the first step, the thin piece production device 10 irradiates the wafer 3 with the ion beam b11 from the ion beam column 11 and perform etching machining on a part of the wafer 3 to produce an outer shape of the thin piece 4. Further, the thin piece production device 10 performs etching machining on a part of the thin piece 4 with the ion beam b11 to produce an analysis portion 4b near an upper surface of the thin piece 4. The analysis portion 4b is subjected to finished surface processing or the like for subsequent analysis by the TEM device 30. The etching by the ion beam column 11 is performed while irradiating the wafer 3 with the electron beam b12 from the electron beam column 12 and observing an etched portion, in other words, imaging and monitoring the etched portion. One or more thin piece portions 4a corresponding to one or more thin pieces 4 are formed from an upper surface of one wafer 3.

In the first conveyance step, the wafer 3 from which a plurality of the thin pieces 4 are formed is conveyed from the thin piece production device 10 to the thin piece transfer device 20 by the conveyance mechanism 80.

At this time, the management system 2 (or the controller of the inspection system 1) acquires data and information on a production position of the thin piece 4 on the wafer 3 from the thin piece production device 10. Then, the management system 2 transmits the data and information on the production position to the thin piece transfer device 20.

In the second step, based on the data and information received from the management system 2, the thin piece transfer device 20 takes t out the thin piece 4 from the production position on the wafer 3 using an attaching and detaching device 23, and transfers the thin piece 4 onto the carrier 5. This transfer is repeated until the transfer is completed for all the thin pieces 4 formed from the surface of the wafer 3.

In the second conveyance step, the carrier 5 to which the thin piece 4 is transferred is conveyed from the thin piece transfer device 20 to the thin piece observation device 30 by the conveyance mechanism 90.

At this time, the management system 2 (or the controller of the inspection system 1) acquires data and information on a position of the thin piece 4 transferred and mounted on the carrier 5 from the thin piece transfer device 20. Then, the management system 2 transmits the data and information to the thin piece observation device 30.

In the third step, the thin piece observation device 30 observes a cross section of the thin piece 4 (particularly, the analysis portion 4b) at a target position on the carrier 5 set inside the device based on the data and information received from the management system 2. The thin piece observation device 30 includes at least an electron beam column 31. The electron beam column 31 includes all components necessary for a TEM device, such as an electron source for generating a charged particle beam b31 which is an electron beam b31, a lens for focusing the electron beam b31, and a deflection system for performing scanning using the electron beam b31 and shifting the electron beam b31. The thin piece observation device 30 is also provided with a detector 32 such as a charged particle detector and an X-ray detector. A TEM image is obtained based on a detection signal from the detector 32.

The observation and analysis for the analysis portion 4b of the thin piece 4 in the thin piece observation device 30 is performed in a state in which the thin piece 4 is mounted on the carrier 5 inside the device. In addition, the carrier 5 on which the thin piece 4 is mounted is disposed such that a front surface of the analysis portion 4b of the thin piece 4 (that is, a surface where a cross-sectional structure is exposed) faces the electron beam column 31, in other words, the front surface of the analysis portion 4b is irradiated with the electron beam b31.

The thin piece observation device 30 first irradiates the analysis portion 4b of the thin piece 4 with the electron beam b31 from the electron beam column 31. Particles generated from the analysis portion 4b of the thin piece 4 due to the irradiation are detected by the detector 32 as a detection signal. The detection signal of the detected particles is subjected to calculation processing by a calculation processing unit provided in the detector 32 to form an image. The thin piece observation device 30 analyzes and inspects a structure and the like of the analysis portion 4b of the thin piece 4 based on the acquired image. Further, X-rays generated from the analysis portion 4b are detected by an X-ray detector, and similarly, a substance or the like constituting the analysis portion can be analyzed based on the obtained image.

The data 9 (FIG. 1) generated as a result of the observation and analysis in the thin piece observation device 30 in such a manner is stored in a memory of a controller (for example, the controller 30C in FIG. 1) of the inspection system 1. Further, the data 9 is output and transmitted to the management system 2 and stored in a memory of the management system 2. The management system 2 can store the data 9 in the memory of the management system 2 and display an inspection result on a screen for the user such as an inspection manager based on the data 9.

### Inspection Processing Sequence in First Type Inspection System

FIG. 6 illustrates a configuration outline of an inspection processing sequence in the first type inspection system 1. The inspection system 1 receives the wafer 3 which is an inspection target sample from a semiconductor manufacturing line in a plant by, for example, conveying the wafer 3 in a FOUP. The management system 2 receives inspection target portion information and information on an inspection instruction from the manufacturing management system in the plant.

The inspection processing sequence of the first type inspection system 1 observes a cross section of the thin piece 4. the Inspection Processing Sequence of the First Type inspection system 1 mainly includes first to third steps. The first type inspection system 1 includes, for example, three types of devices such as the FIB-SEM device 10, the lift out device 20, and the TEM device 30, and the inspection processing sequence is a sequence of continuous processing in the order of these devices. The first step is a thinning machining step, and for example, the FIB-SEM device 10 is used as a first type device. The second step is a lift out step, and the lift out device 20 is used as a second type device. The third step is a cross section observation step, and the TEM device 30 is used as a third type device.

In the first step, the FIB-SEM device 10 performs thinning machining according to a designated recipe at a time (from a start time to an end time) designated in a plan (to be described later) of the management system 2, which is first processing. A designated FOUP that stores the designated wafer 3 is set in the FIB-SEM device 10. The FIB-SEM device 10 performs thinning machining, which is the designated first processing, on the designated wafer 3 taken out from the FOUR. The first processing is processing of forming and producing the thin piece portion 4a by perform thinning machining on a region H an inspection target portion of the wafer 3 with a charged particle beam. The FIB-SEM device 10 forms the thin piece portion 4a from the wafer 3 while performing monitoring using an SEM image imaged based on the beam. At this time, the thin piece portion 4a is still coupled to the wafer 3 via a part of the wafer 3. The FIB-SEM device 10 transfers and stores the wafer 3 on which the thin piece portion 4a is formed in a holder 6 (for example, the FOUP).

There is a first conveyance step between the first step and the second step. In the first conveyance step, for example, an automatic conveyance system conveys the holder 6 (FOUP) that stores the wafer 3 to the lift out device 20 in the second step via the conveyance mechanism 80. Then, the holder 6 is set in the lift out device 20. In the case of manual conveyance, a worker conveys the holder 6 (FOUP) to the lift out device 20 and sets the holder 6 in the lift out device 20.

In the second step, the lift out device 20 performs a lift out processing operation according to a designated recipe at a time (from a start time to an end time) designated in the plan, which is second processing. The lift out device 20 takes out the thin piece portion 4a from a designated position of the wafer 3 taken out from the set FOUP using the attaching and detaching device 23 (FIG. 5), and transfers the thin piece portion 4a to a designated position of the designated carrier 5 (LC to be described later).

There is a second conveyance step between the second step and the third step. In the second conveyance step, for example, an Automatic Conveyance System Conveys the Carrier 5 (specifically, an LCC 7 to be described later) to the TEM device 30 in the third step via the conveyance mechanism 90. Then, the carrier 5 (LCC 7) is set in the TEM device 30. In the case of manual conveyance, a worker conveys the carrier 5 (LCC 7) to the TEM device 30 and sets the carrier 5 in the TEM device 30.

In the third step, the TEM device 30 performs a processing operation of observing a cross section of the thin piece 4 according to a designated recipe at a time (from a start time to an end time) designated in the plan, which is third processing. The TEM device 30 loads the set carrier 5 (specifically, a cartridge to be described later) into the TEM device 30, and performs the TEM image observation for the thin piece 4 on the carrier 5. At this time, the TEM device 3 acquires a TEM image of the analysis portion 4b of the thin piece 4 on a mesh (to be described later) of the carrier 5 under conditions such as a designated position and magnification. At this time, since a reference capable of low magnification search is designated for positioning the analysis portion 4b to an observation position, search to a final observation position can be automated. The TEM device 30 loads the carrier 5 to the outside after performing the processing operation a designated number of times and for the designated number of thin pieces 4.

The TEM device 30 stores, as the data 9, image data of the acquired TEM image and data of a result of processing such as measurement and analysis on the image and transmits the data 9 to the management system 2. The management system 2 receives the data 9 from the TEM device 30 and stores the data 9 in the memory. The management system 2 can display a cross section observation result among inspection processing results on a screen based on the data 9. In addition to transmitting the data 9 from the TEM device 30 to the management system 2, the cross section observation result may be output to a screen of an output device of the TEM device 30 at a place of the TEM device 30.

A specific example of cross section observation on the thin piece 4 in the TEM device 30 is as follows. In the cross section observation, a position, a shape, and a dimension of stacked films and the like are measured, analyzed, and evaluated for a cross-sectional structure appearing in a front surface (particularly, the analysis portion 4b) of the thin piece 4. For example, a width, a depth, and the like of a trench, a hole, or the like are measured. Then, for example, whether a position, a shape, or a dimension of a film or the like is appropriate is evaluated and determined by comparing a measurement value with a reference value.

A conveyance step includes conveyance of the holder 6 (FOUP) from the manufacturing line to the FIB-SEM device 10, conveyance of the holder 6 (FOUP) from the FIB-SEM device 10 to the lift out device 20 which is the first conveyance step, and conveyance of the carrier 5 (LCC 7) from the lift out device 20 to the TEM device 30 which is the second conveyance step. For these conveyance steps, an automatic conveyance method using an automatic conveyance system may be applied, a manual conveyance method by a worker may be applied, or these methods may be mixed. When the automatic conveyance method is used, completely automatic inspection processing can be achieved. Such a conveyance method is defined in advance for each environment of the inspection system 1. The management system 2 has a function of creating a plan corresponding to such a conveyance method. When the manual conveyance method is used, as will be described later, the management system 2 can transmit and notify a work instruction to a worker in charge.

### Second Type Inspection System And Inspection Processing Sequence

FIG. 7 illustrates a configuration outline of an inspection processing sequence in the second type inspection system 1. An inspection instruction and the like from a plant are the same as those in the case of the first type. The second type inspection processing sequence is mainly different from the first type inspection processing sequence that a second type FIB-SEM device 20 (10B) is used without using the lift out device 20. In addition, in the second type, planar observation of the thin piece 4 (in other words, plane view imaging) can be implemented by the TEM device 30. In the planar observation, the TEM image observation is performed in a planar direction of the wafer 3. The function of the management system 2 can be applied to the second type inspection processing sequence in a similar manner to the first type inspection processing sequence.

The inspection processing sequence of the second type inspection system 1 mainly includes first to third steps. The second type inspection system 1 includes, for example, a set of three types of devices such as a first type FIB-SEM device 10 (10A), the second type FIB-SEM device 20 (10B), and the TEM device 30, and the inspection processing sequence is a sequence of continuous processing in the order of these devices. The first step is a thinning machining step, and for example, the first type FIB-SEM device 10 (10A) is used as a first type device. The second step is a final finishing step, and for example, the second type FIB-SEM device 20 (10B) is used as a second type device. The third step is a cross section observation step, and the TEM device 30 is used as a third type device.

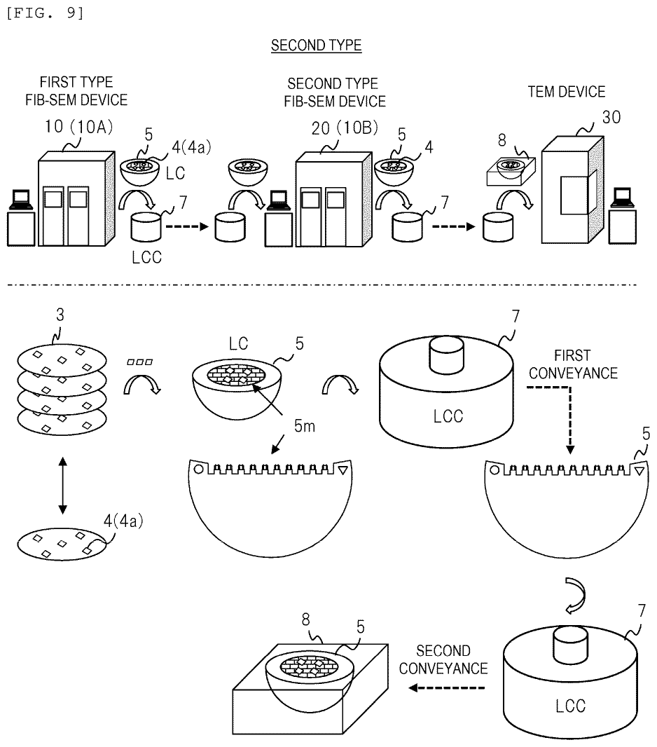

In the first step, the first type FIB-SEM device 10 performs FIB machining up to a state immediately before final finishing as thinning machining on an inspection target position of the wafer 3 according to a designated recipe, and forms the thin piece portion 4a in such a state, which is first processing. After the machining, the first type FIB-SEM device 10 cuts out the thin piece portion 4a from the wafer 3 by FIB machining and transfers the thin piece portion 4a onto the carrier 5 (see FIG. 9 to be described later). The first type FIB-SEM device 10 loads the carrier 5 to the outside and stores the carrier 5 in the LCC 7. In the case of the second type, the first step includes a processing operation of transferring the thin piece 4.

In the first conveyance step, for example, an automatic conveyance system conveys the carrier 5 to which the thin piece portion 4a of the wafer 3 is transferred to the second type FIB-SEM device 20 in the second step via the conveyance mechanism 80 in a state in which the carrier 5 is stored in the LCC 7. Then, the carrier 5 is set in the second type FIB-SEM device 20.

In the second step, the second type FIB-SEM device 20 loads the LCC 7, and performs final finishing FIB machining on the thin piece portion 4a on the carrier 5 according to a designated recipe, which is second processing. At this time, the second type FIB-SEM device 20 moves the stage to a final finishing position while observing the final finishing position using an SEM image, and irradiates the thin piece portion 4a at the position with the FIB to perform final finishing FIB machining. This final finishing may take a relatively long time. Therefore, it is effective to improve efficiency of the entire inspection processing by the management system 2 according to Embodiment 1.

The second type FIB-SEM device 20 performs the above-described processing operation a designated number of times and for the designated number of thin pieces 4, and then loads, to the outside, the LCC 7 that stores the carrier 5 (LC) on which the finished thin piece 4 is mounted.

In the second conveyance step, for example, an automatic conveyance system conveys the LCC 7 that stores the carrier 5 to the TEM device 30 in the third step via the conveyance mechanism 90. Then, the carrier 5 is set in the TEM device 30 while being stored in a cartridge 8.

In the third step, the TEM device 30 performs cross section observation (in particular, planar observation) as the third processing. The TEM device 30 loads the cartridge 8 that stores the carrier 5 into the TEM device 30, and brings the processing into a state in which the thin piece 4 on the carrier 5 is irradiated with the beam. The TEM device 30 acquires a TEM image of the thin piece 4 on the mesh of the carrier 5 under conditions such as a designated position and magnification. The TEM device 30 loads the cartridge 8 that stores the carrier 5 to the outside after performing the above-described processing operation a designated number of times and for the designated number of thin pieces 4.

The FIB-SEM device 10 in the first step and the lift out device 20 in the second step in the first type inspection processing sequence have machine differences. Similarly, the first type FIB-SEM device 10 in the first step and the second type FIB-SEM device 20 in the second step in the second type inspection processing sequence have machine differences. Depending on the machine differences between the devices, the success/failure of the processing operation such as the transfer of the wafer 3 or the thin piece 4 is affected.

### Configuration Example of Carrier and the Like in First Type

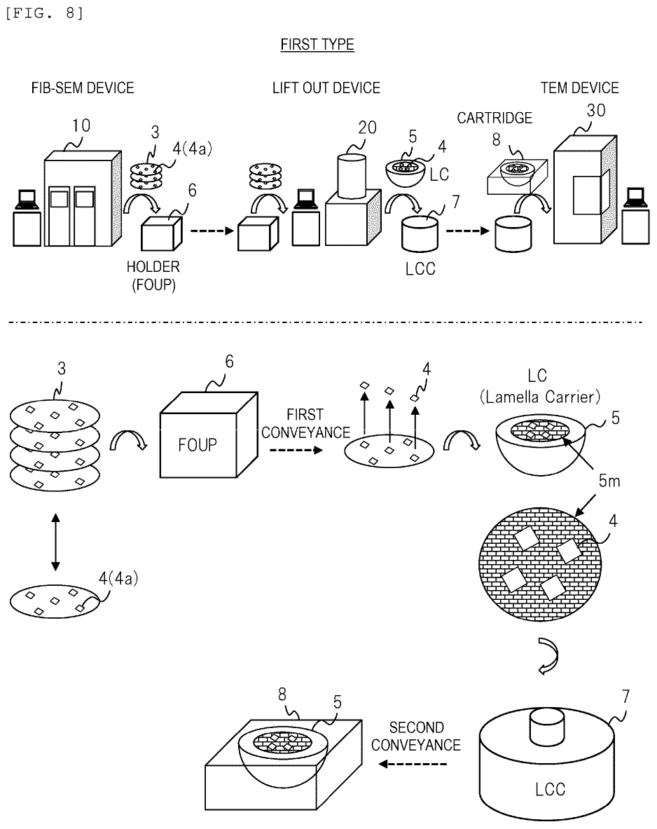

FIG. 8 illustrates a configuration example of the carrier 5 and the like in the inspection processing sequence of the first type inspection system 1 of FIG. 6. In the first step, one or more thin piece portions 4a are formed on a surface of the wafer 3 by the FIB-SEM device 10. The wafer 3 on which the thin piece portion 4a is formed is stored in, for example, a front opening unified pod (FOUP) serving as the holder 6. For example, 20 to 30 wafers 3 can be stored in one FOUP. The FOUP is conveyed to the lift out device 20.

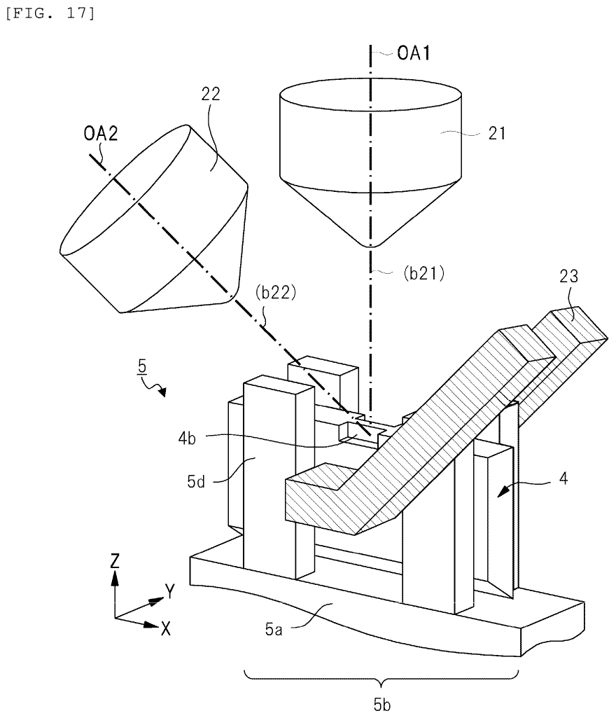

The lift out device 20 in the second step takes out the thin piece 4 from the wafer 3 using the attaching and detaching device 23, and transfers the taken-out thin piece 4 onto a mesh 5m of a lamella carrier (LC) which is the carrier 5. At this time, the thin piece 4 is inserted into, for example, a pillar on the mesh 5m (see FIG. 17 and the like to be described later). The LC which is the carrier 5 is further stored in a lamella carrier container (LCC) 7. For example, eight LCs can be stored in one LCC 7. The LCC 7 is conveyed to the TEM device 30. In the TEM device 30, the LC which is the carrier 5 is transferred from the LCC 7 to the cartridge 8 for TEM, and the cartridge 8 is loaded and set inside the TEM device 30.

### Configuration Example of Carrier and the Like in Second Type

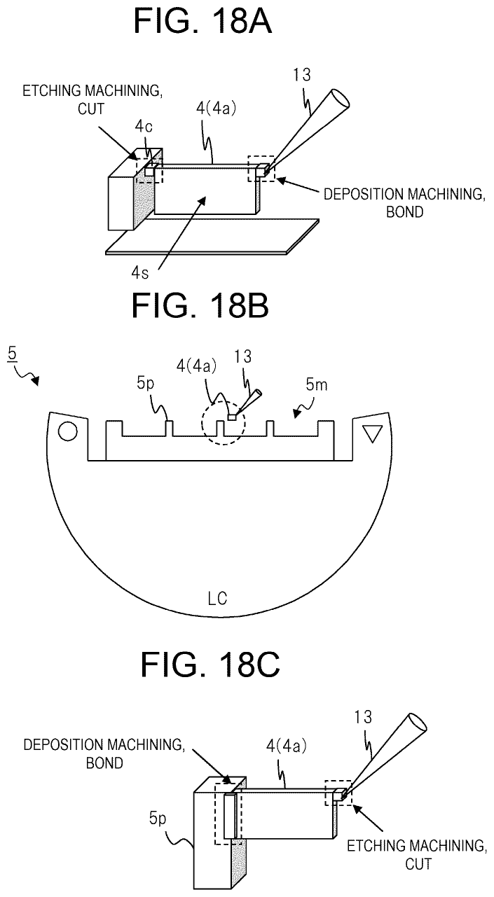

FIG. 9 illustrates a configuration example of the carrier 5 and the like in the inspection processing sequence of the second type inspection system 1 of FIG. 7. In the first step, the first type FIB-SEM device 10 forms one or more thin piece portions 4a up to a state immediately before the final finishing on a surface of the wafer 3. The first type FIB-SEM device 10 cuts out the thin piece portion 4a from the wafer 3 and transfers the cut-out thin piece portion 4a onto the mesh 5 m of the LC which is the carrier 5. At this time, the thin piece portion 4a that remains to be finished is bonded to, for example, the pillar on the mesh 5 m (see FIG. 18 to be described later). The LC which is the carrier 5 is stored in the LCC 7. The LCC7 is conveyed to the second type FIB-SEM device 20.

The second type FIB-SEM device 20 in the second step performs final finishing on the thin piece 4 on the carrier 5. The LCC7 that stores the carrier 5 (LC) on which the thin piece 4 after the final finishing is mounted is conveyed to the TEM device 30. Similarly, in the TEM device 30, the LC which is the carrier 5 is transferred from the LCC 7 to the cartridge 8 for TEM, and the cartridge 8 is loaded and set inside the TEM device 30.

### Thin Piece Production Device: FIB-SEM Device

FIG. 10 illustrates a configuration example of the FIB-SEM device 10 that can be applied as the thin piece production device 10 in the first step in the first type or second type inspection system 1. The FIB-SEM device 10 in FIG. 10 is a device including both an FIB mechanism and an SEM mechanism. The FIB-SEM device 10 can form the thin piece 4 on the wafer 3 using the FIB mechanism, and can image and observe the wafer 3 and the thin piece 4 using the SEM mechanism.

The FIB-SEM device 10 in FIG. 10 includes a sample chamber 107, the ion beam column 11, an ion beam column controller 131, the electron beam column 12, an electron beam column controller 132, a wafer stage 104, a wafer stage controller 134, a sub stage 106, a sub stage controller 136, a probe unit 112, a probe unit controller 142, and the like. The FIB-SEM device 10 includes charged particle detectors 109 and 110, detector controllers 139 and 140, an X-ray detector 111, an X-ray detector controller 141, an integrated control unit 130, a computer system 100, and the like.

The ion beam column 11 and the electron beam column 12 are mounted in the sample chamber 107. The ion beam column 11 is disposed along a Z-axis direction in which an optical axis (indicated by a one-dot chain line) is a vertical direction. The electron beam column 12 is disposed along a direction in which an optical axis (indicated by a one-dot chain line) is inclined with respect to the optical axis of the ion beam column 11. The ion beam b11 which is an FIB is emitted from the ion beam column 11 toward a cross point CP1, and the electron beam b12 is emitted from the electron beam column 12 toward the cross point CP1. The ion beam b11 emitted from the ion beam column 11 and the electron beam b12 emitted from the electron beam column 12 are focused at the cross point CP1 which is an intersection of the respective optical axes. In this example, the optical axis of the electron beam column 12 is inclined relative to the optical axis of the ion beam column 11, but the invention is not limited to such a configuration.

The ion beam column 11 includes components necessary for the FIB device, such as an ion source for generating the ion beam b11, a lens for focusing the ion beam b11, a deflection system for performing scanning using the ion beam b11, and a blanking deflection system for blanking the ion beam b11.

The electron beam column 12 includes components necessary for the SEM device, such as an electron source for generating the electron beam b12, a lens for focusing the electron beam b12, a deflection system for performing scanning using the electron beam b12, and a blanking deflection system for blanking the electron beam b12.

The wafer stage 104 is a moving stage on which the wafer 3 serving as a sample can be placed. The sub stage 106 is a moving stage on which the thin piece 4 or the carrier 5 can be placed. The wafer stage 104 and the like can perform planar movement and rotational movement. The integrated control unit 130 controls the movement of the wafer stage 104 via the wafer stage controller 134 to position the wafer stage 104 so that a target portion (for example, a portion where the thin piece 4 is formed) on the surface of the wafer 3 can be irradiated with a beam.

The charged particle detector 109 detects charged particles generated when a sample is irradiated with the ion beam b11 as a detection signal. The charged particle detector 110 detects charged particles generated when a sample is irradiated with the electron beam b12 as a detection signal. The detector controller 139 performs calculation processing on the detection signal of the charged particle detector 109 to form an image. The detector controller 140 performs calculation processing on the detection signal of the charged particle detector 110 to form an image. The detector controllers 139 and 140 includes a calculation processing unit implemented by a circuit or program processing.

The probe unit 112 picks up the thin piece portion 4a formed on the wafer 3 by a probe under control of the probe unit controller 142. In the case of the second type, the probe unit 112 may be, for example, a mechanism that drives a needle 13 in FIG. 18.

The sample chamber 107 includes, as other components, a gas supply unit (not illustrated) that supplies a gas used for etching or deposition machining. The sample chamber 107 may include, as other types of detectors, a backscattered electron detector that detects backscattered electrons generated from a sample.

The thin piece production device 10 is not limited to the FIB-SEM device as described above, and an FIB device not including the SEM mechanism may be applied, or an FIB device including an optical microscope instead of the SEM mechanism may be applied.

The integrated control unit 130 controls the entire and each unit of the FIB-SEM device 10. The integrated control unit 130 is electrically connected to a controller of each unit such as the wafer stage controller 134, and can communicate with the controller. The integrated control unit 130 controls the controller and the like of each unit using a control signal. A plurality of controllers may be integrated as one controller. Each controller may be implemented by a computer system, a dedicated circuit, or the like. The computer system 100 is connected to the integrated control unit 130. The integrated control unit 130 controls the entire and an operation of each unit of the FIB-SEM device 10 according to an instruction or the like from the computer system 100.

The computer system 100 provides a user interface including a GUI to a user who uses the FIB-SEM device 10, and receives input of various instructions, settings, and the like by the user. An input device 162, an output device 161, a storage device, and the like are built in or externally connected to the computer system 100. Examples of the input device 162 include a keyboard, a mouse, a touch panel, and a microphone. Examples of the output device 161 include a display, a printer, a speaker, and a lamp. A screen with a GUI is displayed on the display. An image captured by the FIB-SEM device 10, setting information, user instruction information, and the like are displayed on the screen.

A user such as a worker can check various kinds of information, images, and the like on the screen displayed on the display. The user inputs various instructions and settings to the screen using a keyboard or the like. The computer system 100 transmits an instruction or the like to the integrated control unit 130 based on the input instruction, setting, or the like.

The integrated control unit 130 and the computer system 100 may be integrated. The controller 10C in FIG. 1 may be the same as the integrated control unit 130 or the computer system 100, or may be another computer system connected to the integrated control unit 130 or the computer system 100.

The same FIB-SEM device as described above can also be applied to the second type FIB-SEM device 20 (10B) in the second type.

### Thin Piece Transfer Device: Lift Out Device

FIG. 11 illustrates a configuration example of the lift out device 20 that can be applied as the thin piece conveyance device 20 in the second step in the first type inspection system 1.

The lift out device 20 includes the sample chamber 207, and the sample chamber 207 is provided with the electron beam column 21 serving as a first column, the electron beam column 22 serving as a second column, the attaching and detaching device 23, a movable stage 24, a rotation stage 25 for the wafer 3, a rotation stage 26 for the carrier 5, a charged particle detector 27, and the like. Although details are omitted, a holder for holding the wafer 3 is provided on the rotation stage 25, and a holder for holding the carrier 5 is provided on the rotation stage 26.

The electron beam column 21 which is the first column includes all components necessary for the SEM device, such as an electron source 21a for generating a charged particle beam b21 which is an electron beam b21, condenser lenses 21b and 21c for focusing the electron beam b21, an objective lens 21d, and a deflector 21e for performing scanning using the electron beam b21. The electron source 21a, the condenser lenses 21b and 21c, the objective lens 21d, and the deflector 21e are electrically connected to a controller 206 through a drive control unit (not illustrated). An operation of the electron beam column 21 is controlled by transmitting a control signal from the controller 206 to each drive control unit.

The electron beam column 22 which is the second column includes all components necessary for the SEM device, such as an electron source 22a for generating a charged particle beam which is an electron beam b22, condenser lenses 22b and 22c for focusing the electron beam b22, an objective lens 22d, and a deflector 22e for performing scanning using the electron beam b22. The electron source 22a, the condenser lenses 22b and 22c, the objective lens 22d, and the deflector 22e are electrically connected to a controller 212 through a drive control unit (not illustrated). An operation of the electron beam column 22 is controlled by transmitting a control signal from the controller 212 to each drive control unit.

The electron beam column 22 is mounted in the sample chamber 207 at an angle different from that of the electron beam column 21. The electron beam column 21 is disposed in a Z-axis direction which is a vertical direction in the drawing, and the electron beam column 22 is disposed in a direction inclined relative to the Z-axis direction. Therefore, the electron beam b22 is emitted at an angle different from that of the electron beam b21. The electron beam b21 emitted from the electron beam column 21 and the electron beam b22 emitted from the electron beam column 22 are mainly focused on a cross point CP2 which is an intersection of an optical axis OA1 of the electron beam column 21 and an optical axis OA2 of the electron beam column 22.

The movable stage 24 is provided in the sample chamber 207. The rotation stage 25 and the rotation stage 26 are coupled to the movable stage 24. The integrated control unit 230 controls the movement of the movable stage 24 and the like through a controller 213 to position the electron beam b21 and the electron beam b22 so that a target position of a surface of the wafer 3 is irradiated with the beams. The movable stage 24 including the rotation stage 25 and the rotation stage 26 is a moving stage that can perform planar movement, vertical movement, rotational movement, and inclined movement based on drive control.

The detector 27 detects charged particles generated when the wafer 3 or the thin piece 4 is irradiated with the electron beam b21 and the electron beam b22. The detector 27 is electrically connected to a controller 214. The detector 27 is driven and controlled by the controller 214. The controller 214 includes a calculation processing unit that performs calculation processing on a detection signal from the detector 27 to form an image. The calculation processing unit is implemented by a circuit or program processing. The sample chamber 207 may be provided with an X-ray detector, a backscattered electron detector, or the like for detecting X-rays, backscattered electrons, or the like generated from the thin piece 4.

The attaching and detaching device 23 is provided in the sample chamber 207 as a mechanism that can reach the cross point CP2. The attaching and detaching device 23 is electrically connected to a controller 215. The attaching and detaching device 23 is driven and controlled by the controller 215. By driving the attaching and detaching device 23, the thin piece 4 can be taken out from the wafer 3 and the thin piece 4 can be transferred to the carrier 5. Further, the attaching and detaching device 23 can perform planar movement, vertical movement, and rotational movement based on drive control. Therefore, when the attaching and detaching device 23 holds the thin piece 4, an orientation of the thin piece 4 can be freely changed. For example, nano-tweezers are applied as the attaching and detaching device 23.

A degree of vacuum inside the sample chamber 207 is controlled by a controller 216. The sample chamber 207 may be provided on a vibration-proof table 209 in order to prevent vibration. The sample chamber 207 may be further provided with a pressure reduction device for evacuation, a cold trap, an optical microscope, and the like.

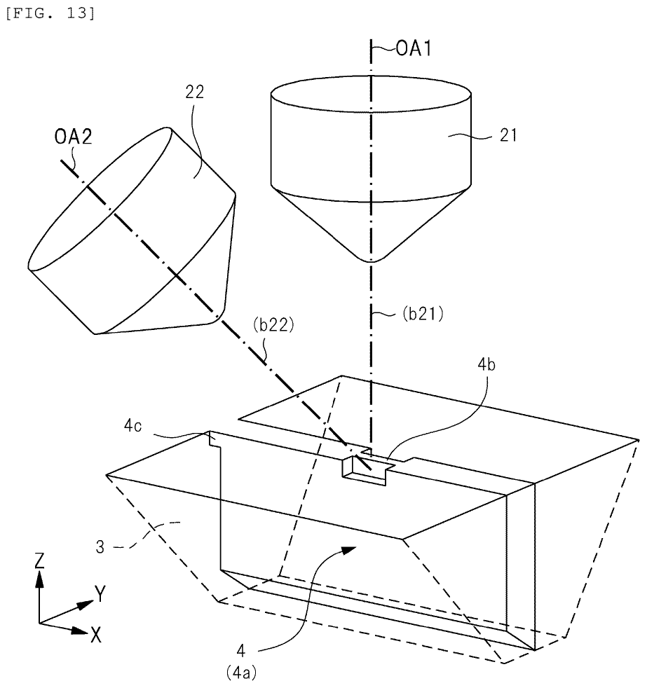

Since the lift out device 20 in FIG. 11 includes the electron beam columns 21 and 22 installed in different optical axis directions, it is possible to monitor and grasp a three-dimensional positional relation or the like among the wafer 3, the thin piece 4, the carrier 5, the attaching and detaching device 23, and the like, and to perform an accurate and efficient processing operation (see FIG. 13 and the like to be described later).

The integrated control unit 230 controls the entire and each unit of the lift out device 20. The integrated control unit 230 is electrically connected to a controller of each unit such as the controller 213, and can communicate with the controller. The integrated control unit 230 controls the controller and the like of each unit using a control signal. A plurality of controllers may be integrated as one controller. Each controller may be implemented by a computer system, a dedicated circuit, or the like. A computer system 200 is connected to the integrated control unit 230. The integrated control unit 230 controls the entire and an operation of each unit of the lift out device 20 according to an instruction or the like from the computer system 200.

The computer system 200 provides a user interface including a GUI to a user who uses the lift out device 20, and receives input of various instructions, settings, and the like by the user. An input device 262 such as a keyboard, an output device 261 such as a display, a storage device, and the like are built in or externally connected to the computer system 200. A screen with a GUI is displayed on the display. An image captured by the lift out device 20, setting information, user instruction information, and the like are displayed on the screen.

A user such as a worker can check various kinds of information, images, and the like on the screen displayed on the display. The user inputs various instructions and settings to the screen using a keyboard or the like. The computer system 200 transmits an instruction or the like to the integrated control unit 230 based on the input instruction, setting, or the like.

The integrated control unit 230 and the computer system 200 may be integrated. The controller 20C in FIG. 1 may be the same as the integrated control unit 230 or the computer system 200, or may be another computer system connected to the integrated control unit 230 or the computer system 200.

The invention is not limited to the configuration example of the lift out device 20 in FIG. 11. For example, an optical microscope may be provided instead of the electron beam columns 21 and 22. In the configuration example in FIG. 11, the processing operation can be performed in a sealed space in the sample chamber 207, but the invention is not limited thereto, and the sample chamber 207 may be omitted and the processing operation may be performed in the atmosphere.

### Thin Piece Observation Device: TEM device

FIG. 12 illustrates a configuration example of the TEM device 30 that can be applied as the thin piece observation device 30 in the third step in the first type or second type inspection system 1. The TEM device 30 in FIG. 12 includes an electron beam column 31, an electron beam column controller 32, a sample holder 303 on which the carrier 5 can be placed, a sample holder stage 304, a sample holder stage controller 324, a secondary electron detector 305, a detector controller 325, an X-ray detector 308, an X-ray detector controller 328, and the like. The secondary electron detector 305 and the like correspond to the detector 32 in (C) of FIG. 5.

In addition, the TEM device 30 includes a fluorescent plate 306, a camera 307, a camera controller 327, and the like installed below the electron beam column 31. The TEM device 30 includes an integrated control unit 330 connected to each controller, a computer system 300 connected to the integrated control unit 330, and the like. A keyboard 362 as an input device and a display 361 as an output device are connected to the computer system 300.

The fluorescent plate 306 is a fluorescent plate that projects a TEM image which is a transmission electron microscope image. The camera 307 is a camera that images the fluorescent plate 306.

The secondary electron detector 305 detects, as P detection signal, particles such as secondary electrons emitted from the thin piece 4 on the carrier 5 serving as a sample. The X-ray detector 308 detects, as a detection signal, X-rays emitted from the thin piece 4 on the carrier 5 serving as a sample.

The integrated control unit 330 controls the entire and each unit of the TEM device 30. The integrated control unit 330 is electrically connected to a controller of each unit such as a controller 321, and can communicate with the controller. The integrated control unit 330 controls a controller and the like of each unit using a control signal. A plurality of controllers may be integrated as one controller. Each controller may be implemented by a computer system, a dedicated circuit, or the like. A computer system 300 is connected to the integrated control unit 330. The integrated control unit 330 controls the entire and an operation of each unit of the TEM device 30 according to an instruction or the like from the computer system 300.

The computer system 300 provides a user interface including a GUI to a user who uses the TEM device 30, and receives input of various instructions, settings, and the like by the user. An input device 362 such as a keyboard, an output device 361 such as a display, a storage device, and the like are built in or externally connected to the computer system 300. A screen with a GUI is displayed on the display. An image captured by the TEM device 30, setting information, user instruction information, and the like are displayed on the screen.

A user such as a worker can check various kinds of information, images, and the like on the screen displayed on the display. The user inputs various instructions and settings to the screen using a keyboard or the like. The computer system 300 transmits an instruction or the like to the integrated control unit 330 based on the input instruction, setting, or the like.

The integrated control unit 330 and the computer system 300 may be integrated. The controller 30C in FIG. 1 may be the same as the integrated control unit 330 or the computer system 300, or may be another computer system connected to the integrated control unit 330 or the computer system 300.

The electron beam column 31 may be configured to, for example, support both a TEM mode and an STEM mode. The electron beam column 31 includes an electron source, an irradiation lens group, an objective lens, a projection lens group, and the like as a configuration example corresponding to the TEM mode. An electron energy loss spectrometer (EELS), an EELS detector, and the like are provided below the electron beam column 31. In the TEM mode, the above-described analysis portion 4b (FIG. 5) on a front surface (main surface on which a cross-sectional structure is formed) of the thin piece 4 on the carrier 5 placed on the sample holder 303 is set as an observation region, and the electron beam b31 (only an optical axis is indicated by a one-dot chain line) emitted by the electron beam column 31 is emitted to spread over the entire observation region. The TEM device 30 acquires a projection image, an interference image, a diffraction pattern, and the like generated by the irradiation of the electron beam b31 as a TEM image.

As a configuration example corresponding to the STEM mode, the electron beam column 31 is provided with a polarization system for performing scanning using an electron beam, a diaphragm for controlling an opening angle of the electron beam, and the like, in addition to the components in the TEM mode. In the configuration of the STEM mode, an annular detector for detecting transmitted electrons scattered at a wide angle and a transmitted electron detector for detecting electrons transmitted through a sample are provided instead of the fluorescent plate 306. In the case of the STEM mode, a TEM image is acquired by focusing the electron beam on the thin piece 4 and scanning the analysis portion 4b which is the observation region.

A cold trap, a cooling mechanism, a heating mechanism, a gas supply mechanism, or the like may be provided in the vicinity of the sample (thin piece 4 on the carrier 5) in the sample holder 303 of FIG. 12.

### Structure Example of Thin Piece

FIG. 13 illustrates an example of a detailed structure of the thin piece 4. For example, FIG. 13 illustrates a state of the thin piece 4 and the like when the thin piece 4 is taken out while the thin piece 4 formed on the wafer 3 is observed in the lift out device 20 (FIG. 11 or the like) in the second step in the first type inspection system 1. FIG. 13 schematically illustrates an example of an arrangement of the electron beam column 21 and the electron beam column 22 relative to the thin piece portion 4a on the wafer 3. In the drawings, (X, Y, Z) or the like may be used as a coordinate system for description. An X axis and a Y axis are two orthogonal axes constituting a horizontal plane direction. A Z axis is a vertical direction perpendicular to the X axis and the Y axis.

The thin piece portion 4a as illustrated is formed on a surface of the wafer 3 by the FIB-SEM device 10 in the first step. A state in which the thin piece 4 is not yet separated from the wafer 3 may be referred to as the thin piece portion 4a. In FIG. 13, a part of the surface of the wafer 3 where the thin piece portion 4a is formed is schematically illustrated as a perspective view. The thin piece 4 has a width and a thickness in the Y direction smaller than a width and a thickness in the X direction and a width and a thickness in the Z direction. In the thin piece 4, the analysis portion 4b is provided at an upper portion in the Z direction and a central portion in the X direction. The analysis portion 4b is a region to be observed by the thin piece observation device 30. As illustrated in the drawing, a width and a thickness of the analysis portion 4b in the Y direction are smaller than a width and a thickness of a portion of the thin piece 4 around the analysis portion 4b.

The analysis portion 4b is formed to be thinner than a main body of the thin piece 4, but is not limited thereto, and may have any thickness as long as the TEM image observation can be performed. A size of the wafer 3 is, for example, 100 mm to 300 mm, a size of the thin piece 4 is, for example, several um to several tens of μm, a thickness of the thin piece 4 is, for example, several μm, and a thickness of the analysis portion 4b is, for example, several nm to several tens of nm.

In Embodiment 1, a surface viewed from above in the Z direction may be described as an upper surface of each of the thin piece 4 and the analysis portion 4b, and a surface viewed from the front in the Y direction may be described as a front surface of each of the thin piece 4 and the analysis portion 4b. Surfaces viewed from the X direction are a right side surface and a left side surface of the thin piece 4, a surface viewed from below in the Z direction is a bottom surface of the thin piece 4, and a surface viewed from the rear in the Y direction is a back surface of each of the thin piece 4 and the analysis portion 4b. The perspective view of FIG. 13 mainly illustrates the front surface, the right side surface, the upper surface, and the tapered bottom surface of the thin piece 4.

### Example (1) of Processing Operation of Transferring Thin Piece

As illustrated in FIG. 13, in a state before the thin piece portion 4a is taken out, the thin piece 4 is coupled to the wafer 3 by a part of a coupling portion 4c, and the thin piece portion 4a, the coupling portion 4c, and the wafer 3 are integrated. Alternatively, one thin piece portion 4a may be connected by a plurality of coupling portions 4c. When the thin piece 4 is transferred by the lift out device 20, the thin piece 4 is gripped by the attaching and detaching device 23 and is cut out at the coupling portion 4c, thereby separating the thin piece 4 from the wafer 3.

The wafer 3 is placed on the rotation stage 25 in FIG. 11 such that an upper surface of the thin piece 4 faces the electron beam column 21 and a front surface of the thin piece 4 faces the electron beam column 22. In this state, the electron beam b21 is emitted from the electron beam column 21 along a direction of the optical axis OA1 (downward direction of the Z axis), and the electron beam b22 is emitted from the electron beam column 22 along a direction of the optical axis OA2 (inclined direction relative to the Z axis). The cross point CP2 in FIG. 11 is on the analysis portion 4b in FIG. 13.

In FIG. 13, the electron beam b21 of the electron beam column 21 is emitted perpendicularly to the upper surface of the thin piece 4. Since the electron beam column 22 is installed at an angle different from that of the electron beam column 21, the thin piece 4 is irradiated with the electron beam b22 at an angle different from that of the electron beam b21, and in FIG. 13, the front surface of the thin piece 4 is irradiated with the electron beam b22 from an oblique direction. Charged particles generated from the thin piece 4 based on the irradiation are detected as a detection signal by the detector 27 in FIG. 11, and the detection signal is converted into an image by a calculation processing device provided in a control unit 214. Accordingly, an SEM image of a top view and an SEM image of a side view are acquired.

In the SEM image of the top view obtained by the electron beam column 21, mainly a thickness of the analysis portion 4 b and a thickness of the entire thin piece 4 can be inspected. In the SEM image of the side view obtained by the electron beam column 22, mainly whether there is a damaged portion, foreign matter adhesion, or the like in the thin piece 4 can be inspected. In addition, in the SEM image of the side view, a rough structure of a device formed in the analysis portion 4b can be observed. Each SEM image obtained here is stored in the storage device of the computer system 200.

As described above, in the lift out device 20, it is possible to perform simple inspection and quality determination for the thin piece 4 by using two SEM images obtained by two electron beam columns. As a result of the inspection, the thin piece 4 is classified into a non-defective product and a defective product. The defective product is, for example, the thin piece 4 that is not suitable for observation in the TEM device 30 and has a damaged portion or foreign matter adhesion. The thin piece 4 determined as a non-defective product is taken out, but the thin piece determined as a defective product is left. The inspection and the quality determination may be automatically performed by the lift out device 20 or may be manually performed by a user.

Next, while checking the SEM image obtained by the electron beam column 21 or the electron beam column 22, the lift out device 20 moves the attaching and detaching device 23 above the thin piece 4 determined to be a non-defective product using the controller 215. The lift out device 20 lowers the attaching and detaching device 23 and brings a tip end of the attaching and detaching device 23 into contact with the thin piece 4. Here, the lift out device 20 can check a height of the attaching and detaching device 23 according to the SEM image of the side view obtained by the electron beam column 22, and can check that the attaching and detaching device 23 is brought into contact with the thin piece 4 according to the SEM image of the top view obtained by the electron beam column 21. Further, the lift out device 20 operates the attaching and detaching device 23 so that the analysis portion 4b is not gripped.

### Example (2) of Processing Operation of Transferring Thin Piece

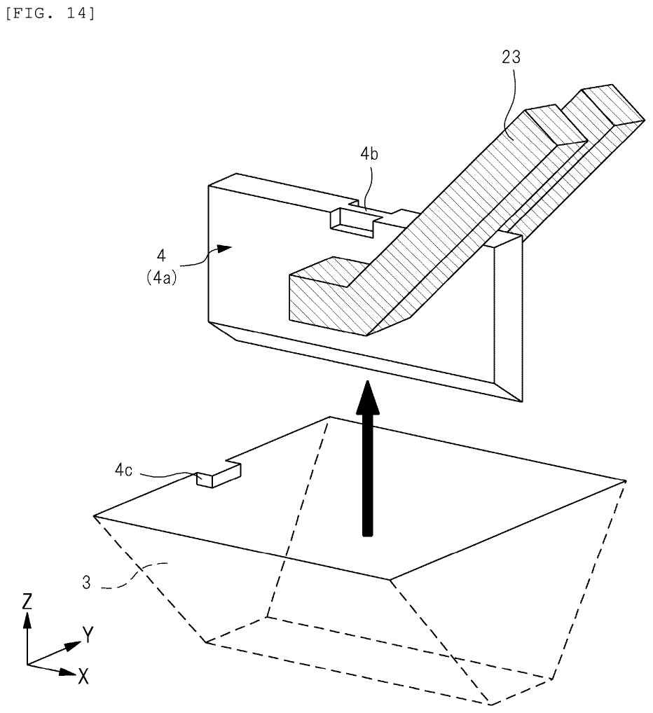

Next, the lift out device 20 takes out the thin piece 4 from a part of the wafer 3. FIG. 14 illustrates a state in which the lift out device 20 grips and takes out the thin piece 4 from a part of the wafer 3 with the tip end of the attaching and detaching device 23. At this time, the lift out device 20 separates the thin piece 4 from the wafer 3 by cutting out the thin piece 4 at the coupling portion 4c by raising the attaching and detaching device 23 in a state in which the thin piece 4 (portion other than the analysis portion 4b) is held by the attaching and detaching device 23. Alternatively, the thin piece conveyance device 20 may separate the thin piece 4 from the wafer 3 by cutting out the thin piece 4 at the coupling portion 4c by lowering the movable stage 24. Accordingly, the thin piece 4 is lifted off from the wafer 3. The method described above (generic term including a method, a system, a mechanism, and the like) is a lift out method. In the first type inspection system 1, the thin piece 4 is taken out from the wafer 3 and transferred to the carrier 5 by the above-described lift out method.

Next, the lift out device 20 acquires an SEM image of the thin piece 4 in a state in which the thin piece 4 is held by the attaching and detaching device 23. Thereafter, the lift out device 20 may perform secondary quality determination as a simple inspection on the thin piece 4 based on the acquired SEM image.

### Example (3) of Processing Operation of Transferring Thin Piece

According to the characteristics of the SEM device, when a working distance (WD) between the thin piece 4 and the objective lens 22d is short, an image with higher resolution can be obtained. In order to use this characteristic, the lift out device 20 may perform the following operation.

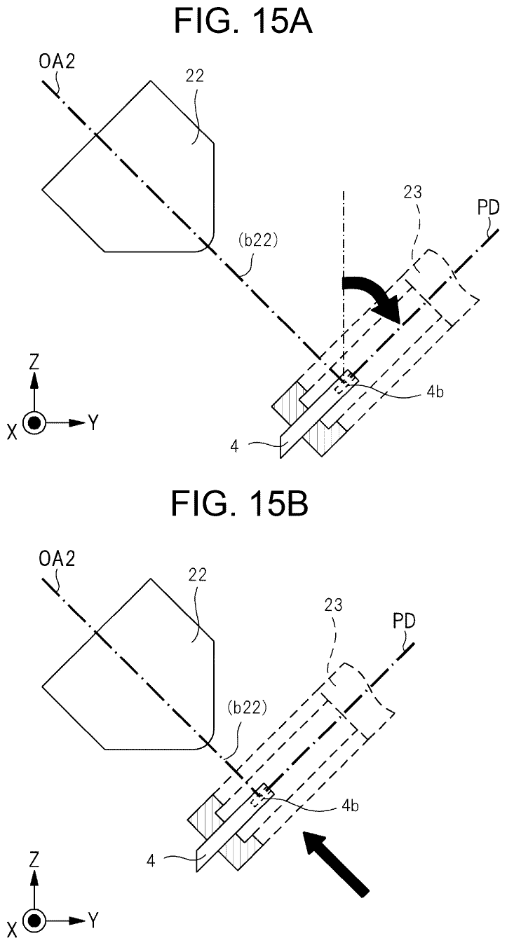

FIG. 15 illustrates an operation example when a suitable SEM image is imaged by the electron beam column 22 by moving the thin piece 4 using the attaching and detaching device 23 in the lift out device 20. In a state in which the thin piece 4 is held by the attaching and detaching device 23 as illustrated in (A), the lift out device 20 rotates the attaching and detaching device 23 so that the front surface of the analysis portion 4b is perpendicular to an irradiation direction of the electron beam b22 as illustrated in the drawing. The PD is an axis of the attaching and detaching device 23, and the thin piece portion 4a is disposed along the axis. A direction of the optical axis OA2 of the electron beam b22 is perpendicular to the axis.

Subsequently, as illustrated in (B), the lift out device 20 moves the attaching and detaching device 23 in parallel in the direction of the optical axis OA2 to bring the front surface of the analysis portion 4b closer to the electron beam column 22. In this manner, the WD between the thin piece 4 and the objective lens 22d is adjusted to an appropriate distance. Accordingly, a high-resolution SEM image can be obtained by the electron beam column 22.

Further, the lift out device 20 may perform secondary quality determination on the thin piece 4 using the SEM image in the state as illustrated in FIG. 15. The secondary quality determination is performed with a higher resolution than primary quality determination. A device structure formed in the analysis portion 4b is observed as a more detailed SEM image than the primary quality determination. The SEM image obtained here is stored in the storage device of the computer system 200. The secondary quality determination may also be automatically performed by the lift out device 20 or may be manually performed by a user.

As a result of the inspection and the secondary quality determination as described above, the thin piece 4 determined as a non-defective product is transferred to the carrier 5, and the thin piece 4 determined as a defective product is stored in a defective product storage place.

### Structure Example of Carrier

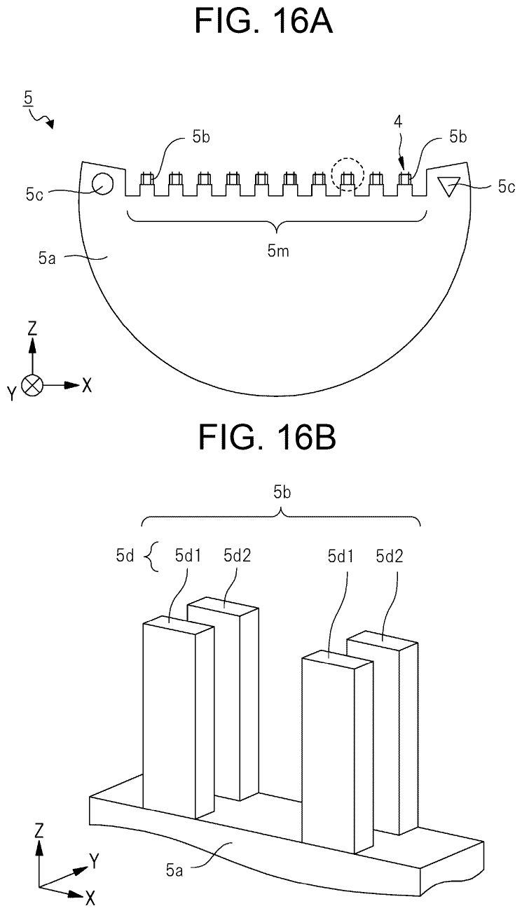

FIG. 16 illustrates a structure example of the carrier 5 used when the thin piece 4 is transferred to the carrier 5 by the lift out device 20 in the first type inspection system 1. (A) of FIG. 16 is a longitudinal cross section view illustrating the carrier 5 which is an LC. The carrier 5 which is an LC may be referred to as a lamellar grid, a TEM mesh, or the like. The carrier 5 includes a half-moon shaped base body 5a and a plurality of support portions 5b protruding upward from a surface of the base body 5a in the Z direction. The mesh 5m includes a plurality of support portions 5b. Each support portion 5b is a thin piece support portion having a structure capable of mounting and holding the thin piece 4.

The base body 5a including the plurality of support portions 5b may be formed of one material such as silicon, but a portion of the base body 5a where the plurality of support portions 5b are provided and the periphery thereof may be formed of a material different from a material for forming the base body 5a. For example, most of the base body 5a may be made of copper, and the plurality of Support portions 5b and the periphery thereof may be made of silicon.

At both ends (circumferential portions in a plan view of an upper surface of the carrier 5) of the base body 5a where the support portion 5b is not provided, marks 5c implemented by holes penetrating the base body 5a are provided. The marks 5c are provided as marks having different shapes, and here, the marks 5c having a circular shape and a triangular shape are exemplified. The marks 5c facilitate identification of the front and rear of the carrier 5. In addition, when a position of the support portion 5b to which the thin piece 4 is to be transferred is determined, the desired support portion 5b can be searched for with reference to the marks 5c, and a transfer position can be easily specified.

(B) of FIG. 16 illustrates a structural example of the support portion 5b. (B) illustrates a state in which the thin piece 4 is not mounted on the support portion 5b. In this example, one support portion 5b is implemented by four pillars 5d {5d1, 5d2, 5d3, 5d4} as pillars (support columns) 5d protruding upward from the base body 5a. The pillar 5d1 and the pillar 5d2 are separated from each other in the Y direction, and the pillar 5d3 and the pillar 5d4 are separated from each other in the Y direction. The pillar 5d1 and the pillar 5d2 are separated from the pillar 5d3 and the pillar 5d4 in the X direction. A separation distance between the pillars are designed as distances for supporting the thin piece 4.

In one carrier 5, a plurality of, for example, 4 to 20 such support portions 5b are provided in a mesh shape on the mesh 5m on an X-Y plane. Although a case where a shape of the pillar 5d is a quadrangular prism is illustrated, the shape may be any shape that can hold the thin piece 4, and may be a polygonal prism, a cylindrical body, or the like. The invention is not limited to the example illustrated in FIG. 16, and only one end of the thin piece 4 may be held by a pillar pair. In a configuration in which the pillar 5d is raised in the Z direction, a plurality of thin pieces 4 may be inserted and held in the Z direction by one support portion 5b.

### Example (4) of Processing Operation of Transferring Thin Piece

In the lift out device 20, a processing operation of transferring the thin piece 4 determined as a non-defective product to the carrier 5 is performed as follows. At the time of transfer, the thin piece 4 is inserted and held in the support portion 5b as illustrated in FIG. 16 by the attaching and detaching device 23 as illustrated in FIG. 17.

The lift out device 20 causes the controller 213 to move the movable stage 24 so that the carrier 5 is disposed at the center of a top view SEM image. At this time, the lift out device 20 controls the rotation stage 26 and the movable stage 24 while checking a side view SEM image using the obliquely arranged electron beam column 22. In this manner, a desired position of the support portion 5b of the carrier 5 is determined.

The lift out device 20 moves the attaching and detaching device 23 that holds the thin piece 4 to a position above the desired support portion 5b while checking the top view SEM image using the vertically arranged electron beam column 21.

FIG. 17 illustrates a state in which the thin piece 4 is transferred by being inserted into the desired support portion 5b of the carrier 5 by the attaching and detaching device 23 in the lift out device 20. The lift out device 20 lowers the attaching and detaching device 23 that holds the thin piece 4 from the position above the desired support portion 5b until a bottom surface of the thin piece 4 comes into contact with or approaches the base body 5a. At this time, the lift out device 20 adjusts a height of the attaching and detaching device 23 and finely controls a posture of the thin piece 4 while checking the side view SEM image using the obliquely arranged electron beam column 22. In this manner, as illustrated in FIG. 17, the target thin piece 4 is inserted into the target support portion 5b. Specifically, one end of the thin piece 4 in the X direction is inserted and held between the pillar 5d1 and the pillar 5d2, and the other end of the thin piece 4 is inserted and held between the pillar 5d3 and the pillar 5d4.

The observation of the thin piece 4 in the TEM device 30 is performed for each thin piece 4 in a state in which a plurality of thin pieces 4 are mounted on the carrier 5. Therefore, the analysis portion 4b of the thin piece 4 is exposed without overlapping the pillar 5d of the support portion 5b in a plan view viewed from the Y direction so that the analysis portion 4b is not blocked by the support portion 5b.

After the insertion of the thin piece 4 as described above is completed, the lift out device 20 releases gripping of the attaching and detaching device 23 and retracts the attaching and detaching device 23. The lift out device 20 repeats the same processing operation for the other thin pieces 4 to be taken out from the wafer 3 and transferred to the carrier 5. The number of the thin pieces 4 that can be mounted on one carrier 5 is determined in advance as an allowable range. When the number of the thin pieces 4 mounted on one carrier 5 reaches the allowable range and there are subsequent other thin pieces 4, the lift out device 20 transfers the subsequent thin pieces 4 to the support portion 5b of another carrier 5. The carrier 5 on which the plurality of thin pieces 4 are transferred and mounted through the above processing operation and the wafer 3 at a transfer source are taken out from the sample chamber 207.

Thereafter, the taken-out carrier 5 is conveyed from the lift out device 20 to the TEM device 30 by the second conveyance step. Further, the taken-out wafer 3 may be returned to the manufacturing line if necessary, or may be discarded if unnecessary. In the TEM device 30 in the third step, the carrier 5 is set, and the TEM image observation for the analysis portion 4b of each thin piece 4 on the carrier 5 is performed.

### Thinning Machining and Transfer by Microsampling Method of Second Type

FIG. 18 illustrates a detailed example of a processing operation of thinning machining and transfer by the microsampling method by the first type FIB-SEM device 10 in the first step in the inspection processing sequence of the second type inspection system 1. First, as illustrated in (A), the first type FIB-SEM device 10 forms the thin piece portion 4a in a state immediately before the final finishing (in other words, remaining to be finished) by FIB machining on an inspection target portion of the wafer 3. A front surface 4s illustrated in the drawing indicates an observation target cross section.

Next, the first type FIB-SEM device 10 brings the needle 13 close to the thin piece portion 4a that remains to be finished. The needle 13 corresponds to a tip end of the probe unit 112 in FIG. 12. Next, the first type FIB-SEM device 10 performs deposition machining to bond the needle 13 to a part of the thin piece portion 4a that remains to be finished. Next, the first type FIB-SEM device 10 cuts the thin piece portion 4a from the wafer 3 by irradiating, with an FIB, the coupling portion 4c on an edge on a side opposite to such a bonding position to perform etching machining.

Next, as illustrated in (B), the first type FIB-SEM device 10 moves the cut-out thin piece portion 4a held by the needle 13 to a position of a pillar 5p to which the thin piece portion 4a is to be mounted, which is a predetermined position on the mesh 5m of the carrier 5 (LC) placed at a position different from the wafer 3. This movement can be implemented by moving a stage. Next, the first type FIB-SEM device 10 moves the needle 13 to bring the thin piece portion 4a close to the position of the pillar 5p on the mesh 5m.

Next, as illustrated in (C), the first type FIB-SEM device 10 performs deposition machining on a portion where the pillar 5p and the thin piece portion 4a are coupled to each other, thereby bonding the pillar 5p and the thin piece portion 4a to each other. Next, the first type FIB-SEM device 10 cuts off the needle 13 and the thin piece portion 4a by irradiating the bonding position between the thin piece portion 4a and the needle 13 with an FIB and performing etching machining, and separates the needle 13 from the thin piece portion 4a.

Through the above-described processing operation, the thin piece 4 is transferred and mounted in a manner of being supported by the pillar 5p on the mesh 5m of the carrier 5. The first type FIB-SEM device 10 performs the above-described processing operation the designated number of times and for the designated number of thin pieces 4a, and then unloads the LCC 7 that stores the LC which is the carrier 5. Although one thin piece 4 is fixed to one pillar 5p in the example illustrated in FIG. 18, the pillar 5p may be configured to be high, and a plurality of thin pieces 4 may be fixed to one pillar 5p.

In the automatic microsampling method as described above, the thin piece 4 is fixed to the pillar 5p by deposition machining or the like. The FIB-SEM device 10 can perform control while monitoring the above-described processing operation according to an SEM image. The success rate of the above-described transfer processing operation varies depending on the machine difference of the FIB-SEM device 10.

### Another Transfer Method

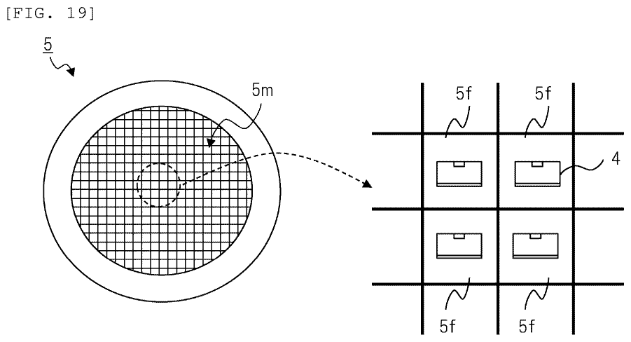

FIG. 19 illustrates a method for mounting the thin piece 4 in the mesh 5m of the carrier 5 as an example of another method related to the transfer of the thin piece 4 to the carrier 5. In FIG. 19, a part of the mesh 5m of the LC which is the carrier 5 in the X-Y plane in a plan view from above is enlarged and illustrated on a right side. As a portion constituting the mesh 5m, in other words, a lattice, for example, a plurality of quadrangular frames which are recesses 5f are provided. During the transfer, the thin piece 4 is placed in such a recess 5f of the mesh 5m. In the example of FIG. 19, one thin piece 4 is placed in one recess 5f with the front surface 4s facing upward.

### Cartridge of TEM Device

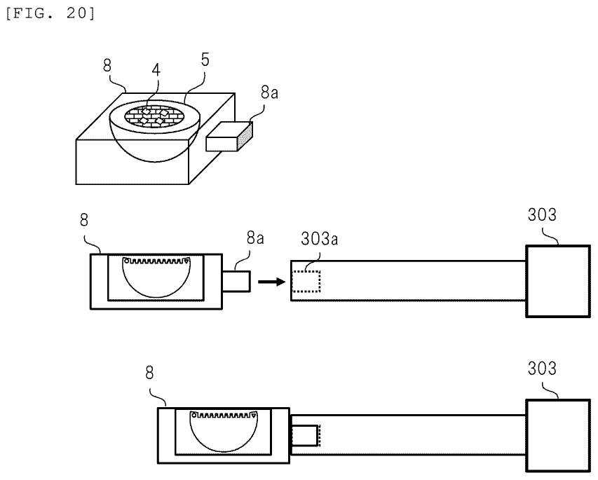

FIG. 20 illustrates a configuration example in which the cartridge 8 on which the carrier 5 is mounted is set in the sample holder 303 of the electron beam column 31 in the TEM device 30 (FIG. 12). The carrier 5 on which the thin piece 4 is mounted is set in the cartridge 8 as illustrated in the drawing. The cartridge 8 is provided with, for example, a protrusion 8a. For example, a recess 303a is provided at a tip end of the sample holder 303. The cartridge 8 is fixed by inserting the protrusion 8a of the cartridge 8 into the recess 303a at the tip end of the sample holder 303. Accordingly, the TEM device 30 holds the carrier 5 of the cartridge 8 by the sample holder 303. In this state, the TEM image observation is performed on the thin piece 4 on the carrier 5.

### Detection of Success/failure of Transfer

In any of the method illustrated in FIG. 13 and the like and the method illustrated in FIG. 18 and the like, a success rate of the processing operation related to the transfer of the thin piece 4 by the FIB-SEM device 10 or the lift out device 20 varies depending on the machine difference of the device. Since the FIB-SEM device 10 or the lift out device 20 can monitor the processing operation according to an image obtained using the SEM mechanism or the optical microscope as described above, it is also possible to determine and detect whether the transfer of the thin piece 4 has succeeded or failed. Further, the success/failure of the transfer of the thin piece 4 may be determined and detected by other technical means.

The management system 2 according to Embodiment 1 also grasps the success/failure of the processing operation of the transfer of the thin piece 4 in the FIB-SEM device 10 or the lift out device 20 based on the above-described technique, and calculates a success rate of the processing operation including the transfer in each device. Then, the management system 2 creates a suitable plan using the success rate (to be described later).

The technical means for detecting and grasping the success/failure of the processing operation of the transfer in the device of the inspection system 1 is not particularly limited, and examples thereof include the following. For example, since the FIB-SEM device 10 of FIG. 10 can perform monitoring using an SEM image, the FIB-SEM device 10 may determine and detect success/failure of transfer from the content of the SEM image. Similarly, since the lift out device 20 of FIG. 11 can perform monitoring using an SEM image, the lift out device 20 may determine and detect success/failure of transfer from the content of the SEM image. For example, in a case where the thin piece 4 or the like can be gripped by the probe unit 112 in FIG. 10 or the attaching and detaching device 23 in FIG. 11, but the thin piece 4 gripped by the probe unit 112 or the attaching and detaching device 23 falls and disappears from the SEM image, it can be determined as a failure. As another technical means, falling of the thin piece 4, breakage of the thin piece 4, or the like may be detected by a sensor device.

### Functional Block of Management System

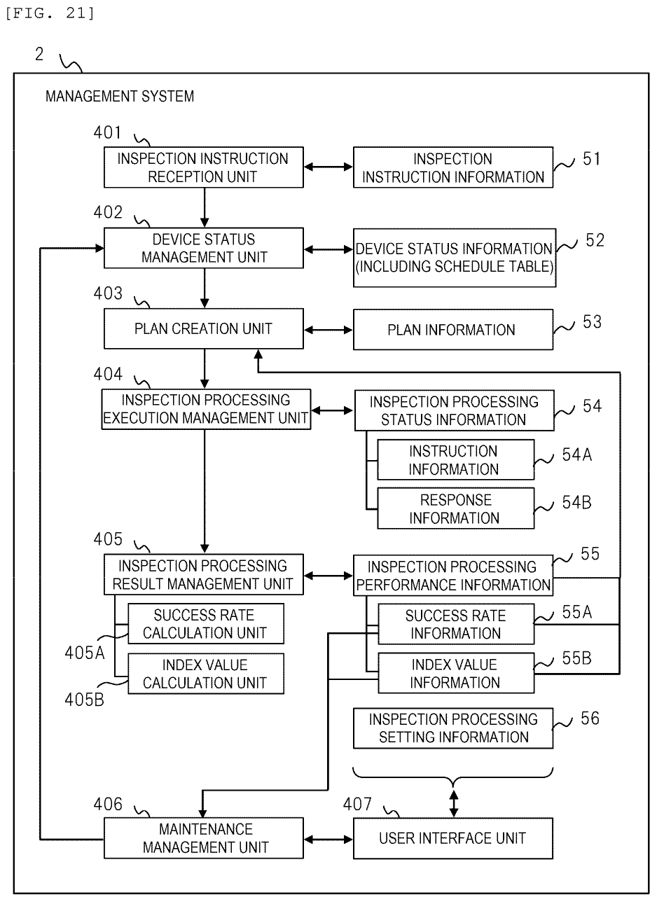

FIG. 21 illustrates a functional block configuration example of the management system 2 according to Embodiment 1. The management system 2 includes, as functional blocks, an inspection instruction reception unit 401, a device status management unit 402, a plan creation unit 403, an inspection processing execution management unit 404, an inspection processing result management unit 405, a maintenance management unit 406, and a user interface unit 407. As more detailed functional blocks, the inspection processing result management unit 405 includes a success rate calculation unit 405A and an index value calculation unit 405B. Each unit is implemented by, for example, program processing executed by the processor 1001 based on the configuration as illustrated in FIG. 3.

FIG. 21 also illustrates an example of data and information handled by each processing unit, which corresponds to those illustrated in FIG. 3. The inspection instruction reception unit 401 reads and writes the inspection instruction information 51 and the like. The device status management unit 402 reads and writes the device status information 52. The plan creation unit 403 reads and writes the plan information 53. The inspection processing execution management unit 404 reads and writes the inspection processing status information 54. The inspection processing status information 54 includes instruction information 54A and response information 54B. The inspection processing result management unit 405 reads and writes the inspection processing performance information 55 (in other words, inspection processing execution record data). The inspection processing performance information 55 includes success rate information 55A and index value information 55B.

The inspection instruction reception unit 401 receives an inspection instruction and inspection target portion information from the manufacturing management system in a plant, and stores and manages the inspection instruction and the inspection target portion information as the inspection instruction information 51. The device status management unit 402 stores and manages a status of each device of the inspection system 1 in FIG. 1 as the device status information 52. The device status management unit 402 stores and manages the configuration of the inspection system 1 including a plurality of devices as illustrated in FIG. 2 in the device status information 52 and inspection processing setting information 56. The configuration of the inspection system 1 includes configurations of a type and method of the inspection system 1 and the inspection processing sequence, a type, the number, and a model of a device, a user such as an associated worker, and the like.

The plan creation unit 403 creates a plan for inspection processing corresponding to the inspection instruction based on the inspection instruction information 51, the device status information 52, the inspection processing performance information 55, and the like, and stores and manages the plan as plan information 53. The inspection processing execution management unit 404 performs execution management for causing the inspection system 1 to execute the inspection processing according to the plan and management of the status of each device during execution of the inspection processing, and stores and manages information related thereto as the inspection processing status information 54. The instruction information 54A is information on a processing start instruction to each device. The response information 54B is information on a response on a processing status from each device.

The inspection processing result management unit 405 stores and manages an execution result of the inspection processing according to the plan as the inspection processing performance information 55. The inspection processing result management unit 405 may store all information including communication information (instruction, response, and the like) during execution of the inspection processing sequence in the inspection processing performance information 55 as a log. The inspection processing result management unit 405 also has a function of analyzing the performance related to the inspection processing. In particular, the success rate calculation unit 405A calculates a success rate of the processing operation of each device based on the performance information, and stores and manages the success rate as the success rate information 55A. In particular, the index value calculation unit 405B calculates an index value related to the processing capacity and the processing time of each device based on the performance information, and stores and manages the index value as the index value information 55B.

The maintenance management unit 406 manages maintenance of each device of the inspection system 1, and stores and manages a maintenance status and schedule of each device as a part of the device status information 52 in cooperation with the device status management unit 402. Further, the maintenance management unit 406 makes a maintenance plan of each device based on the success rate information 55A and the like, and stores and manages the maintenance plan as a part of the device status information 52.

The user interface unit 407 displays, together with the GUI, various kinds of data and information handled by each processing unit on a screen to be provided to a user such as an inspection manager or a worker. The screen is a display screen of the output device 1006 in FIG. 3. The screen may be provided, for example, in a form of a Web page.

Although the inspection processing result management unit 405 calculates the index value or the like in this example, the invention is not limited thereto, and the plan creation unit 403 may calculate the index value or the like.

### Processing Flow of Management System

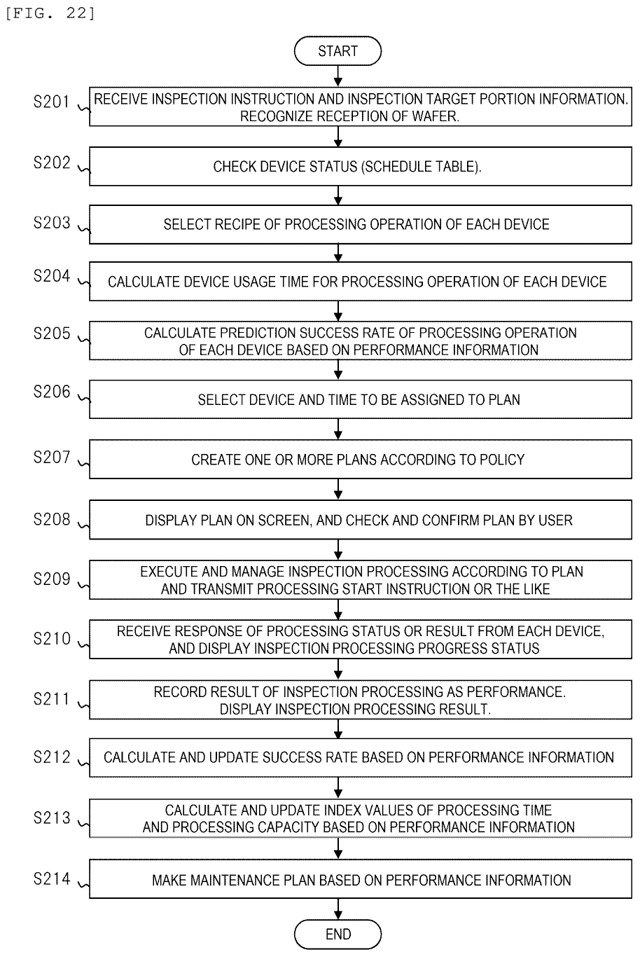

FIG. 22 illustrates a main processing flow of the management system 2 of FIG. 21, and includes steps S201 to S214. This flow illustrates an example of detailed processing related to plan creation and the like.

In step S201, an inspection instruction, inspection target portion information, and the like are issued from the manufacturing management system in a plant. The wafer 3 serving as an inspection target sample is conveyed from a manufacturing line to the inspection system 1. The inspection instruction reception unit 401 of the management system 2 receives the inspection instruction, the inspection target portion information, and manufacturing process information from the manufacturing management system, recognizes that the inspection system 1 receives the wafer 3 by conveyance from the manufacturing line, and stores the information as the inspection instruction information 51. The management system 2 grasps the number of target wafers 3 and thin pieces 4 from the inspection instruction, and grasps the scale of the requested inspection processing, for example, the number of devices required for each step of the inspection system 1. In addition, the inspection instruction reception unit 401 may display contents of the inspection instruction or the like on a screen to the user using the user interface unit 407.

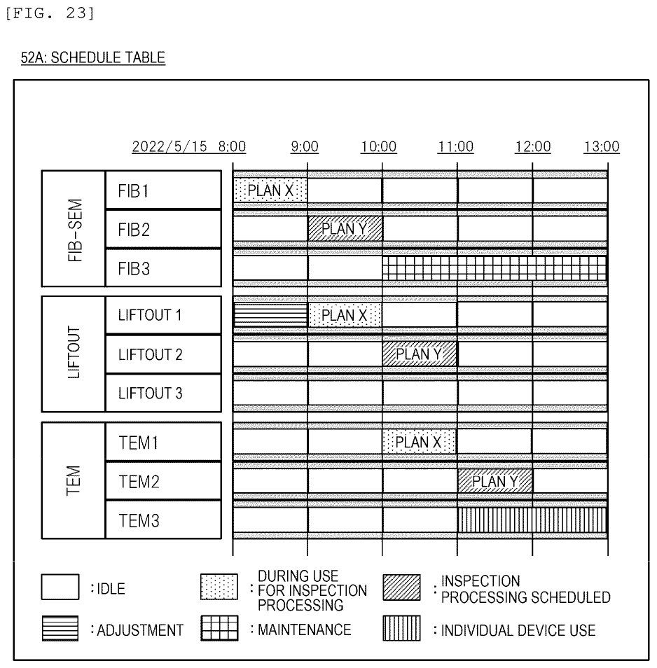

In step S202, the device status management unit 402 of the management system 2 checks the status of each device of the inspection system 1. The device status management unit 402 checks, for example, a schedule table (see FIG. 23 to be described later) of the device status information 52, and grasps an idle time, a usage time, and the like. The device status management unit 402 acquires the latest status of each device by communicating with each device of the inspection system 1, for example. The device status management unit 402 may display the device status on the screen to the user using the user interface unit 407.

In step S203, the plan creation unit 403 of the management system 2 starts creating a plan for inspection processing corresponding to a new inspection instruction based on the inspection instruction information 51, the device status information 52, the inspection processing performance information 55, and the like. For this purpose, first, in step S203, the plan creation unit 403 selects a recipe of a processing operation in each device of each step of the inspection system 1, which is necessary when the requested inspection processing is implemented. A candidate device is a device having a function of performing requested processing. The selection of the recipe is, for example, a selection from standard recipes defined in advance. The recipe is information for controlling a processing operation of a device. For example, a recipe for the FIB-SEM device 10 includes information on a condition for controlling irradiation of a charged particle beam as a recipe corresponding to a function. The plan creation unit 403 may adjust a parameter value of the recipe.

In step S204, the plan creation unit 403 of the management system 2 calculates, based on the recipe or the like, a device usage time of each device, which is necessary when each device in each step of the inspection system 1 performs a necessary processing operation. The device usage time is an estimated time about how much time is required. The plan creation unit 403 estimates a device usage time corresponding to a case where it is assumed that the device executes a processing operation according to the selected recipe. The plan creation unit 403 may estimate the device usage time from the inspection processing performance information 55 with reference to a time required for the past inspection processing in the device. In a case where the device usage time falls within the idle time of the device, in other words, in a case where there is a continuous idle time equal to or longer than the device usage time, the device becomes a candidate for allocation of processing in the plan.

In step S205, the plan creation unit 403 of the management system 2 calculates a prediction success rate for the processing operation of each device based on the inspection processing performance information 55. The plan creation unit 403 particularly calculates the prediction success rate using the success rate information 55A. The prediction success rate is a predicted success rate for the processing operation of each device, assuming that the device executes the selected recipe. The plan creation unit 403 calculates the prediction success rate based on the success rate (“performance success rate”) that has already been calculated in the success rate information 55A. As a more simplified processing example, the performance success rate may be used as the prediction success rate as it is.

In step S206, the plan creation unit 403 of the management system 2 selects, based on the information obtained up to step S205, a device and time for each step as candidates to be assigned to the plan of the inspection processing sequence. At this time, in each step, among the devices having the idle time, when the device usage time falls within the idle time, the device and the device usage time thereof become candidates for allocation.

In step S207, the plan creation unit 403 of the management system 2 creates one or more plans as proposals according to the set policy using the device and the time candidates in step S206. The policy includes, for example, a policy that prioritizes a device with a high success rate. For example, when there are a plurality of device candidates in a certain step, the plan creation unit 403 preferentially selects a device with a high prediction success rate in consideration of the prediction success rate in step S205. When a plurality of plan proposals can be created, the plan creation unit 403 ranks the proposals based on the policy.

In step S208, the plan creation unit 403 of the management system 2 uses the user interface unit 407 to display the contents of one or more plan proposals created in step S207 on the screen to the user. The user can check the contents of the plans on the screen and determines one plan. When there are a plurality of plan proposals, the user can select one of the plan proposals. Alternatively, the management system 2 may automatically determine one plan based on a predetermined policy, and in this case, step S208 may be omitted. The plan creation unit 403 stores the determined plan in the plan information 53.

In step S209, the inspection processing execution management unit 404 of the management system 2 causes the inspection system 1 to execute the inspection processing sequence according to the plan when the date and time at which a certain plan should be executed arrive and the user inputs an execution start instruction based on the plan information 53. Therefore, the inspection processing execution management unit 404 sequentially transmits a processing start instruction or the like to each device of the inspection system 1 at the date and time according to the plan. Each device starts a processing operation in the device in response to the processing start instruction or the like.

In step S210, the inspection processing execution management unit 404 of the management system 2 sequentially receives a response of a processing status or a processing result from each device of the inspection system 1. Each device transmits a processing status, a processing result, and the like in the device to the management system 2 as a response. Accordingly, the inspection processing execution management unit 404 grasps the progress status of the inspection processing sequence. The inspection processing execution management unit 404 displays the progress status of the inspection processing sequence on the screen to the user using the user interface unit 407. The user can check the progress status of the inspection processing sequence on the screen.

In step S211, the inspection processing result management unit 405 of the management system 2 grasps, in cooperation with the inspection execution management unit 404, execution results of the inspection processing in steps S209 and 210, and stores the execution results as the inspection processing performance information 55. The inspection processing performance information 55 includes information on the number of pieces processed, the time required for processing, and success/failure of processing in each device in each step. The inspection processing result management unit 405 displays the execution results of the inspection processing on the screen to the user using the user interface unit 407. The user can check the execution results of the inspection processing on the screen.

In step S212, the inspection processing result management unit 405 of the management system 2 causes, based on the inspection processing performance information 55, the success rate calculation unit 405A to calculate the success rate of the processing operation in each device in each step with respect to the result of the current inspection processing, and updates the success rate information 55A. The inspection processing result management unit 405 may display the success rate of each device on the screen to the user using the user interface unit 407. The user can check the success rate of each device on the screen.

In step S213, the inspection processing result management unit 405 of the management system 2 causes, based on the inspection processing performance information 55, the index value calculation unit 405B to calculate index values of the processing time and the processing capacity (for example, throughput) for the processing operation in each device in each step with respect to the result of the current inspection processing, and updates the index value information 55B. As the index value, at least one of an index value of the processing time or an index value of the processing capacity is calculated. The inspection processing result management unit 405 may display the index value of each device on the screen to the user using the user interface unit 407. The user can check the index value of each device on the screen.

In step S213, the maintenance management unit 406 of the management system 2 may further make a maintenance plan for the device of the inspection system 1 based on the inspection processing performance information 55. For example, when there is a device with a declining success rate, a declining processing capacity, or an increasing processing time, the device becomes a candidate for maintenance. The maintenance management unit 406 sets a maintenance time as a schedule within an idle time of a maintenance candidate device based on the device status information 52. Further, the maintenance management unit 406 displays the made maintenance plan on the screen to the user using the user interface unit 407. The user can check the maintenance candidate device and the made maintenance plan on the screen, and the user can manually set the maintenance plan.

Hereinafter, a specific example of each processing and each function will be described along a flow or order of processing in the entire management system 2 and inspection system 1.

### Inspection Instruction Information

In step S201, the inspection instruction reception unit 401 grasps an inspection target, contents to be performed as the inspection processing, and the like based on the inspection instruction information. The inspection instruction information transmitted from the manufacturing management system in the plant to the management system 2 includes, for example, the following information. The inspection instruction information includes information on a Lot ID, a FOUP ID, a cassette slot position (or a wafer ID), an inspection position, an inspection type, and the like. The Lot ID is identification information of the lot of the wafer 3 which is the inspection target sample. The FOUP ID is identification information of a FOUP which is a container that stores the wafer 3. The cassette slot position is information indicating a position of a slot in the FOUP in which the wafer 3 is stored. The wafer ID is identification information of the wafer 3 which is the inspection target sample. The inspection position is an inspection target position on the wafer 3, and is, for example, two-dimensional coordinates. The inspection position corresponds to a position where the thin piece 4 is produced. The inspection type includes information that defines, for example, an observation type of cross section observation or planar observation, a size of the thin piece 4, a production direction of the thin piece 4, and the like.

### ID Management

An ID and a position of each of objects such as the wafer 3, the thin piece 4, the carrier 5, and the holder 6 handled in the present system are managed individually. The management system 2 grasps the ID and the position of each individual. An ID may be assigned as information to the wafer 3 or the thin piece 4, or an ID may be formed by machining. The ID may be read by image processing, a code reader, or the like. The management system 2 grasps and manages, as information including an ID, at which position of which holder 6, which carrier 5, or the like each wafer 3 or thin piece 4 is mounted, in which device in which step the wafer 3 or thin piece 4 is currently present, and the like. In addition, the management system 2 also grasps and manages, as information, which processing is performed by which device for each wafer 3 or thin piece 4, as well as recipes and conditions for each processing. The information on the ID is also reflected in the plan information. For example, in the plan, information on which FIB-SEM device 10 in the first step forms the thin piece 4 at which position of which wafer 3, to which position of which carrier 5 the formed thin piece 4 is transferred, and to which lift out device 20 in the second step the carrier 5 is transferred is determined.

Each device in each step may perform a processing operation of reading an ID for a target object conveyed to the device. For example, the FIB-SEM device 10 in the first step may read the ID of the conveyed FOUP and wafer 3 and transmit the information to the management system 2. The lift out device 20 in the second step may read the ID of the conveyed carrier 5 and thin piece 4 and transmit information to the management system 2. Each device may determine a processing operation for the object indicated by the ID based on the read ID.

### Device Status Management

Based on the inspection instruction or the like, the management system 2 grasps a device status such as an idle time or a usage time from each device in each step of the inspection system 1 based on communication. In step S202, the device status management unit 402 grasps a status of each device of the inspection system 1. The device status management unit 402 checks a schedule for all devices (for example, FIG. 2) of the inspection system 1 under the management of the management system 2. In other words, the schedule is a device status including a current status and a future schedule. The device status management unit 402 records and manages, in a schedule table, for example, a schedule for each of the devices of the inspection system 1 connected through communication, the number of each of the devices being more than one. The device status management unit 402 refers to the device status information 52 including the schedule table stored in the memory and checks the schedule. The device status management unit 402 grasps an idle time, a usage time, and the like of each device from the schedule.

### Schedule Table

FIG. 23 illustrates a configuration example of a schedule table 52A as a part of the device status information 52. The data structure of the schedule table 52A is not particularly limited. The schedule table 52A of FIG. 23 expresses a schedule with a vertical axis listing each device of the inspection system 1 and a horizontal axis representing a time axis. The example shows a case where the number of each of the FIB-SEM device 10, the lift out device 20, and the TEM device 30 in the first type inspection system 1 is three. For example, there are three FIB-SEM devices 10 denoted by FIB 1, FIB 2, and FIB 3. “FIB 1” and the like are examples of identification information of the device. The time axis only indicates, for example, a portion from 8:00 to 13:00 on May 15, 2022, but other dates and times exist as well.

In the schedule table 52A, a status or a state is recorded and managed as information for each device and for each time. The state for each device and each time is roughly classified into, for example, an idle state and a usage state. A white block in the drawing indicates an idle state. The usage state further includes various states, for example, a “during use for inspection processing” state (indicated by a block with a dot pattern), an “inspection processing scheduled” state (indicated by a block with a diagonal line pattern), an “adjustment” state (indicated by a block with a horizontal line pattern), a “maintenance” state (indicated by a block with a grid pattern), and an “individual device use” state (indicated by a block with a vertical line pattern).

The “during use for inspection processing” state indicates that execution of inspection processing according to a certain plan (for example, a plan X) has already been started. In this example, three devices FIB 1, LIFTOUT 1, and TEM 1 are used for the inspection processing of the plan X. The time of “during use for inspection processing” is fixed and generally cannot be changed.

The “inspection processing scheduled” state indicates that inspection processing in a certain plan (for example, a plan Y) is scheduled and execution thereof has not yet started. In this example, three devices FIB 2, LIFTOUT 2, and TEM 2 are used for the inspection processing of the plan Y. Since the time of “inspection processing scheduled” has not yet started, the plan can be changed.

The “adjustment” state corresponds to, for example, work (for example, optical adjustment) such as setting or adjustment required to be performed before main shared processing in the device. The adjustment includes pre-adjustment work, for example, daily adjustment, and corresponds to adjustment of hardware and software, for example, adjustment and setting of optical conditions and imaging conditions. In a case where the processing in the device is defined including the setting and adjustment, the time of “adjustment” may be integrated into the time of “inspection processing scheduled”. In a case where the maintenance is defined including the setting and adjustment, the time of “adjustment” may be integrated into the time of “maintenance”. In this example, the time of “adjustment” is scheduled before the time (9:00 to 10:00) of the processing operation of the plan X in the LIFTOUT 1 device.

The “maintenance” state corresponds to maintenance work in the device. The maintenance corresponds to the maintenance work such as periodic inspection, sudden inspection, component replacement, and preventive maintenance. In this example, the time of “maintenance” is scheduled after 10:00 for the FIB 3 device.

Further, the “individual device use” state indicates a schedule to individually use the device for a specific purpose. The individual device use corresponds to a case where an individual device is desired to be used at a specific date and time. The use includes uses other than the inspection processing. In this example, for the TEM 3 device, the time of “individual device use” is set after 11:00. The device and the time in the “individual device use” state are not considered when the plan of the inspection processing is created.

The device status management unit 402 manages the schedule table 52A as illustrated in FIG. 23 as a schedule management function, and constantly grasps a status and a schedule of each device of the inspection system 1. Therefore, the plan creation unit 403 can create a suitable plan according to the idle time and the usage time of each of a plurality of devices of the inspection system 1. The management system 2 may provide, to the user, a screen for displaying the schedule table 52A as illustrated in FIG. 23.

### Plan Creation (1)

Based on the device status information 52 and the like, the management system 2 selects a device and time to which each processing is assigned from the plurality of devices of the inspection system 1 for a new inspection processing plan, and creates a plan based on the selection. At this time, the management system 2 calculates, based on the inspection processing performance information 55 and the like, a device usage time when the device executes the processing, and when the device usage time falls within the idle time of the device, the device and the device usage time become candidates for allocation. When there are a plurality of candidates, the candidates are selected in a ranked order according to a predetermined policy. The plan is information for determining how to use the plurality of devices of the inspection system 1 on the time axis, and is a concept including a schedule, a workload, and the like of the inspection processing sequence.

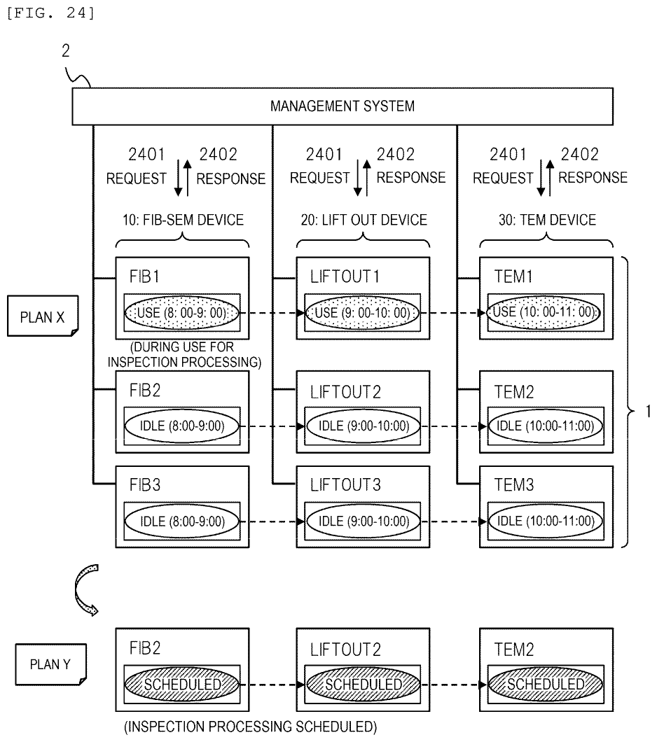

FIG. 24 illustrates an example of creating a plan by the plan creation unit 403 of the management system 2 when the number of each of the devices in the inspection system 1 is more than one (for example, three). The inspection system 1 includes, for example, three FIB-SEM devices 10, namely, FIB 1, FIB 2, and FIB 3, three lift out devices 20, namely, LIFTOUT 1, LIFTOUT 2, and LIFTOUT 3, and three TEM devices 30, namely, TEM 1, TEM 2, and TEM 3. The management system 2 appropriately communicates with each device of the inspection system 1. For example, the management system 2 transmits a device status acquisition request 2401 to each device. In response to the request 2401, each device transmits a response 2402 indicating a device status to the management system 2.

The example of FIG. 24 illustrates a device status of the inspection system 1 at a certain date and time. A square in each device block indicates a resource or a status of the device. For example, the FIB-SEM device 10 referred to as FIB 1 is in the “during use for inspection processing” state for a certain plan X. In this example, three devices, namely, FIB 1 , LIFTOUT 1, and TEM 1 (for example, a first set) are assigned to an inspection processing sequence of the plan X and are in the “during use for inspection processing” state. In addition, three devices, namely, FIB 2, LIFTOUT 2, and TEM 2 (for example, a second set) and three devices, namely, FIB 3, LIFTOUT 3, and TEM 3 (for example, a third set) are in an “idle” state.

For example, in the case of such a device status, the management system 2 that has received a new inspection instruction creates a plan (for example, the plan Y) for a new inspection processing sequence. For example, since the devices in the second set and the third set are in the “idle” state, the plan creation unit 403 uses idle times of the devices as candidates to select a device and a time to be allocated to an inspection processing sequence of the plan Y. In this example, it is assumed that both the devices of the second set and the third set have substantially the same processing capacity. For example, when the device usage time of the devices in the second set falls within the idle time, the plan creation unit 403 sets the devices in the second set and the device usage time as candidates. In this status, for example, when the second set is selected, as illustrated in the lower part of FIG. 24, in the plan Y, each shared processing is allocated to each of the devices and times of FIB 2, LIFTOUT 2, and TEM 2, and is set to the “inspection processing scheduled” state.

In the above example, a concept in a case where one inspection processing sequence is allocated to three types of devices within a relatively short period of time (for example, one day, one hour, or the like) has been described, but similarly, there is an idle state or a usage state for a relatively long period of time on the time axis, and one or more inspection processing sequences can be allocated using the idle time. For example, when there is no idle time in any device in a certain time slot, allocation during the time slot cannot be selected, but when there is an idle time in the next time slot, allocation can be selected using the idle time in the time slot.

The example shows a case where three devices of three different types in the same set are used in series, but the invention is not limited thereto, and any idle device may be used regardless of the set. For example, when all the devices in FIG. 24 are idle, three devices, namely, FIB 1, LIFTOUT 2, and TEM 3 can be selected in other plans.

### Plan Creation (2)

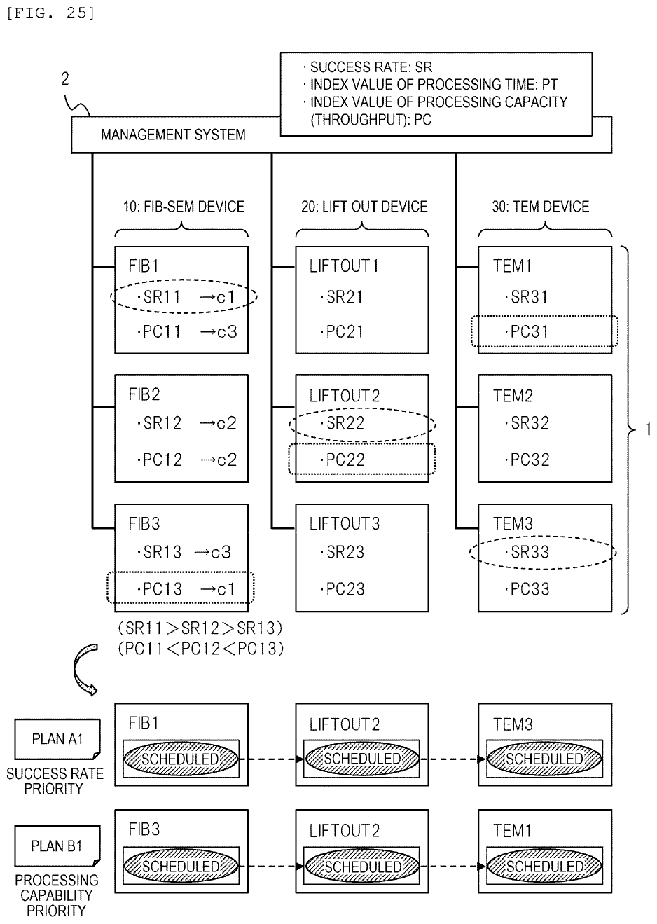

FIG. 25 illustrates an example in which the management system 2 creates a plan using the success rate and the index value of each device. In FIG. 25, there are a plurality of devices as in FIG. 24. The plan creation unit 403 of the management system 2 selects a device and a time to be allocated to the plan based on the set policy, the success rate, and the index value when there is a difference in the success rate, the processing time, and the processing capacity between the devices of the inspection system 1 in each step.

For the sake of description, the success rate is designated as SR. The index value of the processing time is designated as PT. The index value of the processing capacity (for example, throughput) is designated as PC. The success rate SR corresponds to the prediction success rate described above.

In the example of FIG. 25, the success rate SR and the index values PT and PC are illustrated in each device block. For example, the FIB-SEM device 10 referred to as FIB 1 has a success rate SR11 and an index value PC11 of the processing capacity based on the past performance of the inspection processing.

For example, in a case where a policy for creating a plan is a policy that prioritizes a success rate, the plan creation unit 403 preferentially selects a device with a high success rate SR from a plurality of candidate devices in each step. For example, regarding the FIB-SEM device 10 in the first step, when three devices, namely, FIB 1, FIB 2, and FIB 3 are in an idle state in the same time slot, the plan creation unit 403 selects a device with a high success rate SR in order from the three devices. For example, when a magnitude of the success rate SR is SR11>SR12>SR13, the first candidate c1 is selected as FIB 1, the second candidate c2 is selected as FIB 2, and the third candidate c3 is selected as FIB 3. Similarly, based on the success rate SR, for example, when a success rate SR22 of LIFTOUT 2 is the highest, LIFTOUT 2 is selected as a first candidate from the lift out device 20 in the second step. For example, when a success rate SR33 of TEM 3 is the highest, TEM 3 is selected as the first candidate from the TEM device 30 in the third step. The first candidate is indicated by a dashed border.

As a result, as illustrated in the lower part of FIG. 25, a plan using three devices, namely, FIB 1, LIFTOUT 2, and TEM 3 is created as a first plan (referred to as plan A1) with the highest rank as a plan with priority given to the success rate.

In addition, for example, in a case where a policy for creating a plan is a policy that prioritizes the processing capacity, the plan creation unit 403 preferentially selects a device with a high index value PC of the processing capacity from a plurality of candidate devices in each step. For example, regarding the FIB-SEM device 10 in the first step, when three devices, namely, FIB 1, FIB 2, and FIB 3 are in an idle state in the same time slot, the plan creation unit 403 selects a device with a high index value PC in order from the three devices. For example, when a magnitude of the index value PC is PC11<PC12<PC13, the first candidate c1 is selected as FIB 3, the second candidate c2 is selected as FIB 2, and the third candidate c3 is selected as FIB 1. Similarly, based on the index value PC, for example, when an index value PC22 of LIFTOUT 2 is the highest, LIFTOUT 2 is selected as a first candidate from the lift out device 20 in the second step. For example, when an index value PC33 of TEM 1 is the highest, TEM 1 is selected as the first candidate from the TEM device 30 in the third step. The first candidate is indicated by a dotted border.

As a result, as illustrated in the lower part of FIG. 25, a plan using three devices, namely, FIB 3, LIFTOUT 2, and TEM 1 is created as a first plan (referred to as plan B1) with the highest rank as a plan with priority given to the processing capacity.

As described above, the management system 2 can create a plan according to a prioritized policy. The prioritized policy may be determined in advance by a system design, or may be designated by the user on the screen. It is also possible to create a plan for selecting the second candidate and subsequent candidates in addition to the first candidate.

When the policy prioritizes the success rate, it is aimed to increase the success rate of the processing operation including transfer in the device as much as possible, to reduce failures as much as possible, and to reduce recovery processing at the time of failure. The reduction in the recovery processing may consequently increase the throughput of the inspection processing. When the policy prioritizes the processing capacity, it is aimed to increase the throughput of the inspection processing sequence. The same can be achieved by using the index value PT of the processing time instead of the index value PC of the processing capacity. In the case of creating a plan with priority given to the processing time, it is aimed to shorten the processing time of the inspection processing sequence.

Furthermore, in a modification, it is also possible to create a plan by combining the above policies and selecting candidates according to different policies for each step of the inspection processing sequence. For example, it is possible to select a candidate with priority given to the success rate as the device in the first step and select a candidate with priority given to the processing capacity as the device in the second step.

### Plan Creation (3)

The management system 2 may create and propose not only one plan but also a plurality of plans as proposals for one inspection processing sequence. At this time, the management system 2 creates a plurality of plan proposals according to a policy designated by the setting. The management system 2 presents the plurality of plan proposals on the screen in a ranked order according to the policy, and the user checks the plurality of plan proposals on the screen and selects and determines one plan.

Depending on the device status of the inspection system 1 or the like, a plan may not be created, one plan may be created, or a plurality of plan proposals may be created. For example, when there is a lot of free time or available devices, a plurality of plan proposals can be created. When a device or a time is not available until a certain date and time, a plan using the device or the time until the date and time cannot be created, but the plan can be created after the date and time.

When a plurality of plan proposals can be created, the management system 2 may automatically select, based on a predetermined policy or rule, one proposal to determine one plan, instead of the user determining one plan.

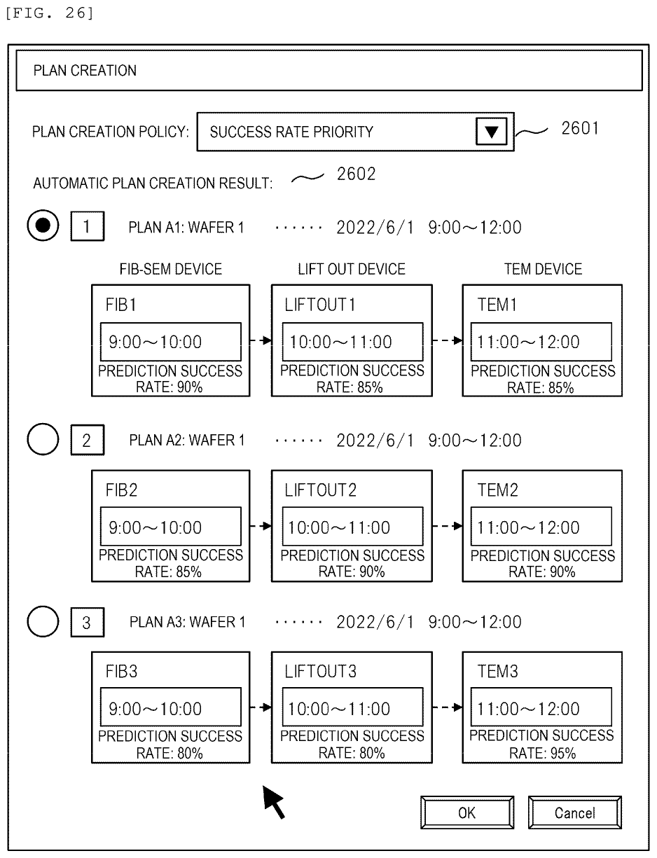

FIG. 26 illustrates an example in which the management system 2 displays a screen related to plan creation to the user. In particular, the screen of FIG. 26 shows an example of displaying a plurality of plan proposals created by the management system 2. The screen of FIG. 26 includes a field 2601 for setting and displaying a plan creation policy and a field 2602 for displaying an automatic plan creation result. In the field 2601, for example, a success rate priority policy is set as the plan creation policy. In the field 2602, one or more plan proposals automatically created by the plan creation unit 403 based on the plan creation policy are displayed. In this example, three plans such as plans A1, A2, and A3 are presented as the automatic creation result. In the field 2602, the plurality of plans are displayed in the order of rank with rank numbers (for example, 1, 2, and 3). In the field 2602, each plan also displays information on a device and time to be used. The time information includes, for example, a scheduled start time and a scheduled end time for a processing operation of each device. In the field 2602, information on a prediction success rate may be displayed for each device. For example, the plan A1 is also illustrated in FIG. 25, and a device with the highest prediction success rate is selected in each step. The illustrated success rates are illustrative numbers to illustrate differences between the devices.

In the field 2602, in a default display, the plan A1 selected by the management system 2 is recommended as a plan with the highest rank, and is displayed in a selected state (with a button turned on). The user checks the plan proposals on this screen, and selects and determines one plan to be applied. For example, the user can select a proposal by operating a cursor on the screen and clicking a button for each plan proposal. On this screen, details can be displayed and checked for each plan proposal and for each device in response to a predetermined operation. For example, the user can check a recipe, a schedule, and other detailed information about processing in the device in response to an operation of selecting the device block.

In addition, the user may select the automatically created plan proposal as it is, but may change the plan proposal to another plan by manually editing a content of the plan proposal on this screen. The user can also change the setting of the policy in the field 2601 and cause the management system 2 to automatically create a plan again.

In the example of the plan of FIG. 26, for simplicity of description, for example, the case where the device usage times in three FIB-SEM devices 10 are the same is illustrated, but the invention is not limited thereto. Actually, the idle time or the device usage time may differ depending on the individual device. Accordingly, the processing time and end time of the entire inspection processing sequence in the plan may vary. In the case of the policy that prioritizes the processing time, it is possible to create a plan that minimizes the processing time of the entire inspection processing sequence or a plan that advances the end time of the entire inspection processing sequence as much as possible. In the case of the policy that prioritizes the processing capacity, it is possible to create a plan that maximizes a processing amount within the processing time of the entire inspection processing sequence.

The management system 2 determines one plan selected and determined from the plurality of plan proposals on the screen as a plan to be actually used, and stores the content of the plan as the plan information 53. The management system 2 prepares to start the inspection processing according to the plan. At the time the plan is created, the management system 2 may notify the user, such as an inspection manager, by e-mail or the like, that the plan has been created. The notified user can access the screen to check the information.

### Plan Creation (4)

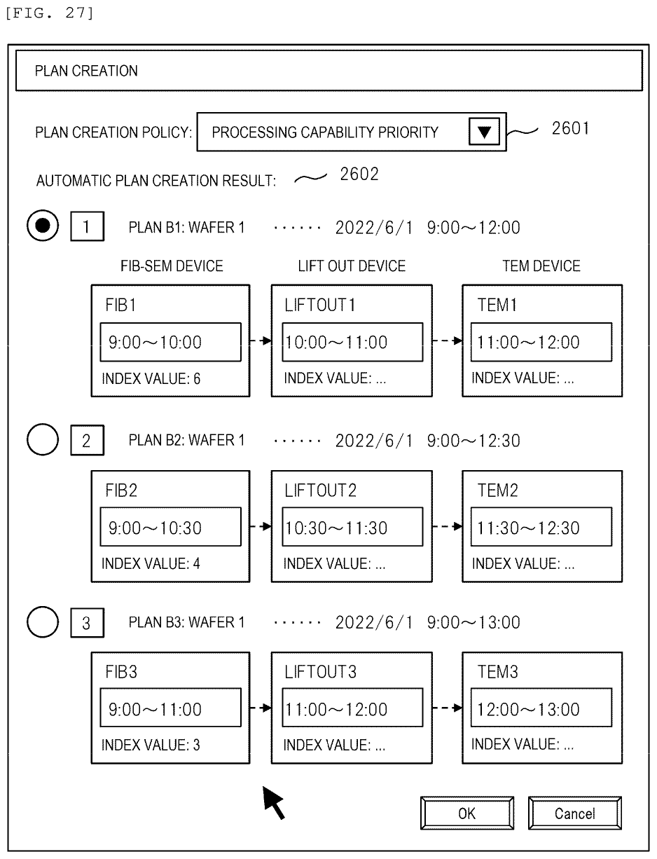

FIG. 27 is similar to FIG. 26, but illustrates an example in which a plan proposal created automatically is displayed on a plan creation screen when the plan creation policy is processing capacity (for example, throughput) priority. In a field 2601, a processing capacity priority policy is set. In a field 2602, three plan proposals such as plans B1, B2, and B3 automatically created according to the policy are displayed in a ranked order. In the field 2602, information on the index value PC of the processing capacity (for example, throughput) may be displayed for each device. For example, the plan B1 is also illustrated in FIG. 25, and a device with the highest index value PC is selected in each step. The illustrated index values are illustrative numbers to illustrate differences between the devices.

The plan creation unit 402 of the management system 2 calculates an allocation of the processing to the device and the time using at least one of the policies as the policy related to the plan creation. Which policy is to be used may be determined in advance as a design matter of the management system 2 or may be variable by user settings as in the above example.

Even after the management system 2 creates and determines a plan, the user can appropriately check a content and a schedule of the plan on the screen.

### Start Execution of Inspection Processing

After the plan is created and determined, the inspection processing execution management unit 404 of the management system 2 causes the inspection system 1 to start the execution of the inspection processing sequence according to the plan based on a scheduled date and time in the plan, an execution start instruction to the inspection processing by the user, and the like. Based on the plan, the management system 2 transmits and outputs an instruction or the like to each device of the inspection system 1 based on communication, and each device receives and inputs the instruction or the like. Accordingly, the inspection processing sequence according to the plan is executed by the inspection system 1. Each device transmits and outputs a status, a result, and the like of processing in the device to the management system 2 through communication, and the management system 2 receives and inputs the status, the result, and the like from each device. Accordingly, the management system 2 grasps and manages the status and result of execution of the inspection processing sequence in the inspection system 1.

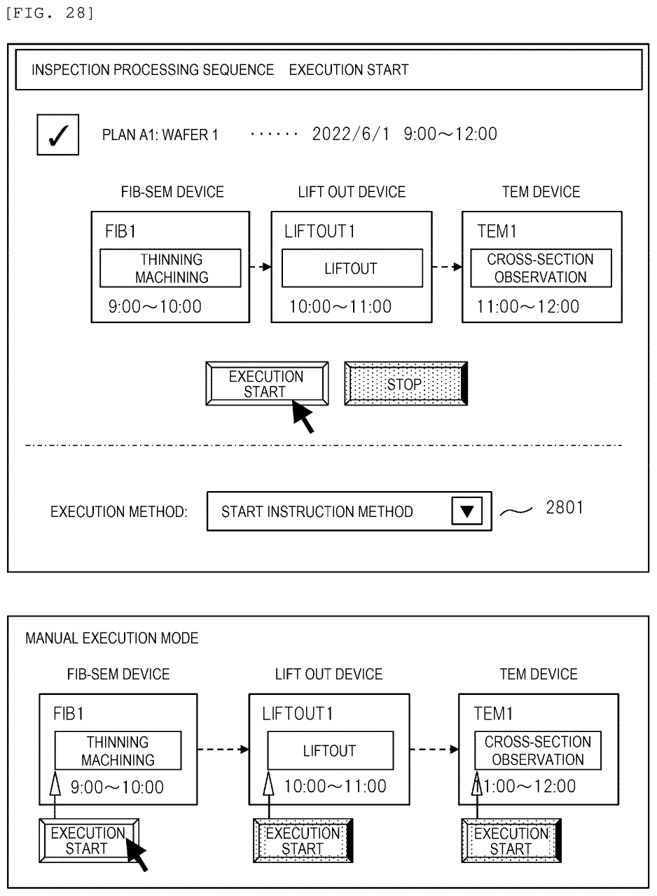

FIG. 28 illustrates an example of an execution start screen of an inspection processing sequence as a screen provided by the management system 2 to the user. On this screen, information on the determined plan (for example, the plan A1 indicated by a check mark) is displayed. An inspection processing sequence of the plan A1 includes, for example, processing at each time in each device of FIB 1, LIFTOUT 1, and TEM 1. When the user presses an “execution start” button on this screen, the execution of the inspection processing sequence according to the plan can be started. After the execution is started, a “stop” button can be pressed, and in this case, the execution of the inspection processing sequence according to the plan can be temporarily stopped. Further, when there are a plurality of plans for a plurality of inspection processing sequences, similarly, it is possible to issue an execution start instruction for each plan.

The invention is not limited to the screen example as illustrated in FIG. 28, and for example, the plan information may be displayed in the form of the schedule table 52A as illustrated in FIG. 23, and the execution start instruction from the user may be received. In a modification, an execution start input on the screen may be omitted, and the management system 2 may automatically start the execution of the inspection processing sequence when the date and time scheduled in the plan have arrived.

### Start Instruction to Inspection Processing

The inspection processing execution management unit 404 of the management system 2 starts the execution of the inspection processing sequence according to the plan based on the input of the plan and the execution start instruction. For this purpose, the inspection processing execution management unit 404 transmits, through communication, a start instruction or the like for starting a processing operation in the device to a corresponding device of the inspection system 1, for example, the FIB-SEM device 10 in the first step. The start instruction corresponds to a command or the like. Each device starts the execution of processing in the device in accordance with the received start instruction or the like. Each device appropriately transmits the status of the processing operation, the result of the processing operation, and the like to the management system 2 as a response. The management system 2 grasps the status and result of the processing operation of each device based on the response from each device, and stores the status and result in the device status information 52.

Each device of the inspection system 1 may include a processing unit for performing communication for management and processing for management with the management system 2 in addition to o the controller for controlling the processing operation of the device.

The management system 2 may transmit control information of the processing operation of the device to each device of the inspection system 1. For example, the management system 2 may transmit recipe information for thinning machining to the FIB-SEM device 10 in the first step. Each device may control the processing operation in the device in accordance with the control information from the management system 2.

In addition, the following method can be applied as control when the management system 2 causes each device of the inspection system 1 to execute inspection processing. The method to be applied (also referred to as a mode) may be selected and set by the user on the screen. For example, as illustrated in the lower part of the screen example of FIG. 28, a field 2801 may be provided in which an execution method can be set. In this method, the same method may be set regardless of the plan, or the method may be set for each plan. For example, when the user designates this method on the screen, the management system 2 switches a control mode to a mode of the designated method.

### Start Instruction Method

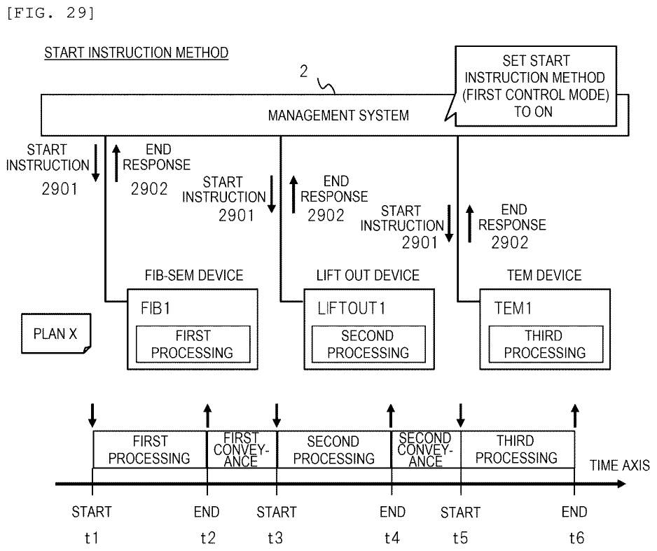

FIG. 29 illustrates a start instruction method as one method. In this method, a start instruction to the processing operation of the inspection processing sequence according to the plan is transmitted from the management system 2 to each device of the inspection system 1. Each device starts the processing operation of the device in accordance with the start instruction. When the processing operation in the device cannot be started in response to the start instruction, each device transmits the response to the management system 2.

When a first control mode corresponding to the start instruction method is in an ON state, the management system 2 transmits a start instruction 2901 to each device at a scheduled start time of the inspection processing in the plan. In the example of FIG. 29, an inspection processing sequence in a certain plan X is executed by FIB 1, LIFTOUT 1, and TEM 1 as a first set of devices. In the lower part, a flow of each processing of each device in the plan X is illustrated on a time axis.

As a schedule in the plan X, first, the first processing in FIB 1 in the first step starts at time t1 and ends at time t2. A period from time t2 to time t3 is the time of the first conveyance step. Next, the second processing in LIFTOUT 1 in the second step starts at time t3 and ends at time t4. A period from time t4 to time t5 is the time of the second conveyance step. Next, the third processing in TEM 1 in the third step starts at time t5 and ends at time t6.

When the inspection processing sequence according to the plan X is started (time t1), the management system 2 first transmits the start instruction 2901 to FIB 1. FIB 1 that has received the start instruction 2901 starts the first processing. FIB 1 appropriately transmits a response indicating the status to the management system 2. When the first processing ends, FIB 1 transmits, to the management system 2, an end response 2902 indicating that the first processing ends. The management system 2 grasps the end of the first processing based on the end response 2902.

Next, the management system 2 transmits the start instruction 2901 to the LIFTOUT 1 at the corresponding time t3 after the first conveyance step. LIFTOUT 1 that has received the start instruction 2901 starts the second processing. When the second processing ends, LIFTOUT 1 transmits, to the management system 2, the end response 2902 indicating that the second processing ends. The management system 2 grasps the end of the second processing based on the end response 2902.

Next, the management system 2 transmits the start instruction 2901 to TEM 1 at the corresponding time t5 after the second conveyance step. TEM 1 that has received the start instruction 2901 starts the third processing. When the third processing ends, TEM 1 transmits, to the management system 2, the end response 2902 indicating that the third processing ends. The management system 2 grasps the end of the third processing based on the end response 2902.

The above example is a case of a fully automatic method to be described later. In each conveyance step, it is assumed that the conveyance is normally completed at a standard time based on the automatic conveyance system.

### Plan Determination Method

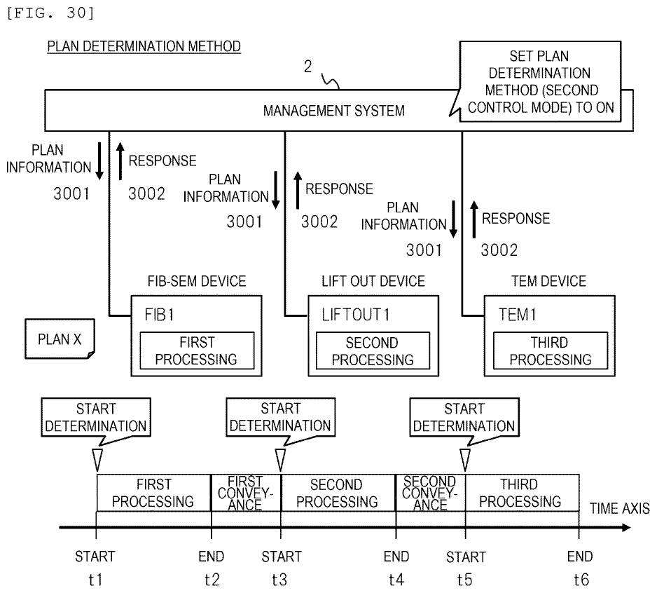

FIG. 30 illustrates a plan determination method as another method. In this method, instead of the start instruction, plan information is transmitted from the management system 2 to each device of the inspection system 1. Each device that has received the plan information determines whether to start a processing operation in the device, and starts the processing operation according to a determination result. When a second control mode corresponding to this method is in an ON state, the management system 2 transmits plan information 3001 to each device at a scheduled start time of the inspection processing in the plan. The transmitted plan information 3001 includes at least a scheduled start time and a scheduled end time of processing scheduled in the device. A timing of transmitting the plan information 3001 is not limited to a timing immediately before the start of the processing as in the first control mode, and may be a timing before the scheduled start time, such as a time when the plan is determined. In a time axis illustrated in the lower part of FIG. 30, for example, the determination is started in each device at times t1, t3, and t5 which are scheduled start times of each processing.

Each device (for example, the controller 10C in FIG. 1) that has received the plan information 3001 grasps processing designated by the device and a start time of the processing based on the plan information 3001. Each device determines, in view of the status of the device, whether the designated processing can be started at a designated start time in the device. When it is determined that the designated processing can be started, each device may transmit a response indicating that the designated processing can be started to the management system 2. When it is determined that the designated processing can be started, each device starts the execution of the designated process at the designated start time. Thereafter, each device appropriately transmits the status and result of the processing in the device to the management system 2 as a response 3002. The management system grasps the status and result of the processing operation of each device based on the response 3002 from each device.

In addition, when it is determined that the designated processing cannot be started, each device may transmit a response indicating that the designated processing cannot be started to the management system 2. Examples of the status in which the designated processing cannot be started include a case where a hardware error occurs in the device and a case where conveyance from the device in the previous step is delayed. When the management system 2 receives, from the device, the response 3002 indicating that the designated processing cannot be started, the management system 2 may temporarily stop the inspection processing sequence to wait and extend the start of the processing in the device. In response to a delay in the start of the processing in the device, the management system 2 may modify the plan to extend processing in subsequent steps of the inspection processing sequence. The management system 2 may notify the user of a status in which the processing in the device cannot be started. When the management system 2 grasps a cause (for example, an error or a conveyance delay) of the delay in the start of the processing in the device, the management system 2 may notify the user of the cause or information for coping with the cause.

### Execution Method of Inspection Processing Sequence

In Embodiment 1, for the inspection processing sequence of the inspection system 1, a fully automatic execution method is basically possible, and the management system 2 has a function of performing plan creation and execution management corresponding to the fully automatic execution method. In the fully automatic execution method, regarding the processing operation of each device in each step of the inspection system 1, the work by the worker can be minimized. In addition, when an automatic conveyance system is available, it is possible to minimize the work of the worker in the conveyance step between the devices.

In Embodiment 1, automatic execution management of the inspection processing sequence by the management system 1 is used as a basis, and the user does not need to perform execution and management by a manual operation. That is, it is not necessary for the user to give a start instruction to the processing operation to each device by the manual operation. However, in some cases, it is assumed that a user such as an inspection manager may want to execute and manage the inspection processing sequence by the manual operation. Therefore, the management system 2 also provides a function and a user interface for the user executing and managing the inspection processing sequence by the manual operation.

In Embodiment 1, examples of a method in which the management system 2 executes and manages the inspection processing sequence of the inspection system 1 based on the plan include a fully automatic execution method and a manual execution method. In the fully automatic execution method, the processing operation in the inspection processing sequence including the above-described conveyance step is automated, enabling complete labor savings.

In addition, the management system 2 displays the plan information on the screen after creating a plan based on the fully automatic execution method, and receives a manual operation so that the user can check the plan information and the user can change a part of the inspection processing in the plan. For example, for the processing operation of the thinning machining in the FIB-SEM device 10 in the first step, it is possible to perform plan adjustment such as changing a size of a thin piece from 10 microns to 12 microns. The management system 2 updates the content of the plan information in response to the change operation.

On the other hand, in the manual execution method, the user such as an inspection manager or a worker performs some of the processing operations in the inspection processing sequence by the manual operation. For example, in the above-described conveyance step, a worker may perform the work of conveying the FOUP or the carrier 5 or the work of setting the FOUP or the carrier 5 in the device. For example, in the case of the first type inspection system 1 in FIG. 6, in the first conveyance step, the worker conveys the FOUP, which is the holder 6, from the FIB-SEM device 10 to the lift out device 20, sets the FOUP in the lift out device 20, and presses a processing operation start button in the lift out device 20. In addition, in the second conveyance step, the worker conveys the LCC 7 that stores the carrier 5 from the lift out device 20 to the TEM device 30, transfers the carrier 5 to the cartridge 8, sets the carrier 5 in the TEM device 30, and presses a processing operation start button in the TEM device 30. After the processing operation start button is pressed in each device, an automatic processing operation is performed in each device, and the device is in a standby state until the processing operation ends.

In the case of the manual execution method, the management system 2 has a function of performing plan creation and execution management corresponding to the method. In this case, on the assumption that the standard work is normally performed for a part where the work is performed by the worker, the management system 2 estimates a time required for the work and a processing capacity, and creates a plan by reflecting the estimation.

In addition, for example, there is a case where the user wants to start processing of a device in a certain step, or to perform the conveyance work in the conveyance step at a timing determined by the user, by a manual operation. The management system 2 receives the plan adjustment in the case of such a manual execution method. In this case, the start of a part of the processing specified by the user on the screen, for example, the start of processing of a device in a certain step, is not an automatic start with a target start time set. After the worker is notified at the target start time, the worker starts the processing at the timing determined by the worker. After the processing is actually started, the management system 2 can grasp a start status based on a response from the device or the worker, and update a target start time in each subsequent step.

Further, the management system 2 provides the user with a screen with a GUI for executing and managing the inspection processing sequence in the manual execution method. On the screen, the user can check a plan, an execution status, and the like of the inspection processing sequence, and can issue a start instruction or the like to an individual device by a manual operation. £ For example, as illustrated in the lower part of FIG. 28 as another screen example, an execution start button for the processing operation of the device is provided for each block device.

### Work Instruction Method

In addition, when the work by the worker is involved in a part of the inspection processing sequence of the inspection system 1, the management system 2 also has a function of transmitting a work instruction or the like to a device or a user in order to support the work by the worker. Here, this is described as a work instruction method.

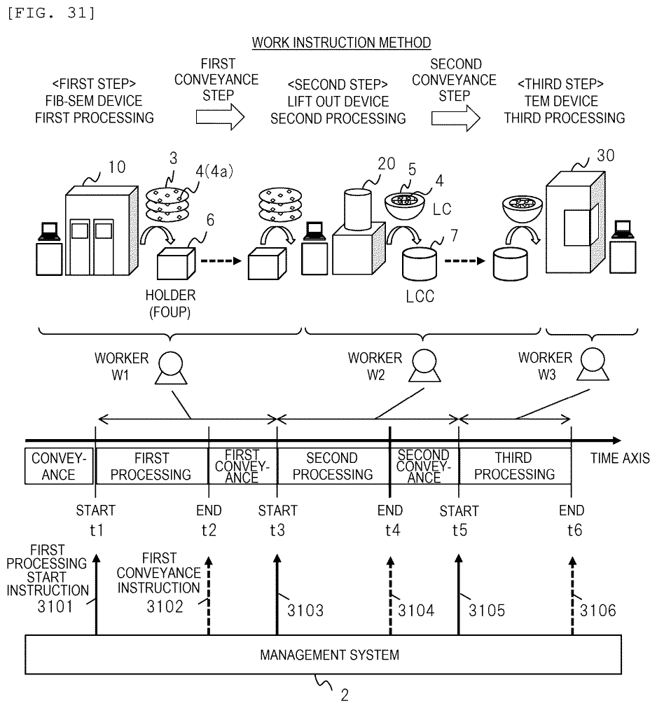

FIG. 31 illustrates the work instruction method. Here, an example of the first type inspection processing sequence of is shown. As illustrated in the drawing, the inspection processing sequence includes on the time axis, for example, conveyance from the manufacturing line, the first processing in the first step (time t1 to t2), the first conveyance (time t2 to t3), the second processing in the second step (time t3 to t4), the second conveyance (time t4 to t5), and the third processing in the third step (time t5 to t6). At the start time of the processing in each step, for example, as in FIG. 29, the start instruction 2901 may be transmitted from the management system 2 to the device.

FIG. 31 also illustrates an example of assignment of workers to the processing operation in each step. For example, the first worker W1 is in charge of the first processing of the FIB-SEM device 10 in the first step and the subsequent work in the first conveyance step. The second worker W2 is in charge of the second processing of the lift out device 20 in the second step and the subsequent work in the second conveyance step. The third worker W3 is in charge of the third processing of the TEM device 30 in the third step. The invention is not limited thereto, and for example, another worker may be in charge of the work in the conveyance step.

The management system 2 transmits a work instruction or the like to each worker in accordance with the start of the processing operation in each step (scheduled time in the plan or the like). The work instruction is information for causing the worker in charge to recognize the work or the processing operation in the step or the device. The lower part of FIG. 31 illustrates an example of the work instruction. For example, the management system 2 transmits a first processing start instruction 3101 to the worker W1 at the start of the first processing (time t1). The first processing start instruction 3101 includes, for example, information on which holder 6 is to be used and when the processing should be started by which FIB-SEM device 10. A transmission destination of each instruction may be, for example, a screen of an output device of the FIB-SEM device 10 or the like or a screen of a mobile terminal of the worker W1 as a predetermined transmission destination. The transmission destination of the instruction may be a common management device (for example, a large display that can be seen by each worker) separate from each device in an environment in which the inspection system 1 is provided.

For example, the worker W1 sets the designated FOUP in the designated FIB-SEM device 10 according to the first processing start instruction 3101, and presses a processing start button of the device. Accordingly, the FIB-SEM device 10 starts thinning machining on the wafer 3 taken out from the FOUP. The FIB-SEM device 10 forms the thin piece 4 by irradiating a designated position on the surface of the wafer 3 with a beam.

The management system 2 may transmit a first conveyance instruction 3102 related to the work in the first conveyance step to the worker W1 in charge, for example, in response to the end of the first processing (time t2). The first conveyance instruction 3102 includes, for example, information on which holder 6 should be conveyed to which lift out device 20 and by when.

Similarly, for example, at the start of the second processing (time t3), the management system 2 transmits a second processing start instruction 3103 to the worker W2 related to the lift out device 20. The second processing start instruction 3103 includes, for example, information on which holder 6 is to be used and when the processing should be started by which lift out device 20. According to the second processing start instruction 3103, the worker W2 sets the designated FOUP in the designated lift out device 20 and presses a processing start button of the device. Accordingly, the lift out device 20 takes out the thin piece 4 from the wafer 3 taken out from the FOUP and transfers the thin piece 4 to the carrier 5. The management system 2 may transmit a second conveyance instruction 3104 related to the work in the second conveyance step to the worker W2 in charge, for example, in response to the end of the second processing (time t4). The second conveyance instruction 3104 includes information on which carrier 5 (LCC 7) should be conveyed to which TEM device 30 and by when.

In this method, information on a worker in charge of work in each step of the inspection system 1 and an address of a notification destination is registered in the management system 2 in advance. The management system 2 transmits the work instruction such as the processing start instruction or the conveyance instruction as illustrated in FIG. 31 to an address of the mobile terminal of the worker in charge in the form of an e-mail or the like. For example, on the screen of the mobile terminal of the worker, a message such as “Please start ~~ processing of ~~device at what time and what minute” is displayed. Such a notification is transmitted before the scheduled start time in the plan.

The management system 2 may display, on a screen of an output device (for example, an operation panel) of each device of the inspection system 1, information on processing scheduled in the device in the plan and a scheduled start time of the processing. This information is displayed before the scheduled start time. By viewing the screen, the worker in charge can check the scheduled start time of the processing in the device.

Similarly, regarding the work in the conveyance step, information may be displayed on a screen of a related device. For example, when the work instruction is output for the work in the first conveyance step, the information on the work instruction of the conveyance step is displayed on at least one of a screen of the FIB-SEM device 10, a screen of the lift out device 20, a screen of the mobile terminal of the worker, or a screen of the management device.

In the work instruction method, the management system 2 supports the work of the worker by issuing the work instruction in accordance with plan of the inspection processing sequence. The management system 2 transmits an instruction or a notification to the corresponding worker so that the processing or the work in each step can be started according to the scheduled time in the plan as much as possible. Therefore, in this method, the work by the worker can be performed so as not to be deviated as much as possible in accordance with the scheduled time in the plan.

When the worker does not perform the work according to the scheduled time in the plan, the processing in an individual step is delayed, and the entire inspection processing sequence is postponed. The inspection processing execution management unit 404 of the management system 2 may grasp such a delay based on communication with the device and the worker. For example, the worker may transmit a work status from the mobile terminal to the management system 2. In this case, the management system 2 may modify the plan by, for example, extending a scheduled time in an initial plan. When the plan is modified, the management system 2 may output the modified plan to the user, or may transmit an instruction according to the modified plan to each device or the user.

In addition, the work instruction method also has the following functions so as to support and cope with a case where the worker forgets to perform the work. When the processing or the work in the step is not started according to the scheduled time in the plan, the management system 2 transmits and outputs a notification such as an alert to the corresponding worker. Details of this method are as follows.

When the scheduled start time of the processing or the work in the plan approaches, the management system 2 may display, for example, a notification window for warning of a time-up situation to a predetermined notification destination. For example, regarding the second processing in the lift out device 20 in the second step, when the scheduled start time is 10:00 as the time t3, the processing start instruction 3103 is notified on the screen of the lift out device 20 and the screen of the mobile terminal of the worker W2 in charge, for example, starting 5 minutes beforehand. In the notification, a remaining time until the scheduled start time (t3) is counted and displayed. When the scheduled start time (t3) approaches, a time-up warning is displayed. The output of the warning or the like may be implemented by switching a display state of a pilot lamp included in the device. After the scheduled start time has arrived, a warning or the like may be output as described later.

### Display of Inspection Processing Status

During execution of the inspection processing sequence according to the plan, the inspection processing execution management unit 404 of the management system 2 displays a progress status of the inspection processing sequence currently being executed on the screen to the user. By viewing the screen, the user can check the progress status of the inspection processing sequence currently being executed. Each processing performed by each device of the inspection system 1 in a shared manner includes a more detailed operation sequence and a processing group related to a plurality of thin pieces 4 and the like. The management system 2 also grasps the operation sequence of the processing of each device and a degree of progress of the processing group based on the response from each device, and displays the progress status on the screen. In addition, each device itself in the inspection system 1, for example, the controller 10C may manage the progress status of the processing operation in the device and transmit information indicating the progress status to the management system 2, and the management system 2 may grasp the progress status of each device based on the information. The management system 2 may output information on an inspection processing status to, for example, an operation panel of each device, the mobile terminal of the user, or the like.

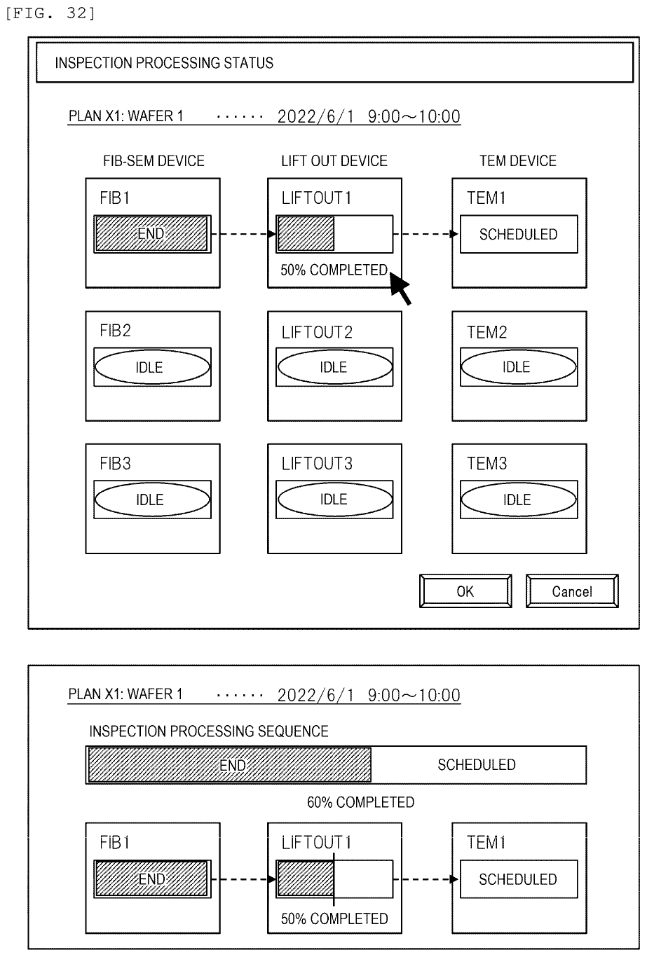

FIG. 32 illustrates an example of a screen displaying an inspection processing status. The inspection processing execution management unit 404 of the management system 2 generates such an inspection processing status screen based on the plan information 53 and the inspection processing status information 54, and provides the inspection processing status screen to the user. In the screen example of FIG. 32, information on a plan (for example, a plan X1) to be checked and information indicating an inspection processing sequence are displayed. A configuration of the inspection system 1 is the same as that in FIG. 2, for example. On this screen, the entire configuration of the inspection system 1 including a plurality of devices is displayed, and this screen clearly indicates that the devices executing the inspection processing sequence of the plan X1 are FIB 1, LIFTOUT 1, and TEM 1. Further, a connection of processing of each device is displayed by, for example, an arrow image.

On this screen, for the inspection processing sequence of the plan X1 being executed, a status of processing in each device is displayed. As the status of the processing, for example, a state indicating whether the processing in each device has been started or ended is displayed. For example, a state in which the first processing in FIB 1 has been ended is displayed as “end”. A state in which the third processing in TEM 1 has not been started yet is displayed as “scheduled”. When the processing in the device is being executed, an execution status and a degree of progress of the processing are displayed. In this example, in each device block, the processing is represented by a rectangular bar, and the degree of progress of the processing is represented by a length of the bar (for example, a portion with a diagonal line pattern). For example, in LIFTOUT 1, a status is displayed in which the lift out processing is being executed as the second processing and, for example, 50% of the entire processing is completed. The 50% indicates, for example, that 5 out of 10 scheduled thin piece 4 have been processed, or that 30 minutes out of scheduled 1-hour duration is over. This screen may further display an actual start time and end time of the processing of each device.

On this screen, it is also possible to check a device in an idle state that is not used in the plan X1 in the inspection system 1. Although not illustrated here, as will be described later, a maintenance scheduled state or the like of the device is also displayed, and thus can be checked together. In addition, on this screen, when the user selects information on a plan, details of the plan are displayed and can be checked. When the user selects a device block, a detailed status of the device can be displayed and checked.

Further, in the screen example of FIG. 32, a degree of progress of each device is displayed, but the invention is not limited thereto, and a degree of progress of the entire inspection processing sequence may be calculated and displayed. The lower part of FIG. 32 illustrates a display example in this case. In this example, the degree of progress of the entire inspection processing sequence is represented by a long bar.

### Display of Inspection Processing Result

The inspection processing execution management unit 404 of the management system 2 displays an execution result of the inspection processing sequence according to the plan on the screen. The user can check an inspection processing result by viewing the screen. The inspection processing result here is different from the result (data 9) of observation and analysis, and the like by the TEM device 30, and is the execution result of the inspection processing sequence.

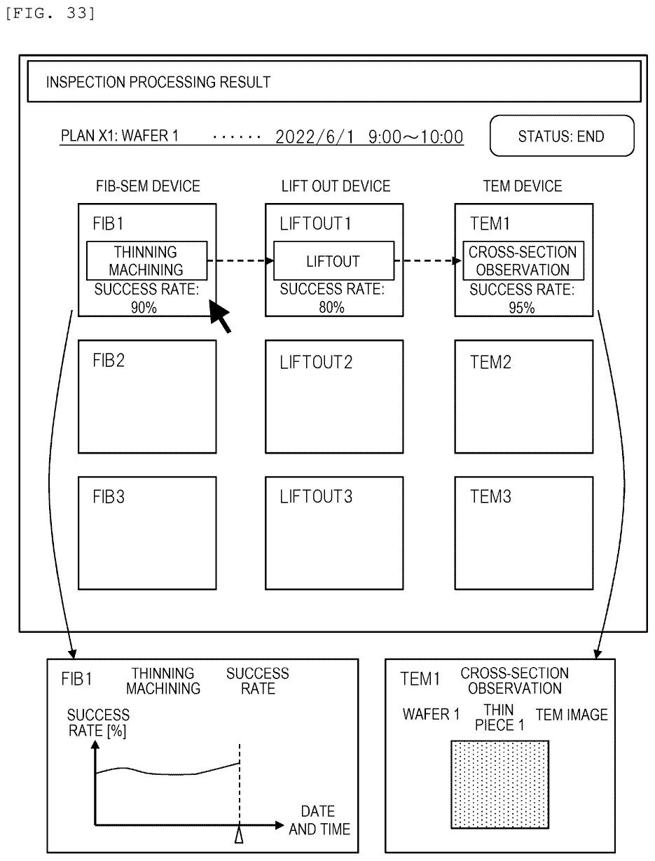

FIG. 33 illustrates a screen example displaying an inspection processing result. When the inspection processing in the inspection processing sequence according to the plan is completed, the inspection processing execution management unit 404 generates such an inspection processing result screen and provides the inspection processing result screen to the user. In this screen example, in addition to the information on the plan, the status, and the information on the overall configuration of the inspection system 1, an inspection processing sequence and information on a success rate of a processing operation in each device are displayed. In the inspection processing sequence, for example, inspection processing is performed on a plurality of thin pieces 4, and a success rate of the processing operation is displayed for each device based on the success rate information 55A. For example, in FIB 1, the success rate of the thinning machining is displayed as 90%. The success rate is a value calculated based on a result of the current inspection Processing Sequence.

On this screen, for example, when a block device is selected based on a user operation, detailed information on the success rate can be displayed and checked. For example, as illustrated in the lower part of FIG. 33, the management system 2 may display a transition of the success rate in a graph based on past performance as the success rate of the processing in FIB 1. The user may designate a period for calculating the success rate on the screen, and the success rate in the designated period may be calculated and displayed. Similarly, as will be described later, the index value can also be displayed for each device.

Further, on this screen, based on a user operation, for example, in response to an operation of selecting a device block, detailed information on the processing itself of the device can be displayed and checked. For example, as illustrated in the lower part of FIG. 33, detailed information on cross section observation can be displayed and checked as the third processing in the TEM device 30. Based on the data 9 (FIG. 1) obtained as a result of the inspection processing, the management system 2 acquires, for example, an image or information as a result of the cross section observation of the TEM 1, and displays the image or the information on the screen. For example, a TEM image of a certain thin piece 4 is displayed and can be checked by the user.

Similarly to the screen of FIG. 32, the screen of FIG. 33 may display information on a processing time of the entire inspection processing sequence as a result of the entire inspection processing sequence.

### Warning Display

The inspection processing execution management unit 404 of the management system 2 grasps whether the processing in each device of the inspection processing sequence is executed as scheduled in a plan based on a response from each device. When the processing in the device has not been started as scheduled in the plan or it is determined that the processing has not been ended, the inspection processing execution management unit 404 outputs a warning indicating the fact. For example, the inspection processing execution management unit 404 displays a warning on the screen to a user associated with the processing. The invention is not limited thereto, and the management system 2 may notify the user of a warning by e-mail or the like. The management system 2 may notify a warning to an operation panel of the corresponding device or the mobile terminal of the worker in charge. The management system 2 may output a warning in the form of light or sound. The warning may be provided in a stepwise manner, ranging from low to high severity.

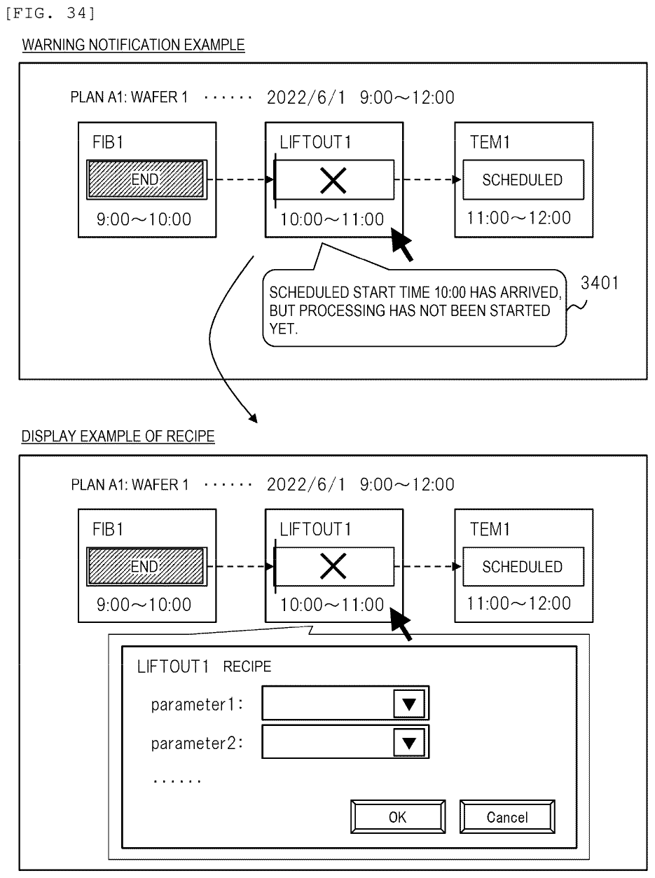

FIG. 34 illustrates a screen example for notifying a warning to a user such as an inspection manager or a worker. On this screen, in addition to the plan information and the information on each device in the inspection processing sequence, warning information 3401 is displayed. As the information on each device in the inspection processing sequence, a scheduled time and a progress status of processing of each device are displayed. For example, the block of LIFTOUT 1 displays that a start time and an end time of the second processing are from 10:00 to 11:00 as scheduled in the plan. As the progress status, the fact that the processing has not been started yet is represented by a cross mark or the like. As the warning information 3401, for example, a message such as “the scheduled start time 11:00 has arrived, but the processing has not been started yet” is displayed, for example, in a speech bubble image. Examples of the reason why the processing in the second step has not been started include a case where the worker W1 in charge of the conveyance work in the first conveyance step has forgotten to do the work, a case where the work has not been completed yet, and a case where a hardware error occurs in the LIFTOUT 1.

When the user receives such a warning, the user can check a content of the warning, an inspection processing status, and the like, and consider a countermeasure. For example, the worker may go to a location of the device that is the subject of the warning and check whether a hardware error, a conveyance delay, or the like has occurred. The inspection manager may transmit an instruction or the like to the worker in charge. After checking the warning and performing taking a corrective action, the user can resume the inspection processing by inputting a start instruction again on the screen (for example, FIG. 28).

Further, for example, the management system 2 may display, on the screen, parameter values or the like as information on a recipe of a processing operation of a device corresponding to the plan, and the user may check the recipe and manually correct a part of the parameter values or the like to take a corrective action. The lower part of FIG. 34 illustrates a display example of the recipe. For example, when the block of LIFTOUT 1 is selected on the screen, recipe information of LIFTOUT 1 is displayed. The user checks or modifies the parameter values of the recipe and presses an OK button. The management system 2 modifies and updates the recipe in the plan. When a schedule such as a processing time is updated along with the update of the recipe, the management system 2 may display the updated schedule to the user.

Since the inspection processing status and the warning function as described above are provided, the user can check whether the processing operation of each device in the inspection processing sequence is proceeding without any trouble according to the plan, and when there is a trouble, it is possible to deal with the trouble smoothly.

### Error Display

When a trouble occurs in the inspection processing sequence, for example, when a hardware error of the device or a conveyance delay in the conveyance step occurs, the inspection processing execution management unit 404 of the management system 2 grasps such a trouble based on communication with the inspection system 1. For example, the inspection processing execution management unit 404 grasps what kind of error or the like occurs in a processing operation of which device in which inspection processing sequence, and what kind of progress status (for example, a state such as interruption) . Then, the inspection processing execution management unit 404 outputs a status related to such a trouble or an error to a user such as an inspection manager. Accordingly, the user can check the status, and can quickly take a corrective action to resolve the status.

When an error such as a hardware error occurs in the processing operation of the device, each device transmits an error notification to the management system 2 as a type of response. The inspection processing status management unit 404 grasps an error state in the device based on reception of an error notification from the device. Then, the inspection processing status management unit 404 displays an error notification screen to the user using the user interface unit 407.

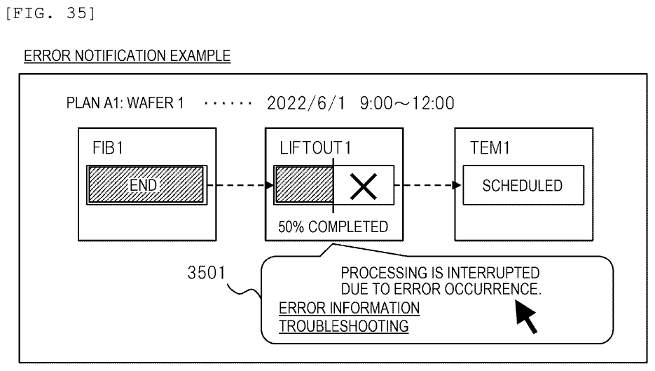

FIG. 35 illustrates a screen example for notifying the user of an error when the error occurs in the inspection processing sequence. In this screen example, in addition to the plan information and the information on the progress status of the inspection processing sequence, error notification information 3501 is displayed, for example, in a speech bubble image. The progress status is, for example, the same as that in FIG. 32, and the second processing in LIFTOUT 1 has been completed up to 50%. At this time, since a hardware error occurs in LIFTOUT 1, the second processing in the LIFTOUT 1 is interrupted. In response to this error, in the error notification information 3501, for example, a message such as “the processing is interrupted due to error occurrence” is displayed, and a link to error information (for example, an error code), a link to troubleshooting, and the like are displayed. The user can check the error notification information 3501 and the like on this screen and smoothly take a corrective action such as troubleshooting.

### Display of Success Rate

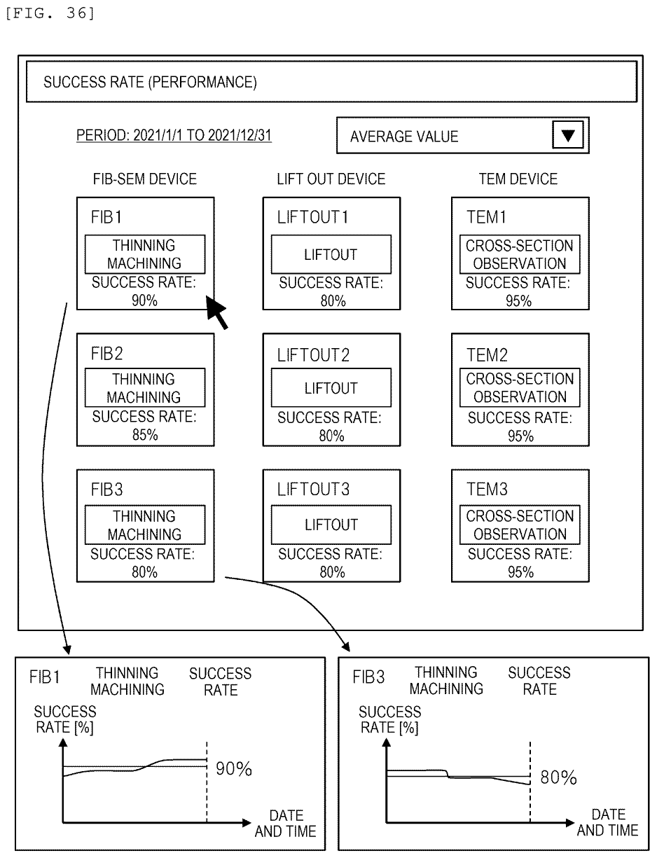

FIG. 36 illustrates an example of displaying a statistical value regarding a success rate (performance success rate) for each device of the inspection system 1 on a screen. The user can request and check such a screen at any timing. The inspection processing result management unit 405 of the management system 2 refers to the success rate information 55A of the inspection processing performance information 55 by the success rate calculation unit 405A, and calculates a statistical value of the success rate in a past predetermined period, for example, a period designated by the user on the screen. The calculation may be performed in advance or may be performed at the time when a request is received from the user.

In the screen example of FIG. 36, for example, one year from the present to the past is designated as a period for taking statistics. In addition, an average value is designated as the type of statistical value. The success rate calculation unit 405A calculates the designated statistical value in the designated period based on the success rate information 55A in which the success rate in each past inspection is stored. Not only the average value but also a maximum value, a minimum value, a change amount, and the like can be displayed.

In addition, on this screen, for example, a graph of a transition of the success rate of the device can also be checked in response to an operation on the device block. As illustrated in the lower part of FIG. 36, for example, a trend can be checked in which the success rate of FIB 1 increases, but the success rate of FIB 3 decreases.

When there are a plurality of pieces of processing in a detailed operation sequence as processing of each device, a success rate may be calculated and displayed for each detailed operation processing. For example, a success rate of an operation of storing the wafer 3 on which the thin piece portion 4a is formed in the holder 6 by the FIB-SEM device 10, a success rate of an operation of taking out the thin piece 4 from the wafer 3 by the lift out device 20, a success rate of an operation of mounting the taken-out thin piece 4 on the carrier 5, and the like are included.

Further, on the screen, for example, it is also possible to display devices in descending order of success rate, or to highlight a device with the highest success rate among the devices of the same type. In addition, it is also possible to extract a location where a change in the success rate is large in the past transition of the success rate, and to display and check detailed information at the location. For example, when maintenance is performed on the device, the success rate may change due to the influence of the maintenance. By the check, it is possible to evaluate effectiveness of maintenance. As will be described later, it is also possible to make a maintenance plan based on the transition of the success rate.

### Display of Index Value

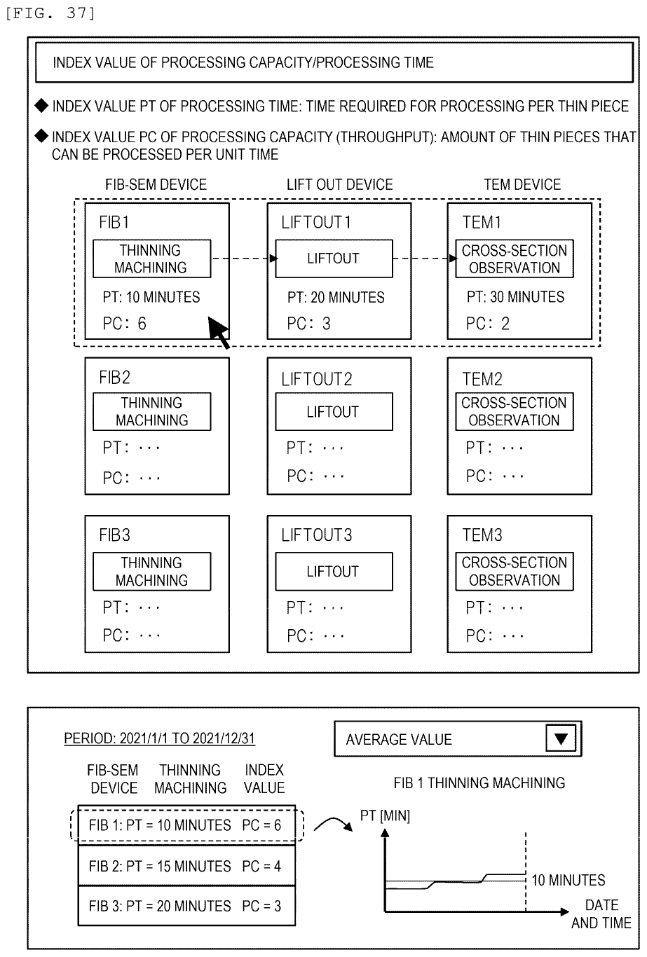

FIG. 37 illustrates an example of displaying index values of a processing time and a processing capacity for each device of the inspection system 1 on a screen. For example, at a timing when an inspection processing sequence in a certain plan ends and an execution result is obtained, the inspection processing result management unit 405 of the management system 2 calculates an index value of each device related to the inspection processing sequence. The inspection processing result management unit 405 causes the index value calculation unit 405B to calculate, based on the inspection processing performance information 55, at least one of the index value PT of the processing time or the index value PC of the processing capacity based on the result of the processing of each device in the inspection processing sequence, and stores the calculated index value as the index value information 55B. The management system 2 generates a screen for displaying the index value using the user interface unit 407 and provides the screen to the user.

In the screen example of FIG. 37, in addition to the configuration of the inspection system 1, the index value PT of the processing time and the index value PC of the processing capacity are displayed for each device. For example, for the processing such as thinning machining in FIB 1, the index value PT of the processing time is 10 minutes, and the index value PC of the processing capacity is 6. Examples of these index values are values for convenience of description.

As described above (FIG. 27), the management system 2 may compare such index values between the devices of the inspection system 1 and select a device and time to which the processing is allocated when a new plan is created. Further, the management system 2 does not necessarily have to store the index value information 55B in a structure such as a table, and the inspection system 1 may store index value information related to the device in each device (for example, the controller 10C or the like).

### Regarding Index Value

The index value PT of the processing time is a time required for processing per thin piece. The index value PC of the processing capacity or the throughput is an amount of thin pieces that can be processed per unit time according to general definition. These index values can be converted into each other. The index value can also be rephrased as an evaluation value, a correction coefficient, or the like. The processing is processing shared by each device, and is, for example, thinning machining in the FIB-SEM device 10. For example, the index value PC of the processing capacity or throughput in the FIB-SEM device 10 can be set to an amount indicating how many thin piece portion 4a can be formed per one hour. The index value PT of the processing time in the FIB-SEM device 10 is a time required for thinning machining for forming one thin piece portion 4a.

The index value can be calculated as follows, for example. The processing time (in other words, a total processing time) of each device of the inspection system 1 can be defined as a [device processing time] by, for example, the following formula. [Device processing time]=[conveyance time]+[preprocessing time]+[shared processing time]. The [device processing time] is a value reflecting a machine difference or the like unique to the device.

The [conveyance time] is a time required for work such as conveyance or setting from a device in a previous step to a device in a current step. The [preprocessing time] is a time required for processing such as adjustment performed before main shared processing in the device. Examples of the adjustment processing include alignment between a stage and an optical system and setting of optical conditions. The [shared processing time] is a time required for the main shared processing performed by a device serving as a sharing unit, and is, for example, the time required for thinning machining in the case of the FIB-SEM device 10.

The [shared processing time] can be defined by, for example, the following formula. [Shared processing time]=[number of thin pieces processed]×[time required for processing per thin piece].

The inspection processing time in the entire inspection processing sequence can be defined by, for example, the following formula. [Device processing time in first step]+[device processing time in second step]+[device processing time in third step].

The formula in the above example is defined including the conveyance step and the like, but is not limited thereto, and may be defined excluding the conveyance step and the like.

The plan creation unit 403 calculates a predicted device processing time (corresponding to the device usage time described above) as a predicted required time when it is assumed that a candidate device executes the shared processing allocated to the candidate device at the time of the plan creation. For example, the number of thin pieces 4 to be processed is assumed to be n. The [conveyance time] is denoted as It. The [preprocessing time] is denoted as Tp. The [shared processing time] (time per thin piece) is denoted as Td. The predicted device processing time is denoted as Te. Each time is a time for each device, and a device ID is given in the following parentheses. The predicted device processing time Te can be calculated by Te=Tt+Tp+Td*n as a formula.

For example, when the predicted device processing time Te for each of the three devices is calculated for the processing such as the thinning machining in the FIB-SEM device 10, the predicted device processing times Te (FIB 1), Te (FIB 2), and Te (FIB 3) of the devices are, for example, as follows. Te (FIB 1)=Tt (FIB 1)+Tp (FIB 1)+Td (FIB 1)* n, Te (FIB 2)=Tt (FIB 2)+Tp (FIB 2)+Td (FIB 2)* n, and Te (FIB 3)=Tt (FIB 3)+Tp (FIB 3)+Td (FIB 3)* n.

In the formula of the above example, the conveyance time Tt and the preprocessing time Tp are constant values regardless of the number of the thin pieces 4, but may be values determined according to the number of the thin pieces 4.

At the time of plan creation, the plan creation unit 403 calculates an allocation such that the predicted device processing time Te of each device falls within an idle time, as the device usage time described above. At this time, a plurality of devices of the same type (for example, the FIB-SEM device 10) may have an idle time in the same time slot and may be used for allocation. In this case, the plan creation unit 403 allocates processing to a device selected, in the order of priority based on a policy, from the plurality of devices in the same time slot and a time corresponding thereto.

The processing capacity, the processing time, and the success rate are improved by improvements and advances such as functional improvement and new function addition of the device. Therefore, for example, even in the same type of FIB-SEM device, the processing capacity and the processing time may vary depending on a difference between a current device and a new device. In addition, for example, even devices of the same model number may have a machine difference between devices. Therefore, the management system 2 calculates index values of the processing capacity and the processing time unique to each device based on the inspection processing performance information 55 and uses the index values to create a plan.

In a specific example, the inspection processing result management unit 405 of the management system 2 calculates the index value PT of the processing time for the device in each step based on the above formula, calculates the index value PC of the processing capacity by conversion from the index value PT, and stores the index value PC as the index value information 55B. The management system 2 may display an index value screen as illustrated in FIG. 37. In the screen example of FIG. 37, results of the inspection processing in the devices such as FIB 1, LIFTOUT 1, and TEM 1 as a certain inspection processing sequence, the index value PT of each device, and the like are displayed. The user can check the processing capacity and the like in the current inspection processing by viewing the screen.

Similarly to the success rate screen in FIG. 36, for the index values, the management system 2 can also calculate statistical values of the index values for a past predetermined period based the inspection processing performance information 55 and display the statistical values on the screen.

In the lower part of FIG. 37, an example of displaying index values when calculated as the statistical values is illustrated. In this example, the index value PT and the index value PC for each of the three FIB-SEM devices 10 such as FIB 1, FIB 2, and FIB 3 in the first step are displayed in parallel. These index values are calculated as the statistical values, for example, average values, for the past year, for example. For example, the index values PT of the processing times of the three devices are 10 minutes, 15 minutes, and 20 minutes, which are converted to the index values PC of the processing capacities of 6, 4, and 3, respectively. By viewing this screen, the user can compare the index values as the statistical values between the devices. For example, it can be seen that among three devices, FIB 1 has the shortest processing time and the highest throughput.

Similarly, as shown in the example on the right side, it is also possible to display a transition of an index value in a graph for a device selected by the user.

The management system 2 can automatically select a device to be used for the plan using the index value as described above (FIG. 27). Further, the user can select or modify the device to be used for the plan with reference to the index values that can be checked on the above screen.

### Display of Maintenance Status and Maintenance Plan

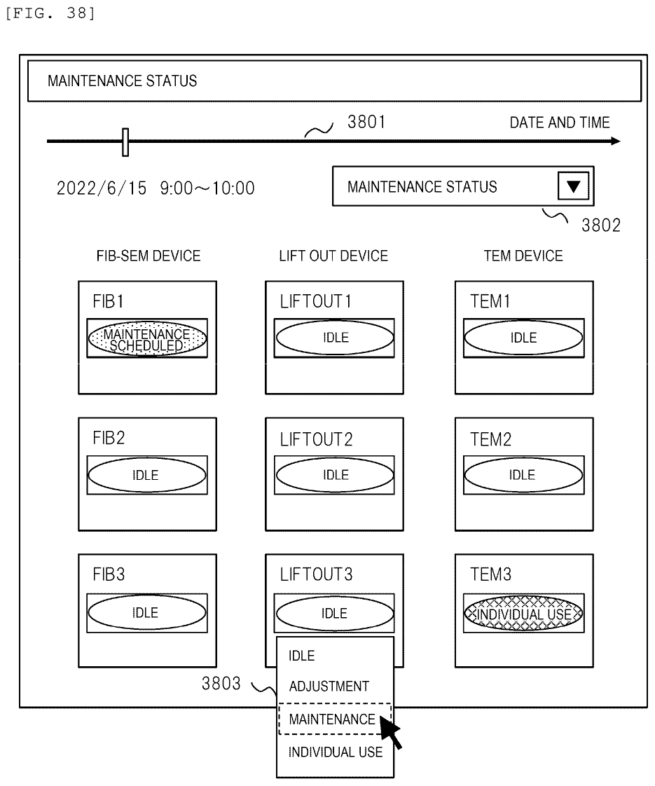

FIG. 38 illustrates an example in which the maintenance management unit 406 of the inspection system 2 displays a maintenance status and maintenance plan screen. The user can check this screen at any timing. In the screen example of FIG. 38, the user can select the date and time using a time axis bar 3801 or the like, and a maintenance status and a maintenance plan for each device of the inspection system 1 are displayed for a time slot of the selected date and time. For example, in a list box 3802, a “maintenance status”, a “plan”, and the like can be selected, and when the “maintenance status” is selected, the maintenance status and the maintenance plan for each device of the inspection system 1 are displayed. The maintenance management unit 406 generates this screen based on the schedule table 52A as illustrated in FIG. 23 and provides this screen to the user using the user interface unit 407.

In the screen example of FIG. 38, states such as “idle” and “maintenance scheduled” are displayed for each device block as the maintenance status and the maintenance plan. In this example, FIB 1 is displayed as “maintenance scheduled” in a certain time slot (9:00 to 10:00). When creating a plan using this time slot, the plan creation unit 403 of the management system 2 excludes FIB 1 in the “maintenance scheduled” state from candidates so as not to be used.

Further, the user can input a maintenance schedule for the device on this screen. For example, when a device block of LIFTOUT 3 is selected, “idle”, “adjustment”, “maintenance”, “individual use”, and the like are displayed as options in a list box 3803, and the user can select and input the options. As the state of “maintenance”, a more detailed state such as whether the maintenance is a periodic inspection or a sudden inspection may be set.

In addition, the user can select a block of a specific device in the inspection system 1 on this screen and input a schedule for the individual use described above. For example, TEM 3 is set as a state of “individual use”. When creating a plan using this time slot, the plan creation unit 403 excludes TEM 3 in the “individual use” state from candidates so as not to be used.

The display of the “maintenance scheduled” and the like is not limited to the screen example of FIG. 38, and may adopt representations similar to the schedule table 52A as illustrated in FIG. 23, for example.

### Maintenance Planning

The maintenance management unit 406 of the management system 2 may use, in addition to the maintenance schedule management information (device status information 52 in an implementation example) as described above, the success rate information 55A and the index value information 55B (FIG. 21) described above for preventive maintenance and maintenance planning. The maintenance management unit 406 makes a maintenance plan for each device of the inspection system 1 based on the information (for example, FIGS. 36 and 37) on the success rate and the index value of each device. For example, the maintenance management unit 406 creates a maintenance schedule such that a device with a lower success rate should undergo maintenance earlier or should undergo maintenance more frequently, and describes the schedule in the schedule table 52A. For example, the maintenance management unit 406 may compare the success rate of the device with a threshold value to determine whether the maintenance is necessary. For example, the maintenance management unit 406 may compare the amount of change in the case of a decrease in the success rate with a threshold value to determine whether the maintenance is necessary. The management system 2 displays the content of the maintenance plan made by the maintenance management unit 406 on a screen using the user interface unit 407.

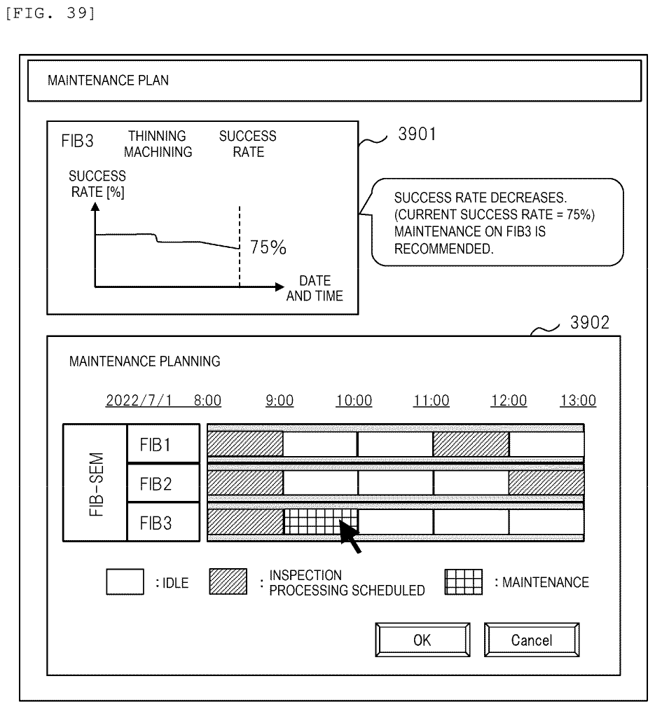

FIG. 39 illustrates a screen example displaying the made maintenance plan. In the screen example of FIG. 39, in the upper part of FIG. 39, information 3901 on the success rate of FIB 3 is displayed, and a maintenance recommended message such as “The success rate has decreased. Maintenance of FIB 3 is recommended” is displayed to the user, for example, in a speech bubble image. For example, as in FIG. 36, when there is a performance that the success rate of FIB 3 in the FIB-SEM device 10 has decreased, the maintenance management unit 406 determines that the maintenance of FIB 3 should be performed early based on the decrease in the success rate, and displays such information. Then, the maintenance management unit 406 makes a maintenance plan for FIB 3.

In the lower part of FIG. 39, information 3902 on maintenance plan made by the maintenance management unit 406 for the maintenance of FIB 3 is displayed. In this example, the information 3902 on the maintenance plan is displayed in the form of a schedule table as in FIG. 23. In this example, FIB 3 has already been scheduled for inspection processing in a time slot from 8:00 to 9:00, for example. The maintenance management unit 406 selects, for example, the earliest time slot from 9:00 to 10:00 among the idle times of FIB 3, and proposes the selected time slot as a time slot for a maintenance schedule.

On this screen, the user can check and modify a device subject to maintenance recommended by the management system 2 and the content of the maintenance plan made automatically. The user views the information 3902 on the maintenance plan, and presses an OK button when the user approves of the proposed maintenance schedule. Accordingly, the maintenance management unit 406 reflects the proposed maintenance schedule in the device status information 52. In addition, when the user wants to modify the proposed maintenance schedule, for example, the user performs an operation of horizontally sliding a region of the maintenance schedule with a cursor to move the region to a region of a desired idle time, and presses an OK button.

According to the above functions, efficient maintenance and preventive maintenance can be realized, and the success rate of the device can be maintained or increased. Each device of the inspection system 1 may include a consumable maintenance component as a device component. Examples of the consumable maintenance component include tweezers constituting the attaching and detaching device 23 of the lift out device 20. In this case, the device requires maintenance and replacement work for the consumable maintenance component. The maintenance schedule includes a schedule of the maintenance and replacement work for such a consumable maintenance component.

The maintenance schedule can be manually input by the user on the screen example, but is not limited thereto, and can be automatically input by the management system 2. For example, each device of the inspection system 1 may manage the maintenance schedule for the device, and the user may input the maintenance schedule by an operation panel or the like of each device. The management system 2 acquires information on a maintenance schedule (for example, a scheduled maintenance time) from each device of the inspection system 1 based on communication. The maintenance management unit 406 sets, based on the acquired information, the maintenance schedule for each device so as to be reflected in the schedule table 52A of the device status information 52.

In addition, the management system 2 may determine and analyze whether the success rate of the processing operation, the processing time, and the processing capacity of the device have improved before and after the maintenance of the device is performed, and output information on a relation between the maintenance and the success rate and the like. The management system 2 may analyze the correlation between a time elapsed since the maintenance of the device is performed and the success rate and output the correlation as a graph. Accordingly, the user can check the effectiveness and necessity of maintenance.

In addition, the management system 2 may determine and analyze a failure occurrence location, a location where a failure is likely to occur, and the like for the processing operation in the device based on information on the degree of progress and success/failure of the processing operation of the device. The management system 2 may output information on the failure occurrence location. Accordingly, the user can refer to the information to determine maintenance details.

The management system 2 may make a maintenance plan for the device based on analysis result information regarding the correlation between the maintenance and the success rate, the failure occurrence location, and the like. For example, as a result of maintenance of a certain device, an increase in the success rate indicates that the maintenance is effective, whereas a decrease in the success rate indicates that the maintenance is not effective. When it is determined that the maintenance in a certain maintenance plan is not effective, the management system 2 makes a maintenance plan having another content.

When there is a difference in the success rate or the like before and after maintenance of the device, the difference is reflected when a new plan is created thereafter. That is, a device with an increased success rate after maintenance is likely to be selected in the case of the success rate priority policy described above when a new plan is created. In addition, the management system 2 may preferentially select the device with an increased success rate after maintenance over a device with an unchanged or decreased success rates after maintenance.

In addition, when there is a plan that has been created once and then maintenance of the device is performed, the management system 2 may adjust the created plan in consideration of the maintenance. For example, in the created plan, it is assumed that FIB 1 is set as the device in the first step. Thereafter, it is assumed that maintenance is performed on FIB 2. It is assumed that inspection processing in the plan is not yet started. In this case, the management system 2 changes the device in the first step in the plan to FIB 2 on which the maintenance has been performed. Accordingly, in the plan after the adjustment, it is expected that the success rate or the like of FIB 2 is increased by the maintenance, and thus more suitable inspection processing can be expected.

### Recovery Processing

When a failure occurs in a predetermined processing operation such as thinning machining, lift out, or cross section observation in each device of the inspection system 1, information indicating the failure may be transmitted from each device to the management system 2 as a type of response. The information indicating the failure may be, for example, information indicating that the processing of a specific ID among 10 thin pieces 4 (for example, ID=1 to 10) scheduled in the plan has failed, or information indicating how many of the 10 thin pieces 4 have failed. Alternatively, the information indicating the failure may be in the form of an error code or may be the error notification described above.

Based on the failure information from each device as described above, the management system 2 can grasp a success/failure status of the processing in each device and calculate the success rate. The management system 2 can also analyze a transition of the success rate on the time axis, a tendency of the failure, a tendency of the error, a cause of the error, and the like. The management system 2 may display such analysis result information on the screen. The management system 2 may create a plan using such analysis result information.

In addition, the management system 2 or each device may determine whether to interrupt or continue subsequent processing in the device, upon the occurrence of the failure of the processing for each thin piece 4. For example, except for a fatal case (for example, a case where it is difficult to continue the processing when it is determined that the device has a serious error), the management system 2 does not interrupt the processing even after the occurrence of the failure, and continuously executes the subsequent processing, that is, the same processing related to other thin pieces 4. Accordingly, the management system 2 temporarily completes all the processing of the entire inspection processing sequence (processing excluding the failed processing on the thin piece 4). After the completion, the management system 2 additionally executes recovery processing according to the grasped failure occurrence location and factor. The recovery processing is performed on the failed processing on thin piece 4 until successful completion.

### Plan Creation (5)

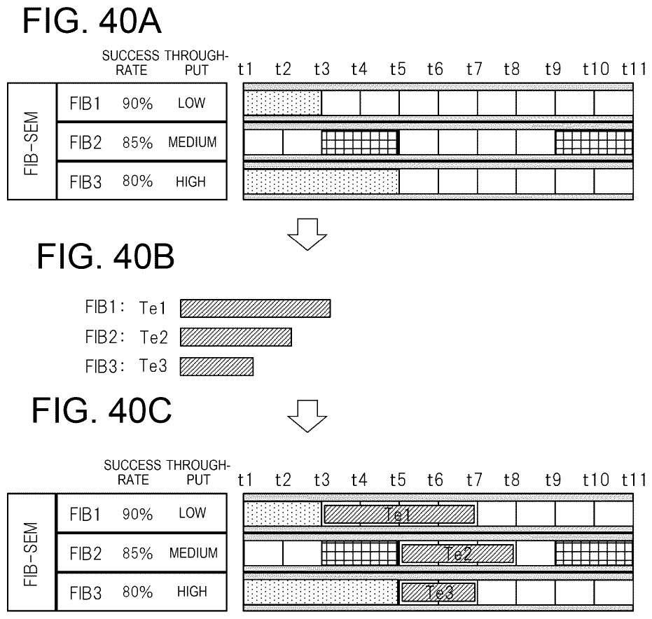

FIG. 40 illustrates another plan creation example. FIG. 40 illustrates an example of calculating a device and time to which processing is allocated when there are three FIB-SEM devices 10 such as FIB 1 to FIB 3 in the first step. (A) illustrates an example of a schedule of FIB 1 to FIB 3 after a current time t1. It is assumed that the time after time t1 is an allocable time. FIB 1 is being used for inspection processing from time t1 to time t3. FIB 2 is scheduled for maintenance from time t3 to t5 and from time t9 to t11. FIB 3 is being used for the inspection processing from time t1 to time t5. It is also assumed that the performances of the success rates of the devices are 90%, 85%, and 80%. In addition, it is assumed that the index values PC of the processing capacities (for example, throughput) of the devices are relatively low, medium, and high. That is, in this example, it is assumed that FIB 1 has a relatively high success rate but, in return, a relatively low throughput, and FIB 3 has a relatively low success rate but, in return, a relatively high throughput.

The plan creation unit 403 estimates the predicted device processing time Te of each device as described above. As a result, as illustrated in (B), the predicted device processing times Te of the devices are Te1, Te2, and Te3 as illustrated in the figure. Here, Te1>Te2>Te3. In this example, Te1 is a length of four unit times, Te2 is a length of three unit times, and Te3 is a length of two unit times.

(C) illustrates an example of a propose of processing allocation based on the predicted device processing time Te in (B) for the device status in (A). First, simply, among possible options where the time Te can be kept within an idle time after the time t1, a propose that allows processing to be processed at the earliest time is selected. In such a policy, in the candidate FIB 1, a block of time Te1 is arranged between time t3 and time t7. In the candidate FIB 2, since time Te2 cannot be arranged between time t1 and time t2, a block of time Te2 is arranged between time t5 and time t8. In the candidate FIB 3, a block of time Te3 is arranged between time t4 and time t7. The plan creation unit 403 selects one of these three candidates, for example.

When the determination is made only by the success rate priority policy, the plan creation unit 403 selects FIB 1 based on the value of the success rate regardless of the arrangement of the time Te, and allocates the processing to the time period from time t3 to time t7 of FIB 1 in this propose.

When the determination is made only by a throughput priority policy, the plan creation unit 403 selects FIB 3 based on the value of the index value PC regardless of the arrangement of the time Te, and allocates the processing to the time period from time t5 to time t7 of FIB 3 in this propose.

In addition, as another approach in the case of throughput priority, the plan creation unit 403 may select a device that finishes processing at the earliest time based on arrangement plans as in (C). In this example, among the three arrangement plans, a processing end time of each of FIB 1 and FIB 3 is time t7. Therefore, the plan creation unit 403 may select either FIB 1 or FIB 3.

In the above example, only the processing of the FIB-SEM device 10 in the first step in the inspection processing sequence is considered, but similarly, the processing of the subsequent lift out device 20 or TEM device 30 can also be planned. For example, when the time Te1 (time t3 to time t7) of FIB 1 is selected among the arrangement plans, an allocation of the processing for the lift out device 20 in the second step is calculated for a time period after the time t7.

In addition, the plan creation unit 403 may sequentially perform allocation of processing in the device in each step as temporary selection, create temporary allocation in the entire inspection processing sequence, then evaluate the time required for the inspection processing in the entire inspection processing sequence, and finally select and determine a plan.

Further, in Embodiment 1, the calculation of the predicted device processing time Te is not reflected in the recovery processing when the processing operation fails. As a modification, the predicted device processing time Te may be calculated by considering the information on the success rate, that is, by considering a predicted time required for the recovery processing in the case of failure.

### Plan Creation (6)

The manufacturing management system of the manufacturing plant may provide information on a priority related to an inspection and a sample in an inspection instruction. The management system 2 may receive the information on the inspection instruction and the priority from the manufacturing management system and give a priority to an inspection processing sequence and a plan in accordance with the priority or the like. Alternatively, the management system 2 may give a priority or the like to the inspection instruction. In other words, the management system 2 may give a priority to each target sample or each inspection processing. The management system 2 creates a plurality of plans in consideration of priorities among a plurality of pieces of inspection processing for a plurality of samples.

The priority may be divided into a plurality of levels such as a normal level, a high level, and a highest level. For example, for the normal level, a plan is created to simply receive an inspection instruction and perform processing in time series in the order of arrival. For the high level and the highest level, a plan is created to perform processing ahead of a normal-level processing in time series.

For example, it is assumed that a plan (referred to as a first plan) for normal-level sample inspection processing is created first based on a first inspection instruction. Next, it is assumed that a request for a high-level sample inspection processing is received as a second inspection instruction. In this case, the plan creation unit 403 reconstructs the entire set of plans including the first plan and a second plan such that the high-level inspection processing is completed as early as possible by shifting the existing normal-level first plan backward as much as possible and inserting a high-level plan (referred to as the second plan) ahead of the first plan.

Further, for example, it is assumed that a request for highest-level sample inspection processing is received as a third inspection instruction during the execution of the inspection processing in the first plan or the second plan. In this case, for example, the plan creation unit 403 interrupts the inspection processing in the current plan, creates a highest-level plan (referred to as a third plan) such that the execution of the highest-level inspection processing is completed as early as possible with the highest priority, and controls a plurality of plans as a whole. After the inspection processing in the third plan is completed, the interrupted inspection processing in the plan is resumed.

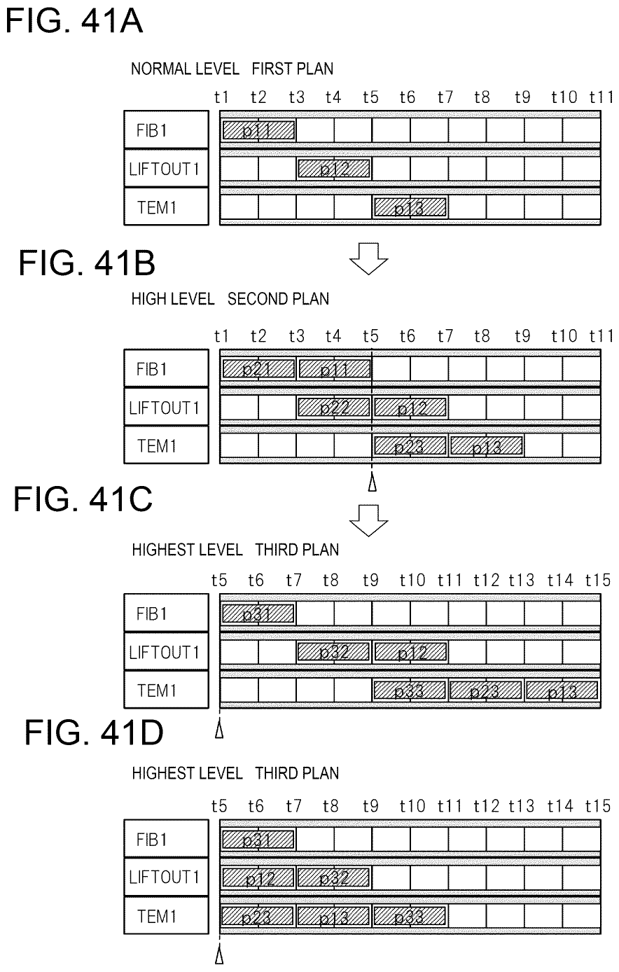

FIG. 41 illustrates an example of plan creation using the priority. (A) illustrates the first plan related to the normal-level sample inspection processing, which is created first based on the first inspection instruction. Here, for simplicity, a case where only FIB 1, LIFTOUT 1, and TEM 1 are used as the devices is shown. The first plan includes processing p11 in FIB 1 from time t1, processing p12 in LIFTOUT 1 from time t3, and processing p13 in TEM 1 from time t5.

(B) illustrates the second plan related to the high-level sample inspection processing, which is then created based on the second inspection instruction. The plan creation unit 403 shifts the time of the first plan backward and inserts the time of the second plan so that the inspection processing in the second plan is executed before the inspection processing in the first plan. The second plan includes processing p21 in FIB 1 from time t1, processing p22 in LIFTOUT 1 from time t3, and processing p23 in TEM 1 from time t5. The updated first plan is shifted backward by two unit times.

Here, it is assumed that the inspection processing is executed according to the plan of (B) and, for example, the processing p21, p11, and p22 up to time t5 are completed.

(C) Illustrates a creation example of the third plan related to the highest-level sample inspection processing when the third inspection instruction is received at time t5. The plan creation unit 403 interrupts the processing in the first plan and the second plan at time t5. At time t5, the processing p12, p23, and p13 remain. The plan creation unit 403 creates and inserts the third plan with the highest priority from time t5. The third plan includes processing p31 in FIB 1 from time t5, processing p32 in LIFTOUT 1 from time t7, and processing p23 in TEM 1 from time t9. The plan creation unit 403 puts the processing p12, p23, and p13 after resumption at a time later than the first plan. For example, the processing p12 is arranged after the processing p32, and the processing p23 and p13 are arranged after the processing p33.

(D) illustrates another example of the arrangement of the processing p12, p23, and p13 after resumption with respect to the third plan. In this example, a vacant time before the time to be used in the third plan is used. The plan creation unit 403 arranges the processing p12 of LIFTOUT 1 in a vacant time (time t5 to time t7) in (C). The plan creation unit 403 arranges the processing p23 and p13 of TEM 1 in a vacant time (time t5 to time t9) in (C).

### Simultaneous Parallel Processing

In the inspection system 1, when there are a plurality of devices of the same type, for example, when there are a plurality of sets, it is possible to simultaneously execute a plurality of pieces of inspection processing on a plurality of samples in parallel by using these resources. The plan creation unit 403 can create a plurality of plans for simultaneous parallel of the plurality of pieces of inspection processing.

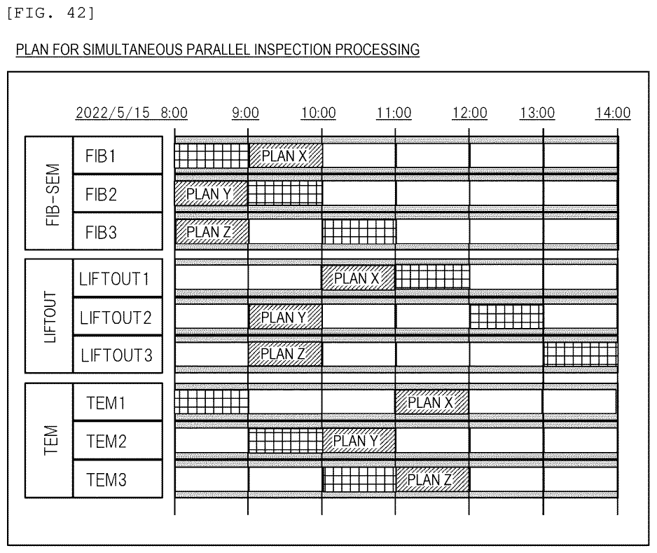

FIG. 42 illustrates an example of creating a plurality of plans in this case. First, as an example of an advance device status, it is assumed that there is a maintenance schedule (block with a grid pattern) for each device as illustrated in the drawing. It is assumed that the management system 2 receives inspection instructions for three pieces of inspection processing. The plan creation unit 403 creates three plans (referred to as plans X, Y, and Z) for three pieces of inspection processing using the idle time.

In this example, the management system 2 creates the plan X using a first set of devices {FIB 1, LIFTOUT 1, TEM 1}, creates the plan Y using a second set of devices {FIB 2, LIFTOUT 2, TEM 2}, and creates the plan Z using a third set of devices {FIB 3, LIFTOUT 3, TEM 3} . Regarding the first processing in the first step in each plan, for example, since FIB 1 is scheduled for maintenance during the time period from 8:00 to 9:00, the processing is arranged from 9:00 to 10:00 for FIB 1, and since FIB 2 and FIB 3 are available, the processing in FIB 2 and FIB 3 is simultaneously arranged in parallel. Regarding the second processing in the second step, the processing is arranged for each of LIFTOUT 1, LIFTOUT 2, and LIFTOUT 3 immediately after the processing in the previous step is completed. Regarding the third processing in the third step, the processing is arranged for TEM 1 and TEM 2 immediately after the processing in the previous step is completed, the processing is arranged from 11:00 to 12:00 for TEM 3 since TEM 3 is scheduled for maintenance, and the processing in TEM 1 and TEM 3 is simultaneously arranged in parallel.

Although the invention has been specifically described above based on embodiments, the invention is not limited to the embodiments described above, and various modifications can be made without departing from the scope of the invention. In each embodiment, components can be added, deleted, replaced, or the like except for essential components. Unless otherwise specified, each component may be single or plural. The embodiments can be combined.

### Reference Signs List

1: inspection system
2: management system (inspection management system)
3: wafer
4: thin piece
5: carrier
10: thin piece production device (FIB-SEM device)
20: thin piece transfer device (lift out device)
30: thin piece observation device (TEM device)

1.-20. (canceled)

21. An inspection management system for managing inspection of a sample by an inspection system that inspects the sample, wherein
the inspection in the inspection system is implemented as an inspection processing sequence in which first processing, second processing, and third processing are sequentially performed by a first type device, a second type device, and a third type device, respectively, which are devices that perform different kinds of processing,
the first type device, the second type device, and the third type device each include one or more devices,
as the inspection processing sequence, the inspection system produces a thin piece from the sample at each target portion of the inspection, transfers the thin piece to a carrier, and performs processing related to the inspection for each of the thin pieces on the carrier,
the inspection management system
is connected to each of a plurality of devices including the first type device, the second type device, and the third type device through communication,
grasps a device status including an idle time and a usage time of each of the devices based on communication with each of the devices, and
based on an inspection instruction related to the inspection and the device status, selects, from the plurality of devices, the devices respectively serving as the first type device, the second type device, and the third type device to be used in the inspection processing sequence and a time to be used for the devices, and creates a plan of the inspection processing sequence including the selected devices and time,
the inspection management system executes the inspection processing sequence of the inspection by the inspection system based on the plan,
the first type device performs a processing operation of forming the thin piece on the sample,
the first type device or the second type device performs a processing operation of taking out the thin piece formed on the sample and transferring the thin piece to the carrier,
the third type device performs a processing operation of observing the thin piece mounted on the carrier,
the inspection management system holds performance information of a result of the inspection processing sequence executed based on the plan, and
creates the plan of a new inspection based on the performance information,
the inspection management system calculates a success rate of a processing operation for each of the devices based on the result of the inspection processing sequence executed based on the plan, and
creates the plan of a new inspection based on the success rate,
the first type device or the second type device monitors a status of a processing operation of transferring the thin piece to the carrier, and
the inspection management system calculates a success rate of the processing operation of transferring the thin piece to the carrier by the first type device or the second type device based on the monitoring.

22. The inspection management system according to claim 21, wherein
the inspection management system creates one or more plan proposals as the plan based on a set policy, displays the created plan proposals on a screen to the user, and determines a plan proposal selected based on an operation of the user on the screen as the plan, and
as the policy, a success rate priority is able to be selected, and when the success rate priority is selected, a device with the high success rate is preferentially selected from the plurality of devices.

23. The inspection management system according to claim 21, wherein
the inspection management system makes a maintenance plan for each of the devices based on a result of the inspection processing sequence executed based on the plan, and
makes the maintenance plan by setting a device with a the success rate declining as a maintenance candidate and an idle time of the device as a maintenance time

24. An inspection management method executed by an inspection management system for managing inspection of a sample by an inspection system that inspects the sample, wherein
the inspection in the inspection system is implemented as an inspection processing sequence in which first processing, second processing, and third processing are sequentially performed by a first type device, a second type device, and a third type device, respectively, which are devices that perform different kinds of processing,
the first type device, the second type device, and the third type device each include one or more devices,
as the inspection processing sequence, the inspection system produces a thin piece from the sample at each target portion of the inspection, transfers the thin piece to a carrier, and performs processing related to the inspection for each of the thin pieces on the carrier,
the inspection management system is connected to each of a plurality of devices including the first type device, the second type device, and the third type device through communication,
the inspection management method comprises:
the inspection management system grasping a device status including an idle time and a usage time of each of the devices based on communication with each of the devices;
based on an inspection instruction related to the inspection and the device status, the inspection management system selecting, from the plurality of devices, devices respectively serving as the first type device, the second type device, and the third type device to be used in the inspection processing sequence and a time to be used for the devices, and creating a plan of the inspection processing sequence including the selected devices and time; and
the inspection management system executing the inspection processing sequence of the inspection by the inspection system based on the plan,
the first type device performs a processing operation of forming the thin piece on the sample,
the first type device or the second type device performs a processing operation of taking out the thin piece formed on the sample and transferring the thin piece to the carrier,
the third type device performs a processing operation of observing the thin piece mounted on the carrier,
the inspection management system holds performance information of a result of the inspection processing sequence executed based on the plan, and
creates the plan of a new inspection based on the performance information,
the inspection management system calculates a success rate of a processing operation for each of the devices based on the result of the inspection processing sequence executed based on the plan, and
creates the plan of a new inspection based on the success rate,
the first type device or the second type device monitors a status of a processing operation of transferring the thin piece to the carrier, and
the inspection management system calculates a success rate of the processing operation of transferring the thin piece to the carrier by the first type device or the second type device based on the monitoring.

25. An inspection management system for managing inspection of a sample by an inspection system that inspects the sample, wherein
the inspection in the inspection system is implemented as an inspection processing sequence in which first processing, second processing, and third processing are sequentially performed by a first type device, a second type device, and a third type device, respectively, which are devices that perform different kinds of processing,
the first type device, the second type device, and the third type device each include one or more devices,
as the inspection processing sequence, the inspection system produces a thin piece from the sample at each target portion of the inspection, transfers the thin piece to a carrier, and performs processing related to the inspection for each of the thin pieces on the carrier,
the inspection management system
is connected to each of a plurality of devices including the first type device, the second type device, and the third type device through communication,
grasps a device status including an idle time and a usage time of each of the devices based on communication with each of the devices, and
based on an inspection instruction related to the inspection and the device status, selects, from the plurality of devices, devices respectively serving as the first type device, the second type device, and the third type device to be used in the inspection processing sequence and a time to be used for the devices, and creates a plan of the inspection processing sequence including the selected devices and time,
the inspection management system executes the inspection processing sequence of the inspection by the inspection system based on the plan,
the first type device performs a processing operation of forming the thin piece on the sample,
the first type device or the second type device performs a processing operation of taking out the thin piece formed on the sample and transferring the thin piece to the carrier,
the third type device performs a processing operation of observing the thin piece mounted on the carrier,
the inspection management system holds performance information of a result of the inspection processing sequence executed based on the plan, and
creates the plan of a new inspection based on the performance information,
the inspection management system calculates an index value of a processing time or a processing capacity for each of the devices based on the result of the inspection processing sequence executed based on the plan, and
creates the plan of a new inspection based on the index value,
the first type device or the second type device monitors a status of a processing operation of transferring the thin piece to the carrier, and
the inspection management system calculates the index value of the processing time or the processing capacity of the processing operation of transferring the thin piece to the carrier by the first type device or the second type device based on the monitoring.

26. The inspection management system according to claim 21, wherein
the monitoring includes capturing an image of the thin piece during the processing operation by an imaging mechanism included in the first type device or the second type device, and performing determination based on the captured image.

27. The inspection management system according to claim 26, wherein
the determination based on the captured image includes determining that the processing operation fails when the thin piece is not able to be checked in the image.

28. The inspection management system according to claim 25, wherein
the monitoring includes detecting falling or breakage of the thin piece during the processing operation by a sensor device included in the first type device or the second type device.

29. The inspection management system according to claim 25, wherein
the inspection management system creates one or more plan proposals as the plan based on a set policy, displays the created plan proposals on a screen to the user, and determines a plan proposal selected based on an operation of the user on the screen as the plan, and
as a policy for creating the plan, a processing capacity priority is able to be selected, and when the success rate priority is selected, a device with a high index value of the processing time or the processing capacity is preferentially selected from the plurality of devices.

30. The inspection management system according to claim 25, wherein
the inspection management system makes a maintenance plan for each of the devices based on a result of the inspection processing sequence executed based on the plan, and
makes the maintenance plan by setting a device with the index value decreased as a maintenance candidate and an idle time of the device as a maintenance time.

31. The inspection management system according to claim 21, wherein
a change in the success rate for the processing operation of the device before and after maintenance work of the device is determined, and information on a correlation between the maintenance work and the success rate is output.

32. The inspection management system according to claim 25, wherein
a change in the index value of the processing time or the processing capacity for the processing operation of the device before and after maintenance work of the device is determined, and information on a correlation between the maintenance work and the index value is output.
